(19) United States
(12) Patent Application Publication
(10) Pub. No.: US 2022/0165968 A1
(43) Pub. Date: May 26, 2022

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Ming Sang, Beijing (CN); Hongbo Li, Beijing (CN); Wei Cai, Beijing (CN); Zhen Wang, Beijing (CN); Tao Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 17/530,611

(22) Filed: Nov. 19, 2021

(30) Foreign Application Priority Data
Nov. 23, 2020 (CN) 202011305815.2
Sep. 9, 2021 (CN) 202111036660.1

(51) Int. Cl. H01L 51/00; C07F 15/00; C09K 11/06

(52) U.S. Cl. CPC H01L 51/0085; C07F 15/0033; H01L 51/0072; H01L 51/5016; C09K 2211/185; C09K 2211/1033; C09K 11/06

(57) ABSTRACT

Provided are an organic electroluminescent material and a device thereof. The organic electroluminescent material is a metal complex containing a ligand Lₐ having a structure of Formula 1. Such new compounds with a fluorine substituent introduced at a particular position of the ligand Lₐ are applicable to electroluminescent devices and can provide more saturated luminescence and better device performance such as improved device efficiency and reduced device voltage. Further provided are an electroluminescent device containing the metal complex and a compound composition containing the metal complex.

### CROSS-REFERENCE TO RELATED APPLICATION(S)

This application claims priority to Chinese Patent Application No. CN 202011305815.2 filed on Nov. 23, 2020 and Chinese Patent Application No. CN 202111036660.1 filed on Sep. 9, 2021, the disclosure of which are incorporated herein by reference in their entireties.

### TECHNICAL FIELD

The present disclosure relates to compounds for organic electronic devices such as organic light-emitting devices. More particularly, the present disclosure relates to a metal complex containing a ligand Lₐ having a structure represented by Formula 1, an organic electroluminescent device containing the metal complex and a compound composition containing the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Cyano substitutions are not generally introduced into phosphorescent metal complexes such as iridium complexes. US20200251666A1, which is a previous application of the applicant of the present application, has disclosed a metal complex with a cyano-substituted ligand. The metal complex is applicable to an organic electroluminescent device and can improve device performance and color saturation to a relatively high level in the industry, but it is still to be improved.

### SUMMARY

The present disclosure aims to provide a series of metal complexes each containing a ligand Lₐ with a structure represented by Formula 1 to solve at least part of the above-mentioned problems. The metal complex may be used as a light-emitting material in an electroluminescent device. Those novel compounds are applicable to electroluminescent devices and can provide more saturated luminescence and better device performance such as improved device efficiency and reduced device voltage.

According to an embodiment of the present disclosure, disclosed is a metal complex, comprising a metal M and a ligand Lₐ coordinated to the metal M, wherein Lₐ has a structure represented by Formula 1:

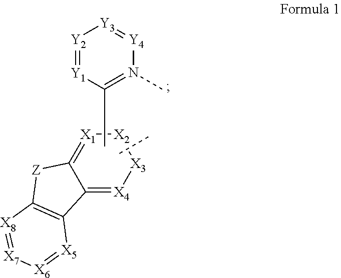

wherein in Formula 1,

the metal M is selected from a metal with a relative atomic mass greater than 40;

Z is selected from the group consisting of O, S, Se, NR, CRR and SiRR, wherein when two R are present at the same time, the two R are identical or different;

X₁ to X₈ are, at each occurrence identically or differently, selected from C, CRₓ or N;

Y₁ to Y₄ are, at each occurrence identically or differently, selected from CR_{y} or N;

R, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

at least one of X₁ to X₈ is CRₓ, and the Rₓ is cyano;

at least one of Y₂ and Y₃ is CR_{y}, and the R_{y} is F; and

adjacent substituents R, Rₓ and R_{y} can be optionally joined to form a ring.

According to another embodiment of the present disclosure, further disclosed is an electroluminescent device, comprising:

an anode,

a cathode, and

an organic layer disposed between the anode and the cathode, where at least one layer of the organic layer contains the metal complex in the preceding embodiment.

According to another embodiment of the present disclosure, further disclosed is a compound composition, comprising the metal complex in the preceding embodiment.

The present disclosure provides a series of metal complexes each containing a ligand Lₐ with a structure represented by Formula 1. Those novel compounds with a fluorine substituent introduced at a particular position of the ligand Lₐ are applicable to electroluminescent devices and can provide more saturated luminescence and better device performance such as improved device efficiency and reduced device voltage.

### BRIEF DESCRIPTION OF DRAWINGS

FIG. 1 is a schematic diagram of an organic light-emitting device that may contain a metal complex and a compound composition disclosed herein.

FIG. 2 is a schematic diagram of another organic light-emitting device that may contain a metal complex and a compound composition disclosed herein.

### DETAILED DESCRIPTION

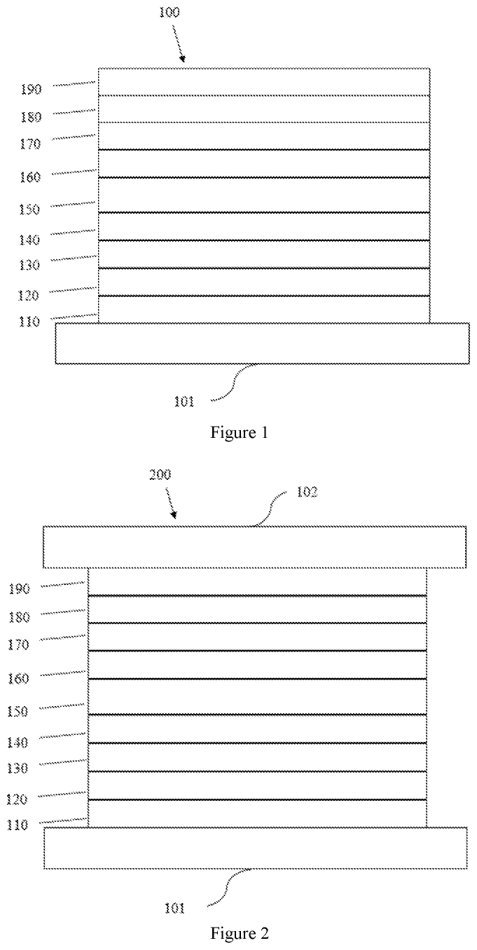

OLEDs can be fabricated on various types of substrates such as glass, plastic, and metal foil. FIG. 1 schematically shows an organic light emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Additionally, the alkyl may be optionally substituted. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylsilyl, dimethylethylsilyl, dimethylisopropylsilyl, t-butyldimethylsilyl, triethylsilyl, triisopropylsilyl, trimethylsilylmethyl, trimethylsilylethyl, and trimethylsilylisopropyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, propenyl, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Additionally, the aryl may be optionally substituted. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, wherein at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic, as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

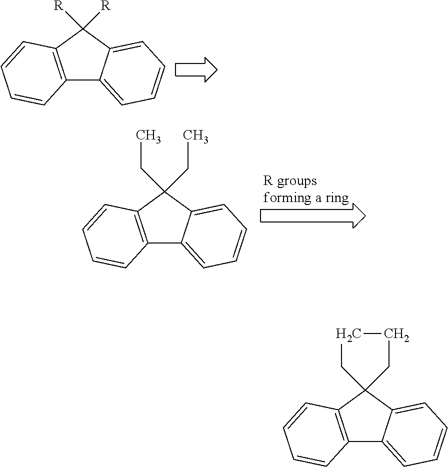

The expression that adjacent substituents can be optionally joined to form a ring is also intended to mean that two substituents bonded to carbon atoms which are directly bonded to each other are joined to each other via a chemical bond to form a ring, which can be exemplified by the following formula:

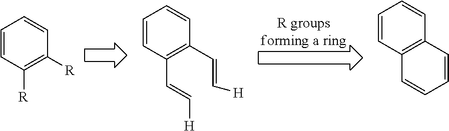

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

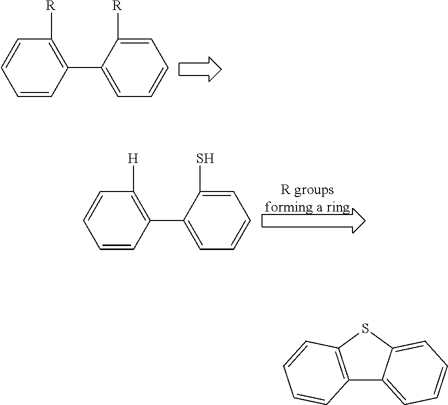

According to an embodiment of the present disclosure, disclosed is a metal complex, comprising a metal M and a ligand Lₐ coordinated to the metal M, wherein Lₐ has a structure represented by Formula 1:

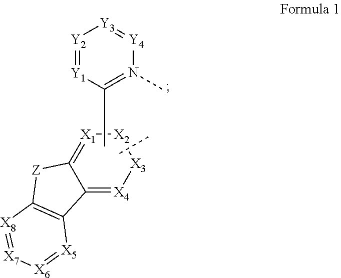

wherein in Formula 1,

the metal M is selected from a metal with a relative atomic mass greater than 40;

Z is selected from the group consisting of O, S, Se, NR, CRR and SiRR, wherein when two R are present at the same time, the two R are identical or different;

X₁ to X₈ are, at each occurrence identically or differently, selected from C, CRₓ or N;

Y₁ to Y₄ are, at each occurrence identically or differently, selected from CR_{y} or N;

R, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

at least one of X₁ to X₈ is CRₓ, and the Rₓ is cyano;

at least one of Y₂ and Y₃ is CR_{y}, and the R_{y} is F; and

adjacent substituents R, Rₓ and R_{y} can be optionally joined to form a ring.

In the present disclosure, the expression that “adjacent substituents R, Rₓ, R_{y} can be optionally joined to form a ring” is intended to mean that any one or more of groups of adjacent substituents, such as two substituents R, two substituents Rₓ, two substituents R_{y}, two substituents R_{y} and Rₓ, and two substituents R and Rₓ, can be joined to form a ring. Obviously, it is possible that none of these substituents are joined to form a ring.

According to an embodiment of the present disclosure, wherein, Lₐ has a structure represented by one of Formulas 1a to 1e:

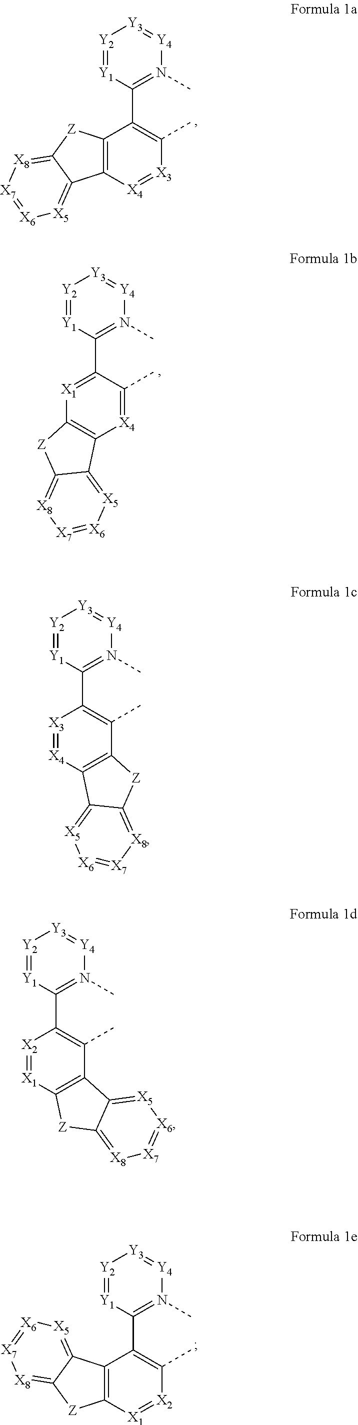

wherein

Z is selected from the group consisting of O, S, Se, NR, CRR and SiRR, where when two R are present at the same time, the two R are identical or different;

in Formulas 1a and 1c, X₃ to X₈ are, at each occurrence identically or differently, selected from CRₓ or N;
in Formula 1b, X₁ and X₄ to X₈ are, at each occurrence identically or differently, selected from CRₓ or N;

in Formulas 1d and 1e, X₁, X₂ and X₅ to X₈ are, at each occurrence identically or differently, selected from CRₓ or N;

Y₁ to Y₄ are, at each occurrence identically or differently, selected from CR_{y} or N;

R, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

in Formula 1a and 1c, at least one of X₃ to X₈ is CRₓ, and the Rₓ is cyano;

in Formula 1b, at least one of X₁ and X₄ to X₈ is CRₓ, and the Rₓ is cyano;

in Formulas 1d and 1e, at least one of X₁, X₂ and X₅ to X₈ is CRₓ, and the Rₓ is cyano;

at least one of Y₂ and Y₃ is CR_{y}, and the R_{y} is F; and adjacent substituents R, Rₓ, R_{y} can be optionally joined to form a ring.

According to an embodiment of the present disclosure, wherein, the metal complex has a general formula of M(Lₐ)ₘ(L_{b})ₙ(L_{c})_{q};

wherein

the metal M is selected from a metal with a relative atomic mass greater than 40; preferably, M is, at each occurrence identically or differently, selected from the group consisting of Cu, Ag, Au, Ru, Rh, Pd, Os, Ir and Pt; more preferably, M is, at each occurrence identically or differently, selected from Pt or Ir;

Lₐ, L_{b} and L_{c} are a first ligand, a second ligand and a third ligand coordinated to the metal M, respectively, and L_{c} is identical to or different from Lₐ or L_{b}; wherein Lₐ, L_{b} and L_{c} can be optionally joined to form a multidentate ligand; for example, any two of Lₐ, L_{b} and L_{c} may be joined to form a tetradentate ligand; in another example, Lₐ, L_{b} and L_{c} may be joined to each other to form a hexadentate ligand; or in another example, none of Lₐ, L_{b} and L_{c} are joined so that the multidentate ligand is not formed;

m is 1, 2 or 3, n is 0, 1 or 2, q is 0, 1 or 2, and m+n+q equals to the oxidation state of the metal M; wherein when m is greater than or equal to 2, the plurality of Lₐ are identical or different; when n is equal to 2, the two L_{b} are identical or different; when q is equal to 2, the two L_{c} are identical or different;

L_{b} and L_{c} are, at each occurrence identically or differently, selected from a structure represented by any one of the group consisting of the following:

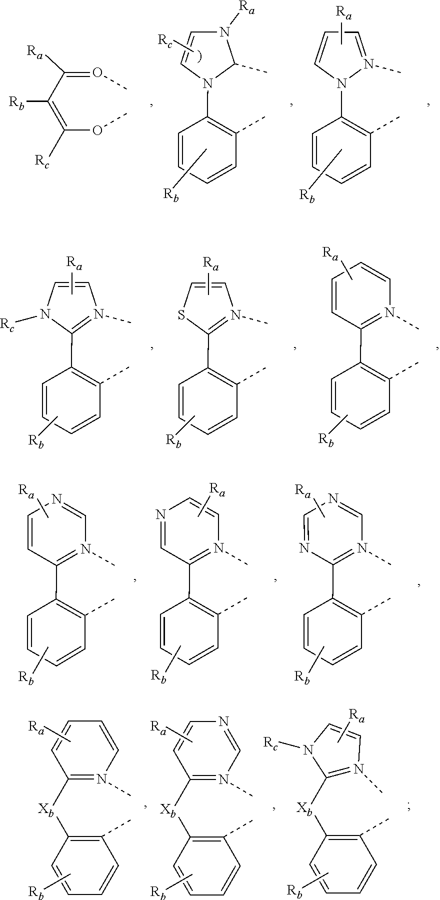

wherein

Rₐ, R_{b} and R_{c} represent, at each occurrence identically or differently, mono-substitution, multiple substitutions or non-substitution;

X_{b} is, at each occurrence identically or differently, selected from the group consisting of: O, S, Se, NR_{N1} and CR_{C1}R_{C2};

Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and

adjacent substituents Rₐ, R_{b}, R_{c}, R_{N1}, R_{C1} and R_{C2} can be optionally joined to form a ring.

In the present disclosure, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, two substituents R_{c}, two substituents Rₐ and R_{b}, two substituents Rₐ and R_{c}, two substituents R_{b} and R_{c}, two substituents Rₐ and R_{N1}, two substituents R_{b} and R_{N1}, two substituents Rₐ and R_{C1}, two substituents Rₐ and R_{C2}, two substituents R_{b} and R_{C1}, two substituents R_{b} and R_{C2}, and substituents R_{C1} and R_{C2}, can be joined to form a ring. Obviously, it is possible that none of these substituents are joined to form a ring.

According to an embodiment of the present disclosure, wherein, the metal complex has a structure represented by Formula 2:

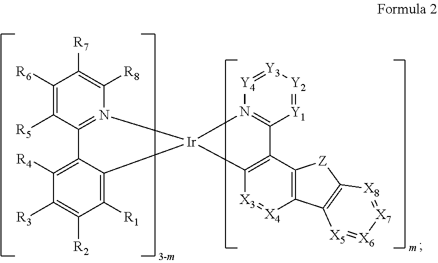

wherein

m is selected from 1, 2 or 3; when m is 1, the two L_{b} are identical or different; when m is 2 or 3, the plurality of Lₐ are identical or different;

Z is selected from the group consisting of O, S, Se, NR, CRR and SiRR, wherein when two R are present at the same time, the two R are identical or different;

X₃ to X₈ are, at each occurrence identically or differently, selected from CRₓ or N;

Y₁ to Y₄ are, at each occurrence identically or differently, selected from CR_{y} or N;

R, Rₓ, R_{y} and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

at least one of X₃ to X₈ is CRₓ, and the Rₓ is cyano;

at least one of Y₂ and Y₃ is CR_{y}, and the R_{y} is F; and

adjacent substituents R, Rₓ, R_{y}, R₁ to R₈ can be optionally joined to form a ring.

In this embodiment, the expression that “adjacent substituents R, Rₓ, R_{y}, R₁ to R₈ can be optionally joined to form a ring” is intended to mean that any one or more of groups of adjacent substituents, such as two substituents R, two substituents Rₓ, two substituents R_{y}, and two substituents of R₁ to R₈, can be joined to form a ring. Obviously, it is possible that none of these substituents are joined to form a ring.

According to an embodiment of the present disclosure, wherein, Z is selected from O or S.

According to an embodiment of the present disclosure, wherein, Z is O.

According to an embodiment of the present disclosure, wherein, Y₁ to Y₄ are, at each occurrence identically or differently, selected from CR_{y}, and at least one of Y₂ and Y₃ is CR_{y}, and the R_{y} is F.

According to an embodiment of the present disclosure, wherein, Y₁ to Y₄ are, at each occurrence identically or differently, selected from CR_{y} or N, and at least one of Y₂ and Y₃ is CR_{y}, and the R_{y} is F.

According to an embodiment of the present disclosure, wherein, at least one of Y₂ and Y₃ is CR_{y}, and the R_{y} is F; when the rest of Y₁ to Y₄ are selected from CR_{y}, and the R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

In the present disclosure, “the rest of Y₁ to Y₄” refers to the following cases: when Y₂ is CR_{y} and the R_{y} is F, “the rest of Y₁ to Y₄” refers to Y₁, Y₃ and Y₄; when Y₃ is CR_{y} and the R_{y} is F, “the rest of Y₁ to Y₄” refers to Y₄, Y₁ and Y₂; and when both Y₂ and Y₃ are CR_{y} and the R_{y} is F, “the rest of Y₁ to Y₄” refers to Y₁ and Y₄.

According to an embodiment of the present disclosure, wherein, at least one of Y₂ and Y₃ is CR_{y}, and the R_{y} is F; when the rest of Y₁ to Y₄ are selected from CR_{y}, and the R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, wherein, at least one of Y₂ and Y₃ is CR_{y}, and the R_{y} is F; when the rest of Y₁ to Y₄ are selected from CR_{y}, and the R_{y} is selected from hydrogen, deuterium, methyl, propyl, isopropyl, butyl, t-butyl, isobutyl, pentyl, isopentyl, neopentyl, t-pentyl or a combination thereof, optionally, hydrogen in the above groups is partially or fully deuterated.

According to an embodiment of the present disclosure, wherein, at least one of Y₂ and Y₃ is CR_{y}, and the R_{y} is F; at least another one of Y₁ to Y₄ is selected from CR_{y}, and at least one R_{y} is selected from the group consisting of: deuterium, halogen, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

According to an embodiment of the present disclosure, wherein, Y₂ is CR_{y}, and the R_{y} is fluorine; Y₃ is CR_{y}, and the R_{y} is selected from the group consisting of: deuterium, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

According to an embodiment of the present disclosure, wherein, Y₃ is CR_{y}, and the R_{y} is fluorine; Y₂ is CR_{y}, and the R_{y} is selected from the group consisting of: deuterium, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

According to an embodiment of the present disclosure, wherein, X₁ to X₈ are, at each occurrence identically or differently, selected from C or CRₓ.

According to an embodiment of the present disclosure, wherein, at least two of X₁ to X₈ are CRₓ, and one of the Rₓ is cyano, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, wherein, at least two of X₁ to X₈ are CRₓ, and one of the Rₓ is cyano, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfhydryl group and combinations thereof.

According to an embodiment of the present disclosure, wherein, at least two of X₁ to X₈ are CRₓ, and one of the Rₓ is cyano, and at least another one Rₓ is selected from the group consisting of: deuterium, halogen, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

According to an embodiment of the present disclosure, wherein, both X₇ and X₈ are selected from CRₓ, and one of the Rₓ is cyano, and another one of the Rₓ is selected from the group consisting of: deuterium, halogen, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

According to an embodiment of the present disclosure, wherein, at least one of X₈ to X₈ is CRₓ, and the Rₓ is cyano.

According to an embodiment of the present disclosure, wherein, X₇ is CRₓ, and the Rₓ is cyano.

According to an embodiment of the present disclosure, wherein, X₈ is CRₓ, and the Rₓ is cyano.

According to an embodiment of the present disclosure, wherein, at least one, two, three or all of R₂, R₃, R₆ and R₇ is(are) selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein, at least one, two, three or all of R₂, R₃, R₆ and R₇ is(are) selected from the group consisting of: deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, wherein, at least one, two, three or all of R₂, R₃, R₆ and R₇ is(are) selected from the group consisting of: deuterium, methyl, ethyl, propyl, isopropyl, n-butyl, isobutyl, t-butyl, cyclopentyl, cyclohexyl and combinations thereof, optionally, hydrogen in the above groups is partially or fully deuterated.

According to an embodiment of the present disclosure, wherein, R is selected from substituted or unsubstituted alkyl having 1 to 20 carbon atoms or substituted or unsubstituted cycloalkyl having 3 to 20 ring carbon atoms.

According to an embodiment of the present disclosure, wherein, R is methyl or deuterated methyl.

According to an embodiment of the present disclosure, wherein, Lₐ is, at each occurrence identically or differently, selected from the group consisting of Lₐ₁ to Lₐ₇₆₆, where the specific structures of Lₐ₁ to Lₐ₇₆₆ are referred to claim 14.

According to an embodiment of the present disclosure, wherein, L_{b} is, at each occurrence identically or differently, selected from the group consisting of L_{b1} to L_{b78}, where the specific structures of L_{b1} to L_{b78} are referred to claim 15.

According to an embodiment of the present disclosure, wherein, L_{b} is, at each occurrence identically or differently, selected from the group consisting of L_{b1} to L_{b80}, where the specific structures of L_{b1} to L_{b80} are referred to claim 15.

According to an embodiment of the present disclosure, wherein, the metal complex has a structure of Ir(Lₐ)₂(L_{b}), where Lₐ is, at each occurrence identically or differently, selected from any one or two of the group consisting of Lₐ₁ to Lₐ₇₆₆ and L_{b} is selected from any one of the group consisting of L_{b1} to L_{b78}, where the specific structures of Lₐ₁ to Lₐ₇₆₆ are referred to claim 14 and the specific structures of L_{b1} to L_{b78} are referred to claim 15.

According to an embodiment of the present disclosure, wherein, the metal complex has a structure of Ir(Lₐ)₂(L_{b}), where Lₐ is, at each occurrence identically or differently, selected from any one or two of the group consisting of Lₐ₁ to Lₐ₇₆₆ and L_{b} is selected from any one of the group consisting of L_{b1} to L_{b78}, where the specific structures of Lₐ₁ to Lₐ₇₆₆ are referred to claim 14 and the specific structures of L_{b1} to L_{b78} are referred to claim 15.

According to an embodiment of the present disclosure, wherein, the metal complex has a structure of Ir(Lₐ)(L_{b})₂, where Lₐ is selected from any one of the group consisting of Lₐ₁ to Lₐ₇₆₆ and L_{b} is, at each occurrence identically or differently, selected from any one or two of the group consisting of L_{b1} to L_{b78}, where the specific structures of Lₐ₁ to Lₐ₇₆₆ are referred to claim 14 and the specific structures of L_{b1} to L_{b78} are referred to claim 15.

According to an embodiment of the present disclosure, wherein, the metal complex has a structure of Ir(Lₐ)(L_{b})₂, where Lₐ is selected from any one of the group consisting of Lₐ₁ to Lₐ₇₆₆ and L_{b} is, at each occurrence identically or differently, selected from any one or two of the group consisting of L_{b1} to L_{b80}, where the specific structures of Lₐ₁ to Lₐ₇₆₆ are referred to claim 14 and the specific structures of L_{b1} to L_{b80} are referred to claim 15.

According to an embodiment of the present disclosure, wherein, the metal complex has a structure of Ir(Lₐ)₃, where Lₐ is, at each occurrence identically or differently, selected from any one, two or three of the group consisting of Lₐ₁ to Lₐ₇₆₆, where the specific structures of Lₐ₁ to Lₐ₇₆₆ are referred to claim 14.

According to an embodiment of the present disclosure, wherein, the metal complex is selected from the group consisting of Metal Complex 1 to Metal Complex 360, where the specific structures of Metal Complex 1 to Metal Complex 360 are referred to claim 16.

According to an embodiment of the present disclosure, wherein, the metal complex is selected from the group consisting of Metal Complex 1 to Metal Complex 390, where the specific structures of Metal Complex 1 to Metal Complex 390 are referred to claim 16.

According to an embodiment of the present disclosure, disclosed is an electroluminescent device, comprising:

an anode,

a cathode, and

an organic layer disposed between the anode and the cathode, where at least one layer of the organic layer contains the metal complex in any one of the embodiments described above.

According to an embodiment of the present disclosure, wherein, in the electroluminescent device, the organic layer containing the metal complex is a light-emitting layer.

According to an embodiment of the present disclosure, wherein, the light-emitting layer of the electroluminescent device emits green light.

According to an embodiment of the present disclosure, wherein, in the electroluminescent device, the light-emitting layer includes at least one first host compound.

According to an embodiment of the present disclosure, wherein, in the electroluminescent device, the light-emitting layer further includes at least two host compounds.

According to an embodiment of the present disclosure, wherein, in the electroluminescent device, at least one of the host compounds includes at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, wherein, in the electroluminescent device, the first host compound has a structure represented by Formula 3:

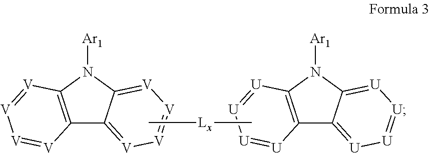

wherein

Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof,

V is, at each occurrence identically or differently, selected from C, CRᵥ or N, and at least one V is C and joined to Lₓ;

U is, at each occurrence identically or differently, selected from C, CRᵤ or N, and at least one U is C and joined to Lₓ;

Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

Ar₁ is, at each occurrence identically or differently, selected from substituted or unsubstituted aryl having 6 to 30 carbon atoms, substituted or unsubstituted heteroaryl having 3 to 30 carbon atoms or a combination thereof; and

adjacent substituents Rᵥ and Rᵤ can be optionally joined to form a ring.

In this embodiment, the expression that “adjacent substituents Rᵥ and Rᵤ can be optionally joined to form a ring” is intended to mean that any one or more of groups of adjacent substituents, such as two substituents Rᵥ, two substituents Ru, and two substituents Rᵥ and Rᵤ, can be joined to form a ring. Obviously, it is possible that none of these substituents are joined to form a ring.

According to an embodiment of the present disclosure, wherein, in the electroluminescent device, the first host compound has a structure represented by one of Formulas 3-a to 3-j:

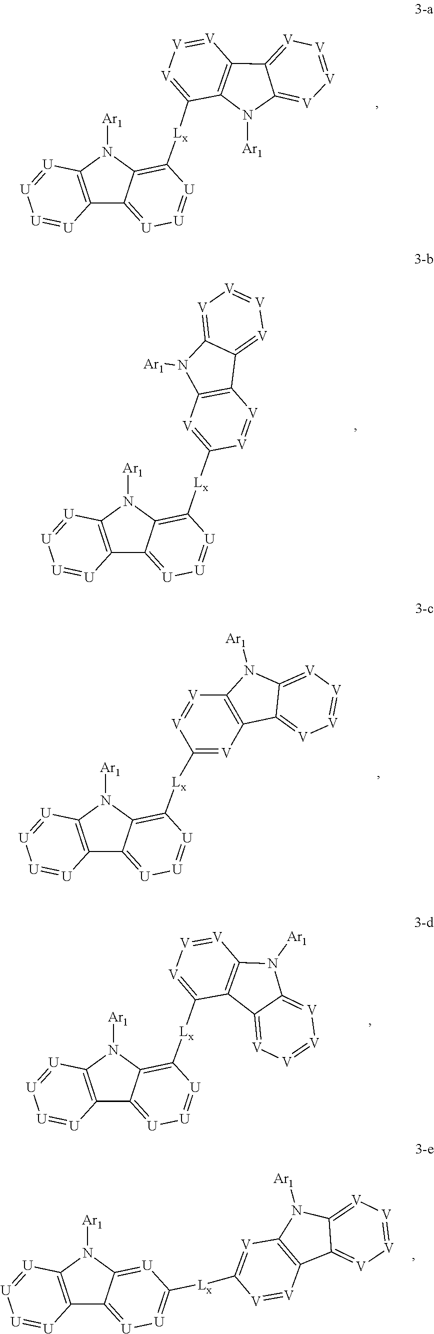

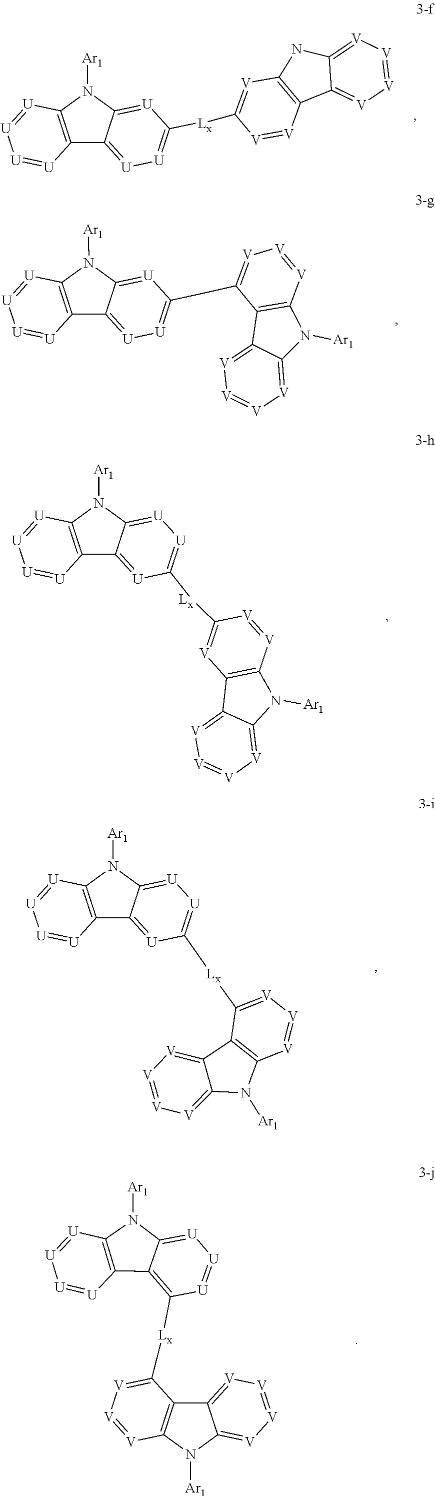

According to an embodiment of the present disclosure, wherein, in the electroluminescent device, the metal complex is doped in the first host compound and the second host compound, and a weight of the metal complex accounts for 1% to 30% of a total weight of the light-emitting layer.

According to an embodiment of the present disclosure, wherein, in the electroluminescent device, the metal complex is doped in the first host compound and the second host compound, and the weight of the metal complex accounts for 3% to 13% of the total weight of the light-emitting layer.

According to another embodiment of the present disclosure, disclosed is a compound composition, comprising the metal complex in any one of the embodiments described above.

Combination with Other Materials

The materials described in the present disclosure for a particular layer in an organic light emitting device can be used in combination with various other materials present in the device.

The combinations of these materials are described in more detail in U.S. Pat. App. No. 20160359122 at paragraphs 0132-0161, which is incorporated by reference herein in its entirety.

The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

Material Synthesis Example

The method for preparing a compound in the present disclosure is not limited herein. Typically, the following compounds are used as examples without limitations, and synthesis routes and preparation methods thereof are described below.

### Synthesis Example 1: Synthesis of Metal Complex 4

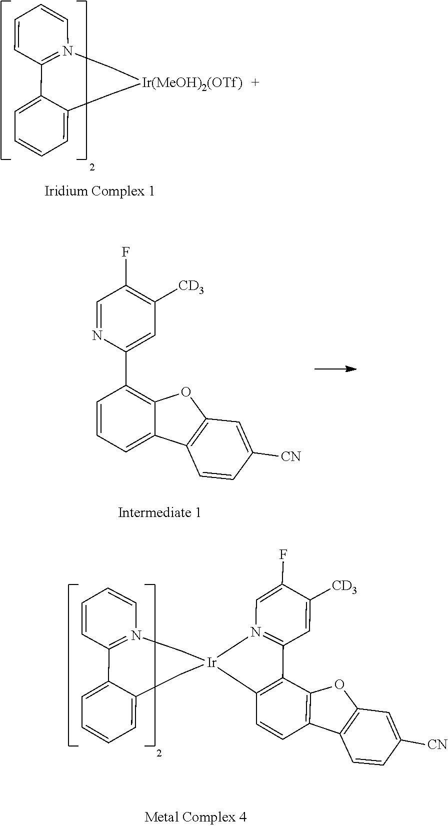

Intermediate 1 (2.2 g, 7.2 mmol), iridium complex 1 (3.5 g, 5.2 mmol), 2-ethoxyethanol (30 mL) and DMF (30 mL) were sequentially added into a dry 250 mL round-bottom flask and heated to 110° C. for 120 h under N₂ protection. The reaction was cooled, filtered through Celite, and washed twice with methanol and n-hexane separately. Yellow solids on the Celite were dissolved with dichloromethane. The organic phases were collected, concentrated under reduced pressure, and purified through column chromatography to obtain Metal Complex 4 as a yellow solid (0.94 g with a yield of 22.4%). The product was confirmed as the target product with a molecular weight of 805.2.

### Synthesis Example 2: Synthesis of Metal Complex 14

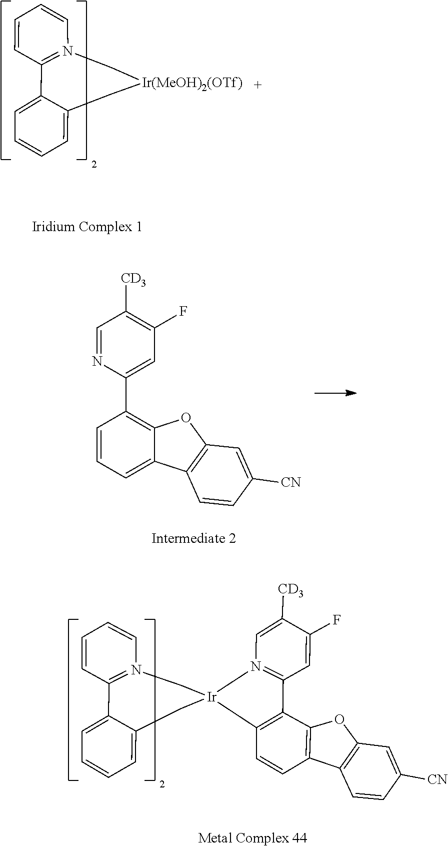

Intermediate 2 (1.5 g, 4.9 mmol), iridium complex 1 (2.9 g, 4.0 mmol), 2-ethoxyethanol (30 mL) and DMF (30 mL) were sequentially added into a dry 250 mL round-bottom flask and heated to 90° C. for 144 h under N₂ protection. The reaction was cooled, filtered through Celite, and washed twice with methanol and n-hexane separately. Yellow solids on the Celite were dissolved with dichloromethane. The organic phases were collected, concentrated under reduced pressure, and purified through column chromatography to obtain Metal Complex 14 as a yellow solid (0.70 g with a yield of 21.8%). The product was confirmed as the target product with a molecular weight of 805.2.

### Synthesis Example 3: Synthesis of Metal Complex 44

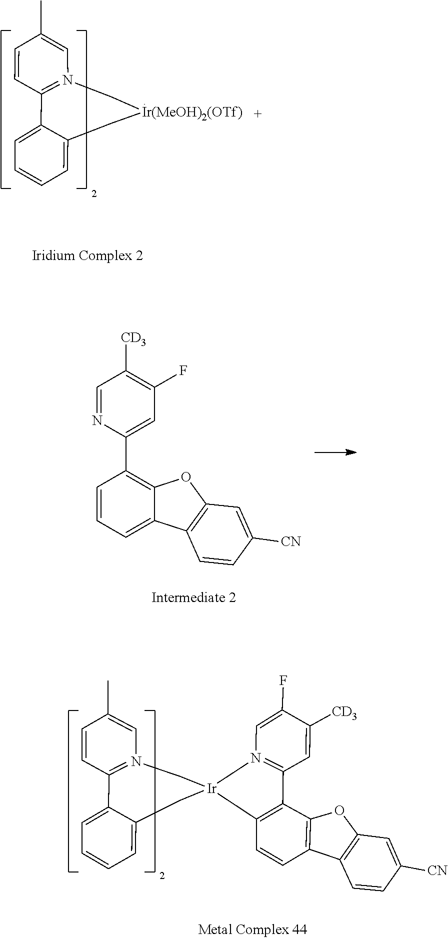

Intermediate 2 (1.6 g, 5.2 mmol), iridium complex 2 (3.1 g, 4.0 mmol), 2-ethoxyethanol (25 mL) and DMF (25 mL) were sequentially added into a dry 250 mL round-bottom flask and heated to 90° C. for 144 h under N₂ protection. The reaction was cooled, filtered through Celite, and washed twice with methanol and n-hexane separately. Yellow solids on the Celite were dissolved with dichloromethane. The organic phases were collected, concentrated under reduced pressure, and purified through column chromatography to obtain Metal Complex 44 as a yellow solid (0.58 g with a yield of 17.5%). The product was confirmed as the target product with a molecular weight of 833.2.

### Synthesis Example 4: Synthesis of Metal Complex 103

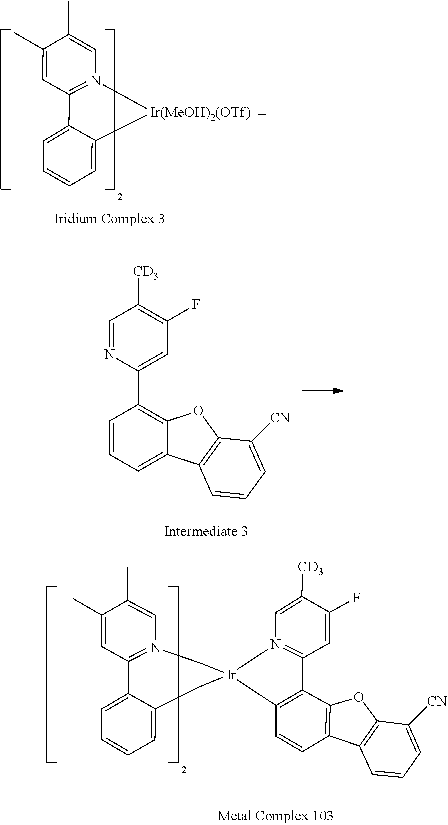

Intermediate 3 (1.2 g, 3.9 mmol), iridium complex 3 (2.5 g, 3.2 mmol), 2-ethoxyethanol (20 mL) and DMF (20 mL) were sequentially added into a dry 250 mL round-bottom flask and heated to 90° C. for 144 h under N₂ protection. The reaction was cooled, filtered through Celite, and washed twice with methanol and n-hexane separately. Yellow solids on the Celite were dissolved with dichloromethane. The organic phases were collected, concentrated under reduced pressure, and purified through column chromatography to obtain Metal Complex 103 as a yellow solid (0.85 g with a yield of 30.9%). The product was confirmed as the target product with a molecular weight of 861.2.

### Synthesis Example 5: Synthesis of Metal Complex 389

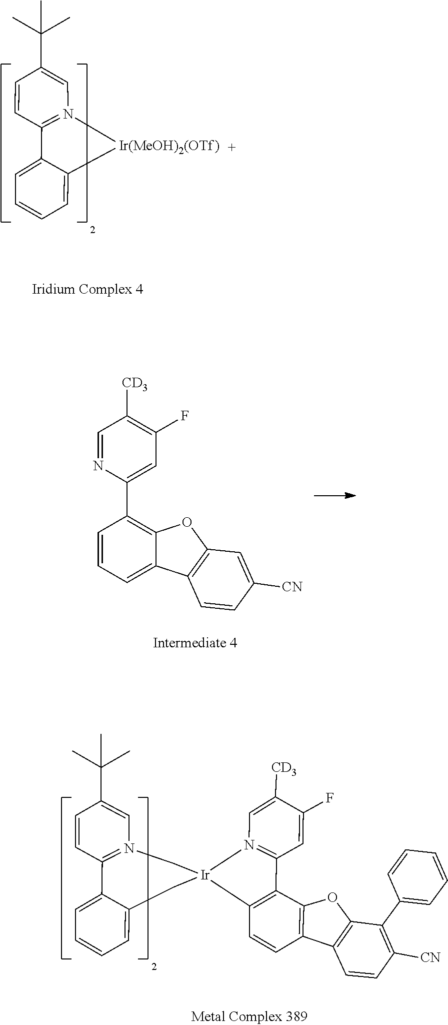

Intermediate 4 (1.6 g, 4.2 mmol), iridium complex 4 (2.6 g, 3.2 mmol), 2-ethoxyethanol (25 mL) and DMF (25 mL) were sequentially added into a dry 250 mL round-bottom flask and heated to 90° C. for 144 h under N₂ protection. The reaction was cooled, filtered through Celite, and washed twice with methanol and n-hexane separately. Yellow solids on the Celite were dissolved with dichloromethane. The organic phases were collected, concentrated under reduced pressure, and purified through column chromatography to obtain Metal Complex 389 as a yellow solid (0.48 g with a yield of 15.1%). The product was confirmed as the target product with a molecular weight of 993.3.

Those skilled in the art will appreciate that the above preparation methods are merely exemplary. Those skilled in the art can obtain other compound structures of the present disclosure through the modifications of the preparation methods.

Device Example 1

First, a glass substrate having an Indium Tin Oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second and a vacuum degree of about 10⁻⁸ torr. Compound HI was used as a hole injection layer (HIL). Compound HT was used as a hole transporting layer (HTL). Compound H1 was used as an electron blocking layer (EBL). Metal Complex 4 of the present disclosure was doped in Compound H1 and Compound H2, and the resulting mixture was deposited for use as an emissive layer (EML). On the EML, Compound H3 was used as a hole blocking layer (HBL). On the HBL, Compound ET and 8-hydroxyquinolinolato-lithium (Liq) were co-deposited for use as an electron transporting layer (ETL). Finally, 8-hydroxyquinolinolato-lithium (Liq) was deposited as an electron injection layer with a thickness of 1 nm, and Al was deposited as a cathode with a thickness of 120 nm. The device was transferred back to the glovebox and encapsulated with a glass lid and a moisture getter to complete the device.

Device Example 2

The implementation mode in Device Example 2 was the same as that in Device Example 1, except that in the emissive layer (EML), Metal Complex 4 of the present disclosure was replaced with Metal Complex 14 of the present disclosure.

Device Example 3

The implementation mode in Device Example 3 was the same as that in Device Example 1, except that in the emissive layer (EML), Metal Complex 4 of the present disclosure was replaced with Metal Complex 44 of the present disclosure.

Device Example 4

The implementation mode in Device Example 4 was the same as that in Device Example 1, except that in the emissive layer (EML), Metal Complex 4 of the present disclosure was replaced with Metal Complex 389 of the present disclosure.

Device Comparative Example 1

The implementation mode in Device Comparative Example 1 was the same as that in Device Example 1, except that in the emissive layer (EML), Metal Complex 4 of the present disclosure was replaced with Compound GD1.

Device Comparative Example 2

The implementation mode in Device Comparative Example 2 was the same as that in Device Example 1, except that in the emissive layer (EML), Metal Complex 4 of the present disclosure was replaced with Compound GD2.

Device Comparative Example 3

The implementation mode in Device Comparative Example 3 was the same as that in Device Example 1, except that in the emissive layer (EML), Metal Complex 4 of the present disclosure was replaced with Compound GD3.

Detailed structures and thicknesses of layers of the devices are shown in Table 1. A layer using more than one material is obtained by doping different compounds at their weight ratio as recorded.

TABLE 1
Device structures in device examples

| Device ID | HIL | HTL | EBL | EML | HBL | ETL |
|---|---|---|---|---|---|---|
| Example 1 | Compound | Compound | Compound | Compound | Compound | Compound |
| | HI (100 Å) | HT (350 | H1 (50 Å) | H1:Compound | H3 (50 Å) | ET:Liq |
| | | Å) | | H2:Metal | | (40:60) |
| | | | | complex 4 | | (350 Å) |
| | | | | (47:47:6) (400 | | |
| | | | | Å) | | |
| Example 2 | Compound | Compound | Compound | Compound | Compound | Compound |
| | HI (100 Å) | HT (350 | H1 (50 Å) | H1:Compound | H3 (50 Å) | ET:Liq |
| | | Å) | | H2:Metal | | (40:60) |
| | | | | complex 14 | | (350 Å) |
| | | | | (47:47:6) (400 | | |
| | | | | Å) | | |
| Example 3 | Compound | Compound | Compound | Compound | Compound | Compound |
| | HI (100 Å) | HT (350 | H1 (50 Å) | H1:Compound | H3 (50 Å) | ET:Liq |
| | | Å) | | H2:Metal | | (40:60) |
| | | | | complex 44 | | (350 Å) |
| | | | | (47:47:6) (400 | | |
| | | | | Å) | | |
| Example 4 | Compound | Compound | Compound | Compound | Compound | Compound |
| | HI (100 Å) | HT (350 | H1 (50 Å) | H1:Compound | H3 (50 Å) | ET:Liq |
| | | Å) | | H2:Metal | | (40:60) |
| | | | | complex 389 | | (350 Å) |
| | | | | (47:47:6) (400 | | |
| | | | | Å) | | |
| Comparative | Compound | Compound | Compound | Compound | Compound | Compound |
| Example 1 | HI (100 Å) | HT (350 | H1 (50 Å) | H1:Compound | H3 (50 Å) | ET:Liq |
| | | Å) | | H2:Compound | | (40:60) |
| | | | | GD1 (47:47:6) | | (350 Å) |
| | | | | (400 Å) | | |
| Comparative | Compound | Compound | Compound | Compound | Compound | Compound |
| Example 2 | HI (100 Å) | HT (350 | H1 (50 Å) | H1:Compound | H3 (50 Å) | ET:Liq |
| | | Å) | | H2:Compound | | (40:60) |
| | | | | GD2 (47:47:6) | | (350 Å) |
| | | | | (400 Å) | | |
| Comparative | Compound | Compound | Compound | Compound | Compound | Compound |
| Example 3 | HI (100 Å) | HT (350 | H1 (50 Å) | H1:Compound | H3 (50 Å) | ET:Liq |
| | | Å) | | H2:Compound | | (40:60) |
| | | | | GD3 (47:47:6) | | (350 Å) |
| | | | | (400 Å) | | |

The structures of the materials used in the devices are shown as follows:

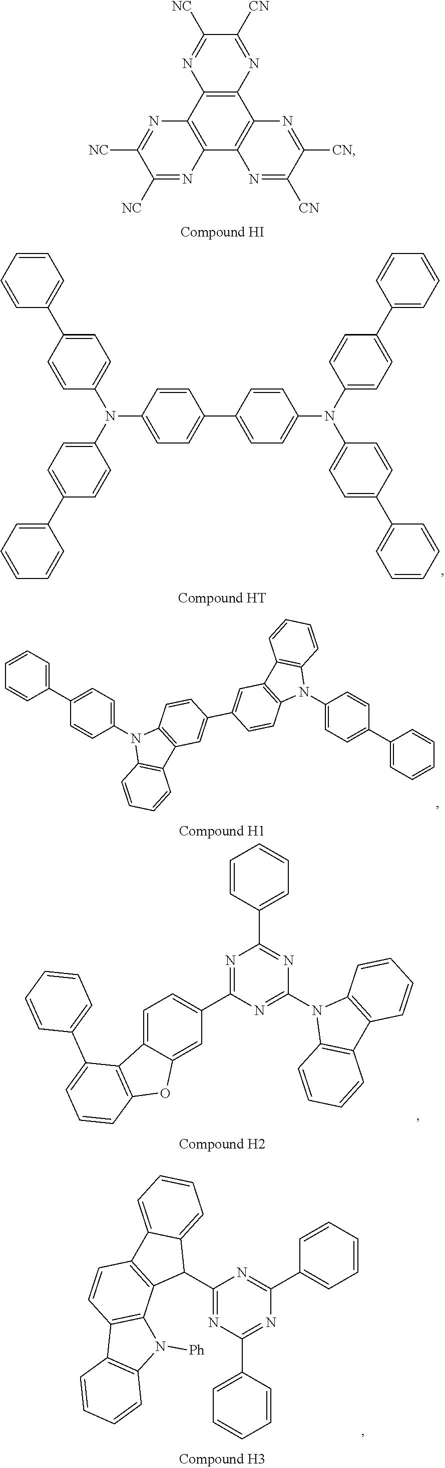 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2nc(-c3ccccc3)nc(C3c4ccccc4-c4ccc5c6ccccc6n(-c6ccccc6)c5c43)n2)cc1]

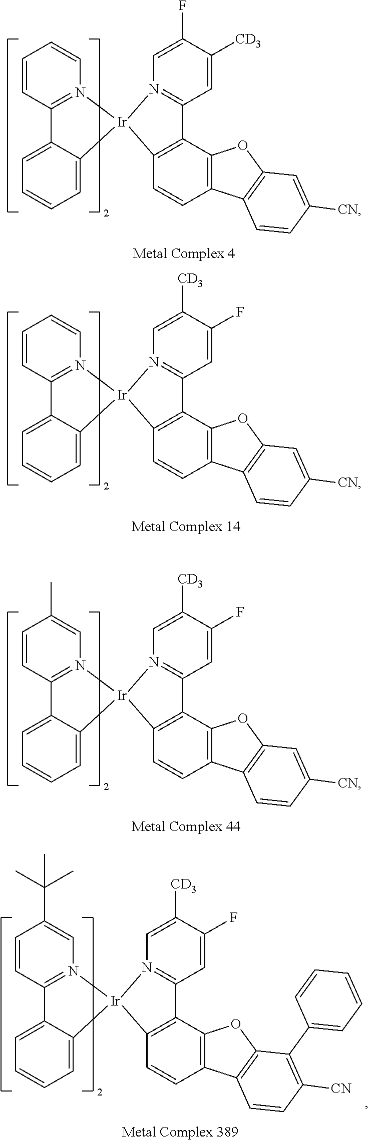

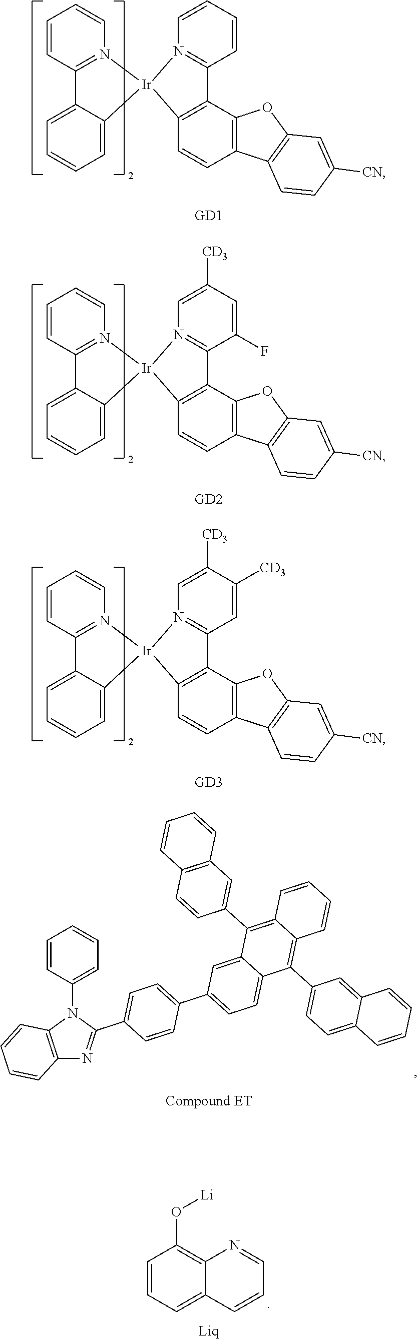

Current-voltage-luminance (IVL) characteristics of the devices were measured. At 1000 cd/m², the CIE data, maximum emission wavelength (λₘₐₓ), full width at half maximum (FWHM), voltage (V), and external quantum efficiency (EQE) of each device were measured. The data was recorded and shown in Table 2.

TABLE 2
Device data

| | | λₘₐₓ | FWHM | Voltage | |
|---|---|---|---|---|---|
| Device ID | CIE (x, y) | (nm) | (nm) | (V) | EQE (%) |
| Example 1 | (0.300, 0.655) | 520 | 41.2 | 2.84 | 24.37 |
| Example 2 | (0.300, 0.654) | 521 | 35.8 | 2.83 | 24.65 |
| Example 3 | (0.319, 0.645) | 524 | 41.2 | 2.69 | 24.14 |
| Example 4 | (0.318, 0.649) | 525 | 32.3 | 2.80 | 26.52 |
| Comparative | (0.321, 0.646) | 525 | 37.8 | 3.19 | 23.39 |
| Example 1 | | | | | |
| Comparative | (0.399, 0.589) | 540 | 59.7 | 2.91 | 23.02 |
| Example 2 | | | | | |
| Comparative | (0.298, 0.653) | 519 | 36.3 | 2.92 | 23.13 |
| Example 3 | | | | | |

Discussion

Table 2 shows the device performance of the examples and the comparative examples. From the data in Table 2, it is found that Example 1 and Example 2 have emission wavelengths blue-shifted by 4-5 nm compared to that of Comparative Example 1 with no substitution on a ligand Lₐ and provide more saturated green light. Moreover, the EQE of the device of Example 1 and the EQE of the device of Example 2 reach 24.37% and 24.65%, respectively, both of which are higher than that (23.39%) of Comparative Example 1 and are further improved based on the EQE of Comparative Example 1 which is at a relatively high level in the industry. In addition, both the device voltages of Example 1 and Example 2 are about 0.35 V lower than that of Comparative Example 1.

The spectrum of Comparative Example 3 containing deuterated methyl substitutions in both Y₂ and Y₃ of the ligand Lₐ is similar to those of Example 1 and Example 2, but the EQE of Comparative Example 3 is lower than those of Example 1 and Example 2 to different degrees and the device voltage of Comparative Example 3 is higher than those of Example 1 and Example 2.

Comparative Example 2 containing a fluorine substitution in Y₁ of the ligand Lₐ has a maximum emission wavelength red-shifted by about 20 nm compared to those of Example 1 and Example 2 and an FWHM 18.5 nm and 23.9 nm wider than those of Example 1 and Example 2, respectively so that Comparative Example 2 emits unsaturated light. In addition, the EQE of Comparative Example 2 is lower than those of Example 1 and Example 2 and the device voltage of Comparative Example 2 is slightly higher than those of Example 1 and Example 2.

The above results show that the metal complex of the present disclosure, which contains a ligand having the F substitution at a particular position, has improved device performance, especially reduced device voltage, improved EQE and improved color saturation compared to a metal complex with no substitution or other alkyl substitutions at the same position of the ligand Lₐ or with the fluorine substitution at another position of the ligand Lₐ.

Both Example 3 and Example 4 have great improvements compared to Comparative Examples 1 to 3 and exhibit higher EQE and lower drive voltage. The drive voltage of Example 3 is 0.5 V, 0.22 V and 0.21 V lower than those of Comparative Examples 1 to 3, respectively. The EQE of Example 4 using the metal complex of the present disclosure reaches 26.52%, which is about 13.4%, 15.2% and 14.6% higher than those of Comparative Examples 1 to 3, respectively. Moreover, the FWHM of Example 4 is very narrow (only 32.3 nm), which is at a very high level in the industry.

The above results show that the metal complex of the present disclosure, which contains a ligand having the F substitution at a particular position, has improved device performance, especially improved color saturation, a narrowed FWHM, improved EQE and reduced device voltage, compared to a metal complex with the fluorine substitution at another position of the ligand.

It should be understood that various embodiments described herein are merely examples and not intended to limit the scope of the present disclosure. Therefore, it is apparent to those skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex containing a metal M and a ligand Lₐ coordinated to the metal M, wherein Lₐ has a structure represented by Formula 1: 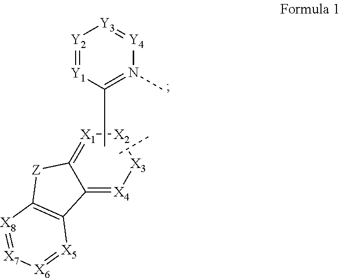
wherein in Formula 1,
the metal M is selected from a metal with a relative atomic mass greater than 40;
Z is selected from the group consisting of O, S, Se, NR, CRR and SiRR, wherein when two R are present at the same time, the two R are identical or different;
X₁ to X₈ are, at each occurrence identically or differently, selected from C, CRₓ or N;
Y₁ to Y₄ are, at each occurrence identically or differently, selected from CR_{y} or N;
R, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of X₁ to X₈ is CRₓ, and the Rₓ is cyano;
at least one of Y₂ and Y₃ is CR_{y}, and the R_{y} is F; and
adjacent substituents R, Rₓ and R_{y} can be optionally joined to form a ring.

2. The metal complex of claim 1, wherein Lₐ has a structure represented by one of Formulas 1a to 1e: 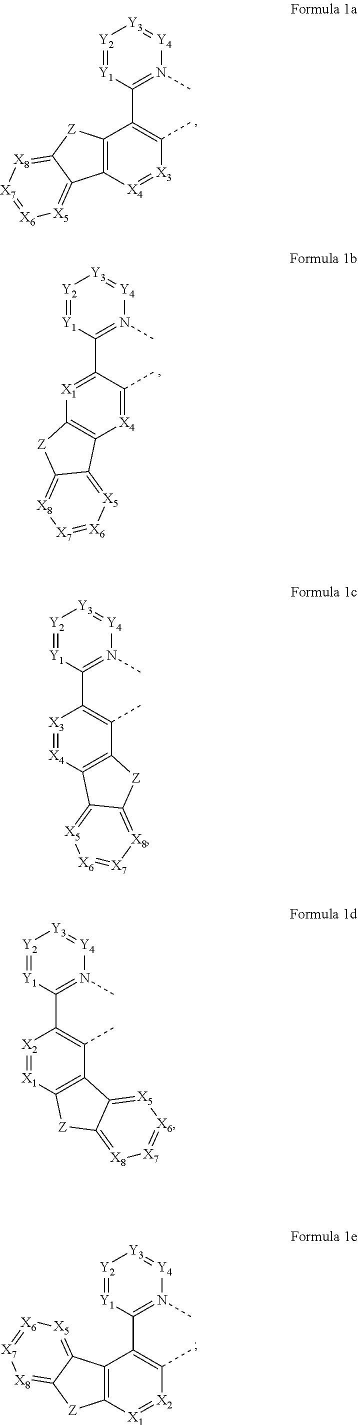
Z is selected from the group consisting of O, S, Se, NR, CRR and SiRR, wherein when two R are present at the same time, the two R are identical or different;
X₁ to X₈ are, at each occurrence identically or differently, selected from CRₓ or N;
Y₁ to Y₄ are, at each occurrence identically or differently, selected from CR_{y} or N;
R, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of X₁ to X₈ is CRₓ, and the Rₓ is cyano;
at least one of Y₂ and Y₃ is CR_{y}, and the R_{y} is F; and
adjacent substituents R, Rₓ and R_{y} can be optionally joined to form a ring.

3. The metal complex of claim 1, wherein the metal complex has a general formula of M(Lₐ)ₘ(L_{b})ₙ(L_{c})_{q};
wherein
the metal M is selected from a metal with a relative atomic mass greater than 40; preferably, M is, at each occurrence identically or differently, selected from the group consisting of Cu, Ag, Au, Ru, Rh, Pd, Os, Ir and Pt; more preferably, M is, at each occurrence identically or differently, selected from Pt or Ir;
Lₐ, L_{b} and L_{c} are a first ligand, a second ligand and a third ligand coordinated to the metal M, respectively, and L_{c} is identical to or different from Lₐ or L_{b}; wherein Lₐ, L_{b} and L_{c} can be optionally joined to form a multidentate ligand;
m is 1, 2 or 3, n is 0, 1 or 2, q is 0, 1 or 2, and m+n+q equals to the oxidation state of the metal M; wherein when m is greater than or equal to 2, the plurality of Lₐ are identical or different; when n is equal to 2, the two L_{b} are identical or different; when q is equal to 2, the two L_{c} are identical or different;
L_{b} and L_{c} are, at each occurrence identically or differently, selected from a structure represented by any one of the group consisting of the following: 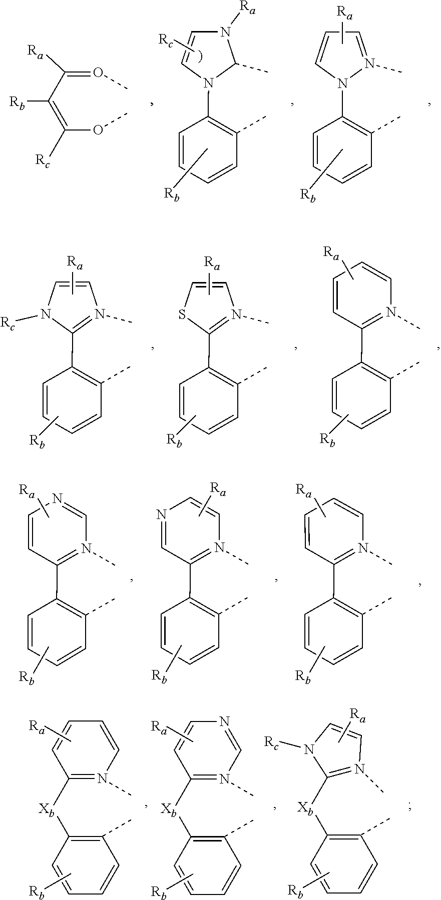
wherein
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{C1} and R_{C2} can be optionally joined to form a ring.

4. The metal complex of claim 1, wherein the metal complex has a structure represented by Formula 2: 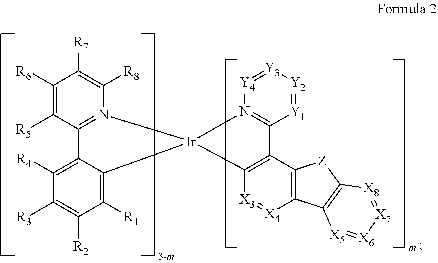
wherein
m is selected from 1, 2 or 3; when m is 1, the two L_{b} are identical or different; when m is 2 or 3, the plurality of Lₐ are identical or different;
Z is selected from the group consisting of O, S, Se, NR, CRR and SiRR, wherein when two R are present at the same time, the two R are identical or different;
X₃ to X₈ are, at each occurrence identically or differently, selected from CRₓ or N;
Y₁ to Y₄ are, at each occurrence identically or differently, selected from CR_{y} or N;
R, Rₓ, R_{y} and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of X₃ to X₈ is CRₓ, and the Rₓ is cyano;
at least one of Y₂ and Y₃ is CR_{y}, and the R_{y} is F; and
adjacent substituents R, Rₓ, R_{y}, R₁ to R₈ can be optionally joined to form a ring.

5. The metal complex of claim 1, wherein Z is selected from O or S; preferably, Z is O.

6. The metal complex of claim 1, wherein Y₁ to Y₄ are, at each occurrence identically or differently, selected from CR_{y}, and at least one of Y₂ and Y₃ is CR_{y}, and the R_{y} is F.

7. The metal complex of claim 1, wherein at least one of Y₂ and Y₃ is CR_{y}, and the R_{y} is F; when the rest of Y₁ to Y₄ are selected from CR_{y}, R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, when the rest of Y₁ to Y₄ are selected from CR_{y}, R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms and combinations thereof, and
more preferably, when the rest of Y₁ to Y₄ are selected from CR_{y}, R_{y} is selected from hydrogen, deuterium, methyl, propyl, isopropyl, butyl, t-butyl, isobutyl, pentyl, isopentyl, neopentyl, t-pentyl or a combination thereof, optionally, hydrogen in the above groups is partially or fully deuterated.

8. The metal complex of claim 1, wherein at least one of Y₂ and Y₃ is CR_{y}, and the R_{y} is F; at least another one of Y₁ to Y₄ is selected from CR_{y}, and at least one R_{y} is selected from the group consisting of: deuterium, halogen, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

9. The metal complex of claim 1, wherein Y₂ is CR_{y}, and the R_{y} is fluorine; and Y₃ is CR_{y}, and the R_{y} is selected from the group consisting of: deuterium, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof; or
Y₃ is CR_{y}, and the R_{y} is fluorine; and Y₂ is CR_{y}, and the R_{y} is selected from the group consisting of: deuterium, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

10. The metal complex of claim 1, wherein X₁ to X₈ are, at each occurrence identically or differently, selected from C or CRₓ.

11. The metal complex of claim 1, wherein at least two of X₁ to X₈ are CRₓ, and one of the Rₓ is cyano, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
preferably, at least two of X₁ to X₈ are CRₓ, and one of the Rₓ is cyano, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfhydryl group and combinations thereof, and
more preferably, at least two of X₁ to X₈ are CRₓ, one of the Rₓ is cyano, and at least another one Rₓ is selected from the group consisting of: deuterium, halogen, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

12. The metal complex of claim 1, wherein at least one of X₈ to X₈ is CRₓ, and the Rₓ is cyano; and
preferably, X₇ is CRₓ, and the Rₓ is cyano; or X₈ is CRₓ, and the Rₓ is cyano.

13. The metal complex of claim 4, wherein at least one, two, three or all of R₂, R₃, R₆ and R₇ is(are) selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, at least one, two, three or all of R₂, R₃, R₆ and R₇ is(are) selected from the group consisting of: deuterium, substituted or unsubstituted alkyl having 1 to 20 carbon atoms, substituted or unsubstituted cycloalkyl having 3 to 20 ring carbon atoms and combinations thereof; and
more preferably, at least one, two, three or all of R₂, R₃, R₆ and R₇ is(are) selected from the group consisting of: deuterium, methyl, ethyl, propyl, isopropyl, n-butyl, isobutyl, t-butyl, cyclopentyl, cyclohexyl and combinations thereof, optionally, hydrogen in the above groups is partially or fully deuterated.

14. The metal complex of claim 3, wherein Lₐ is, at each occurrence identically or differently, selected from any one of the group consisting of:

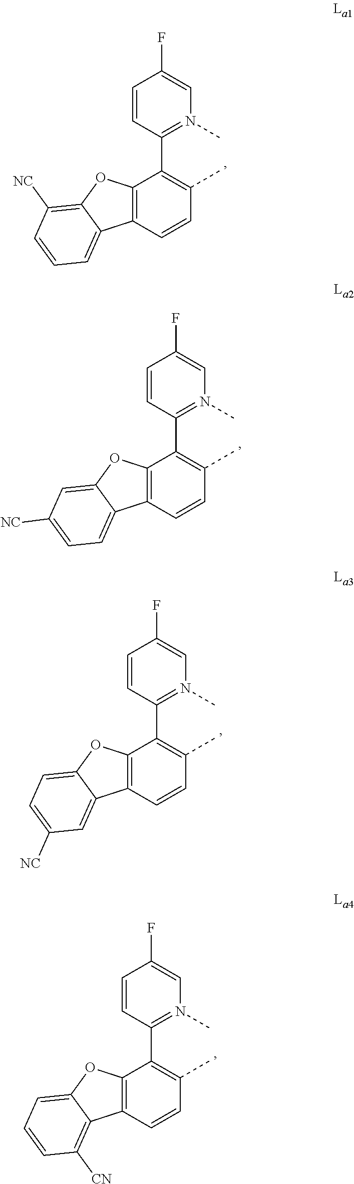

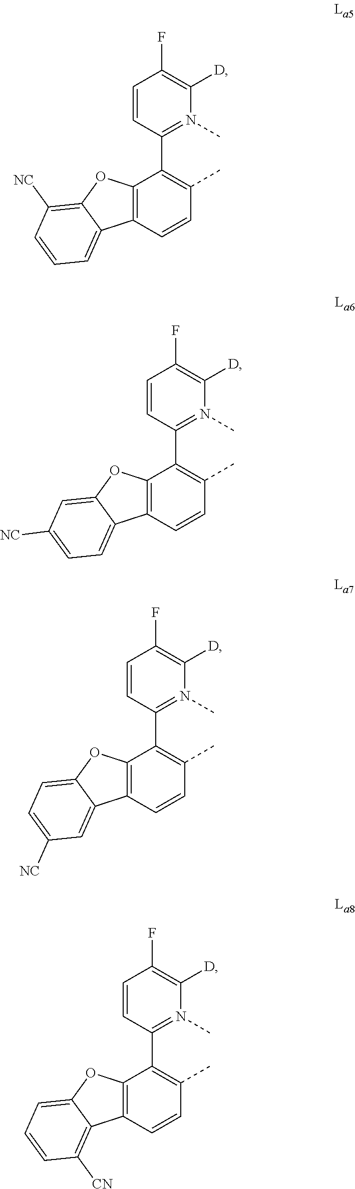

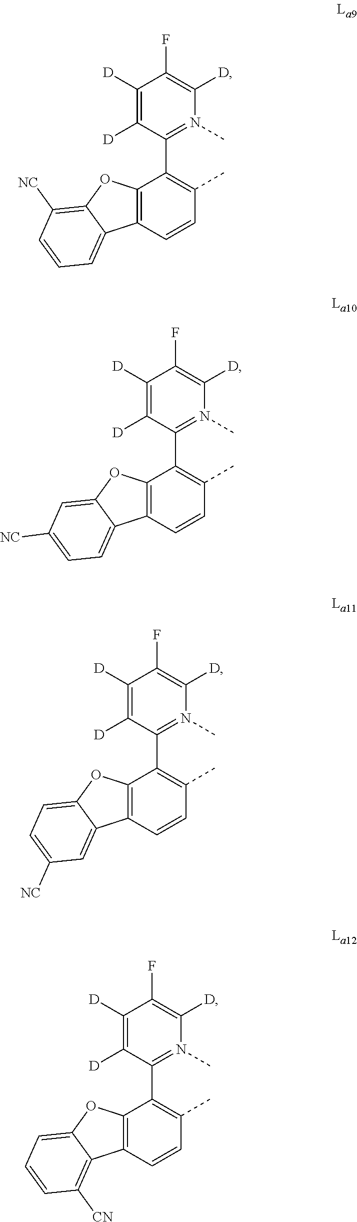

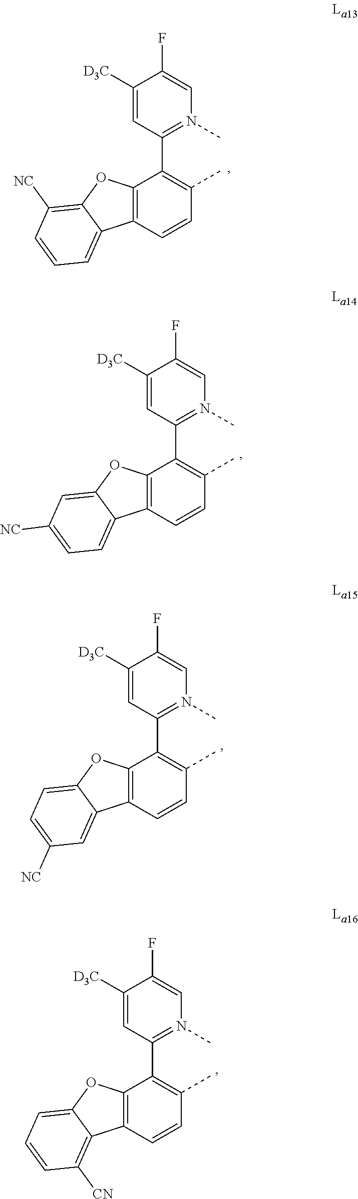

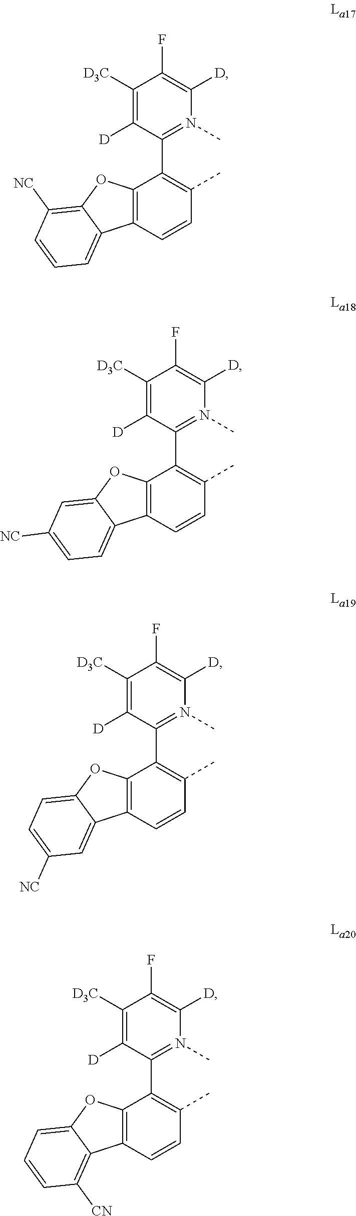

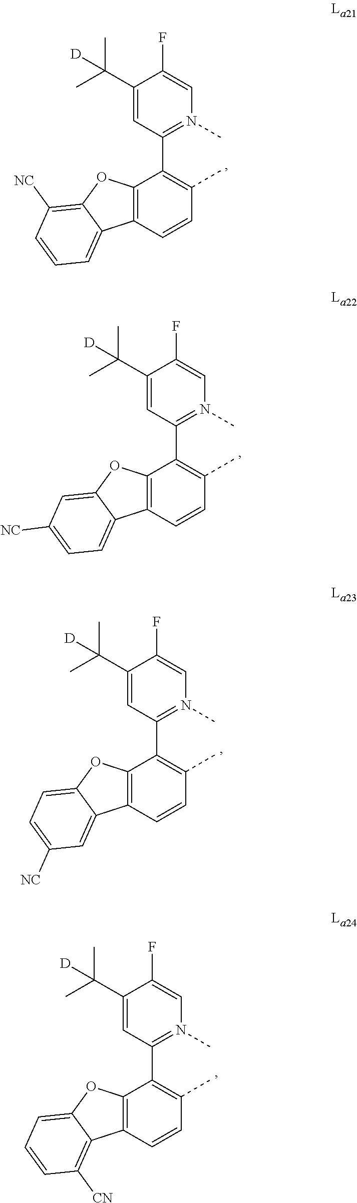

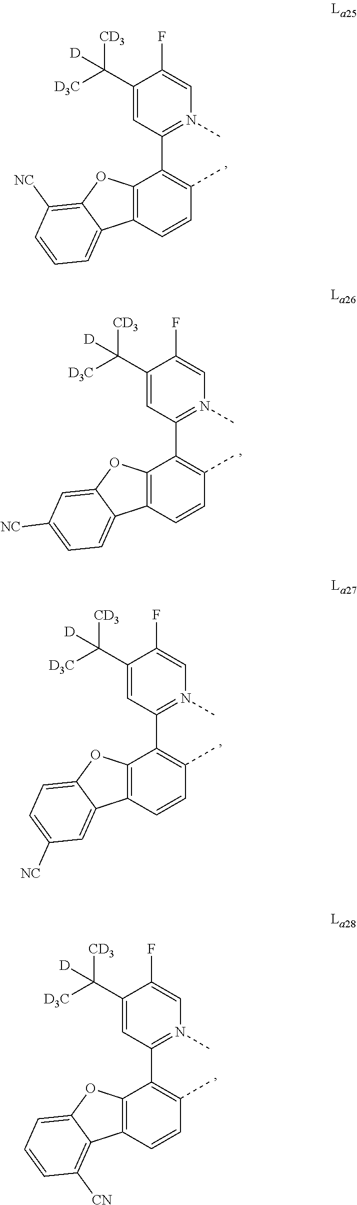

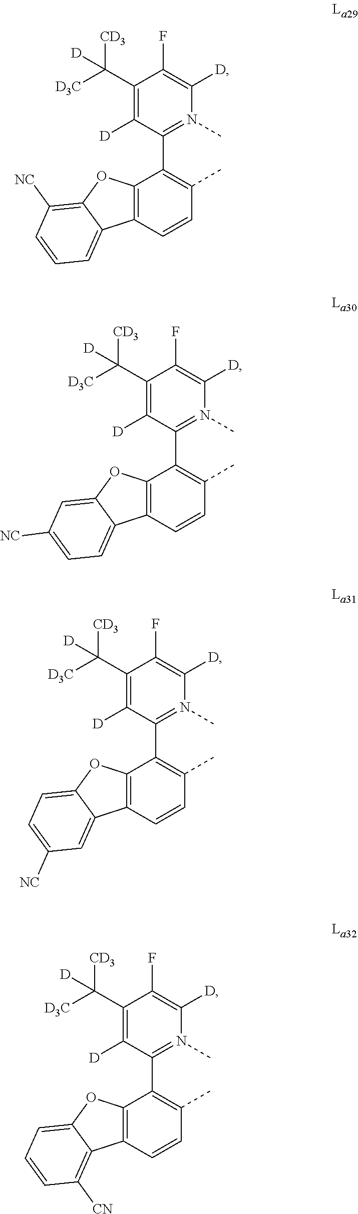

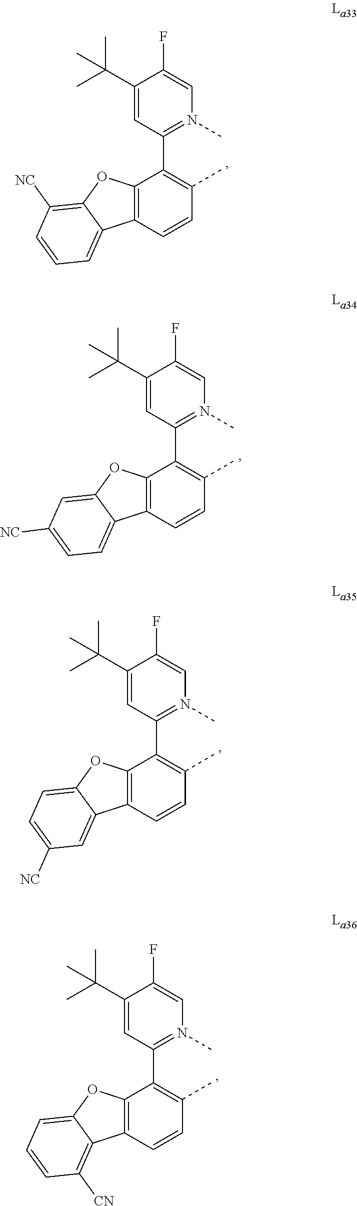

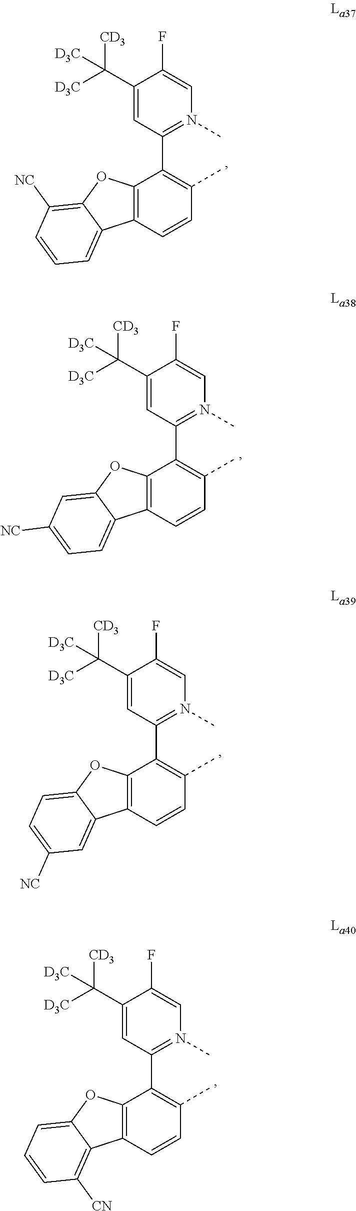

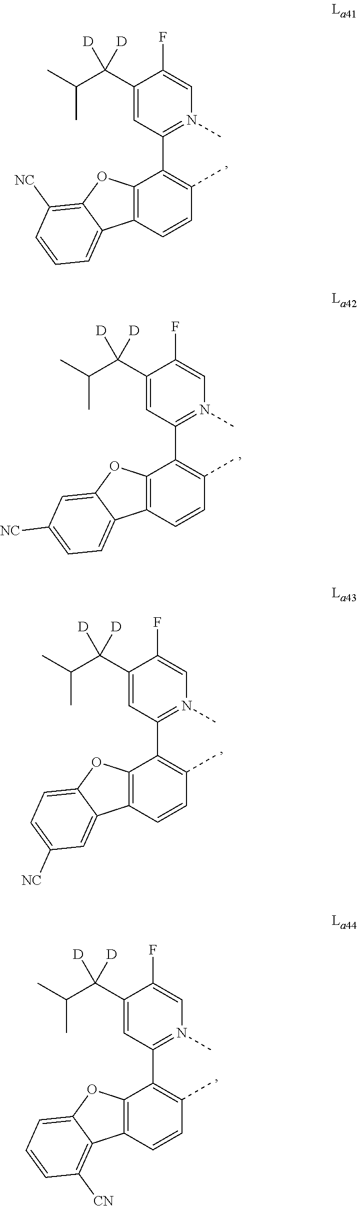

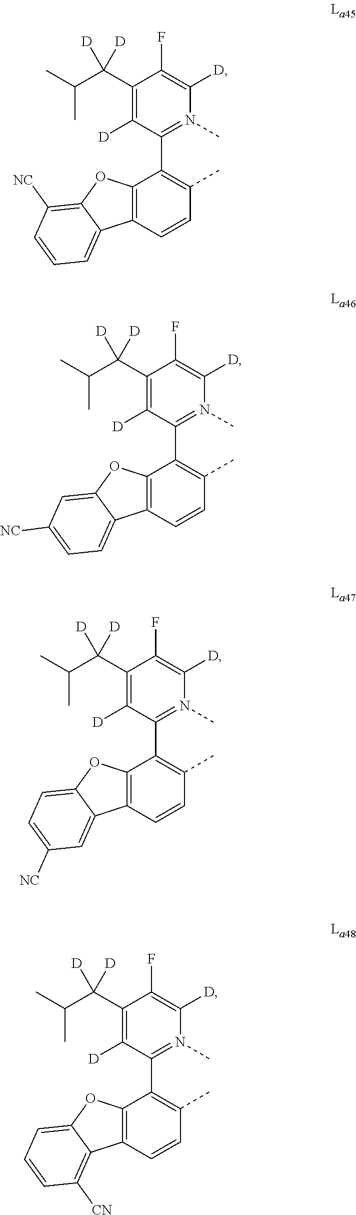

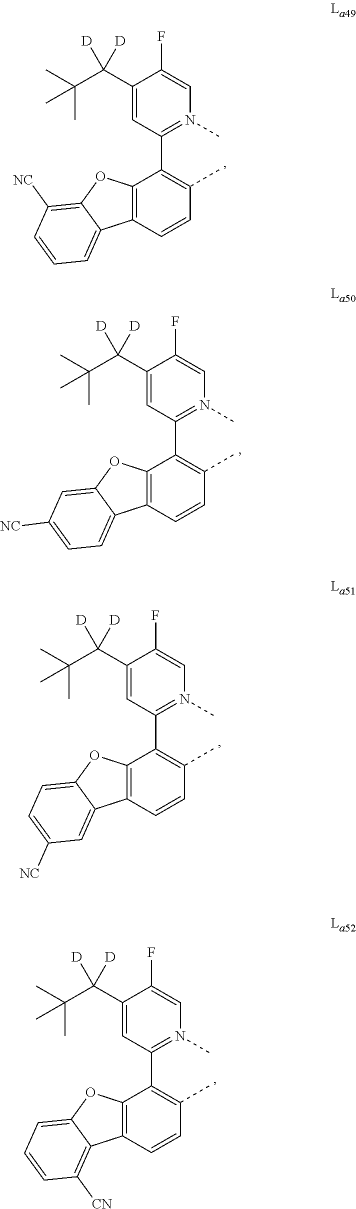

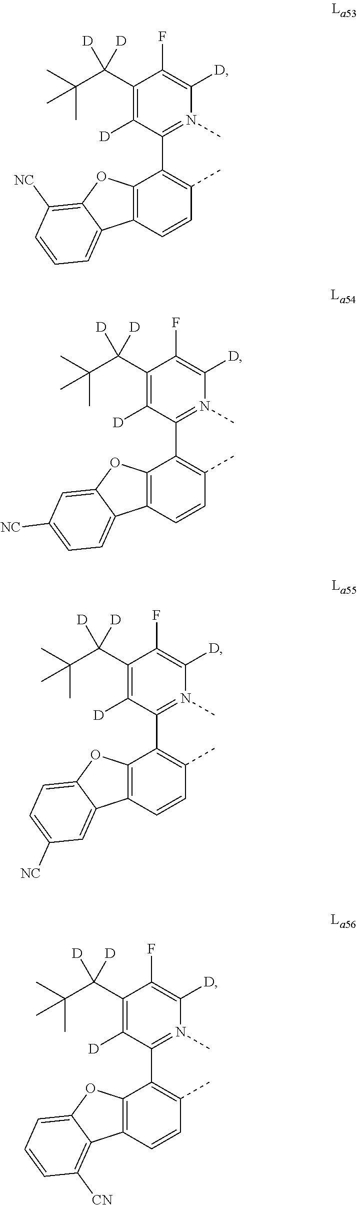

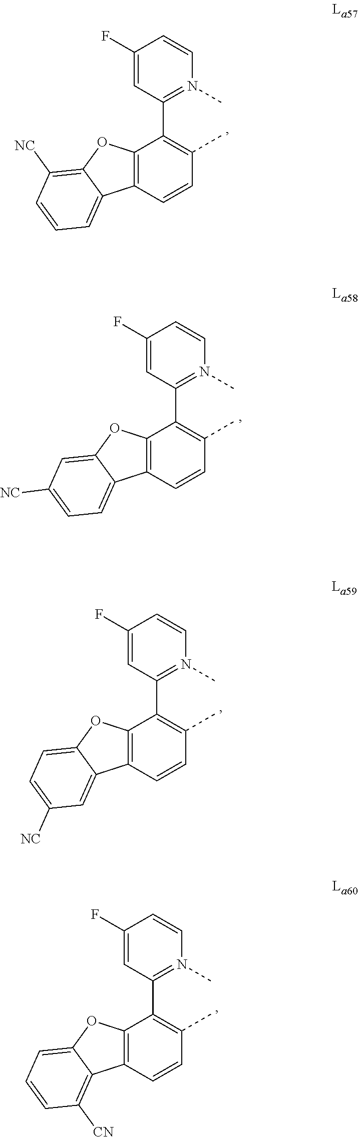

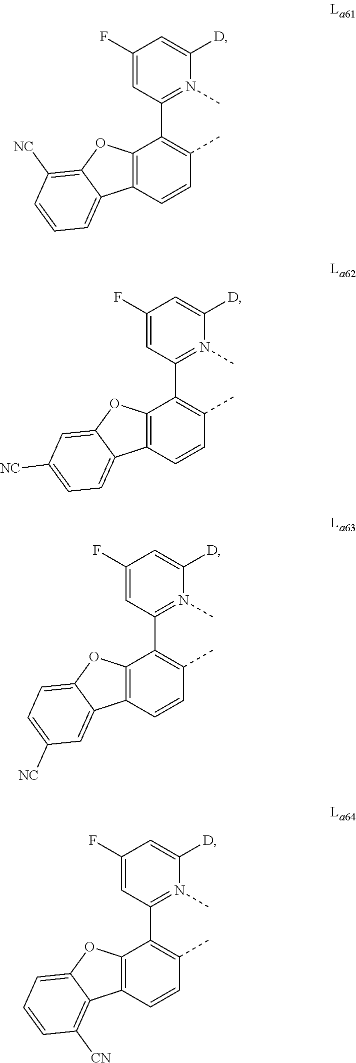

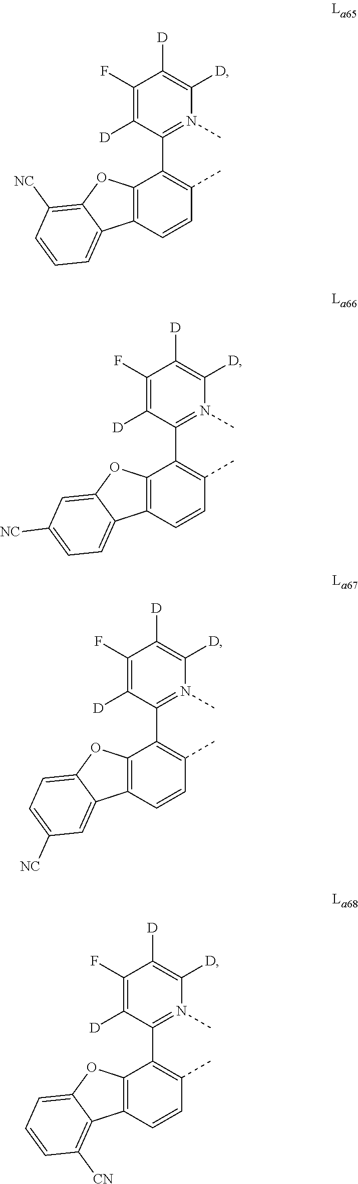

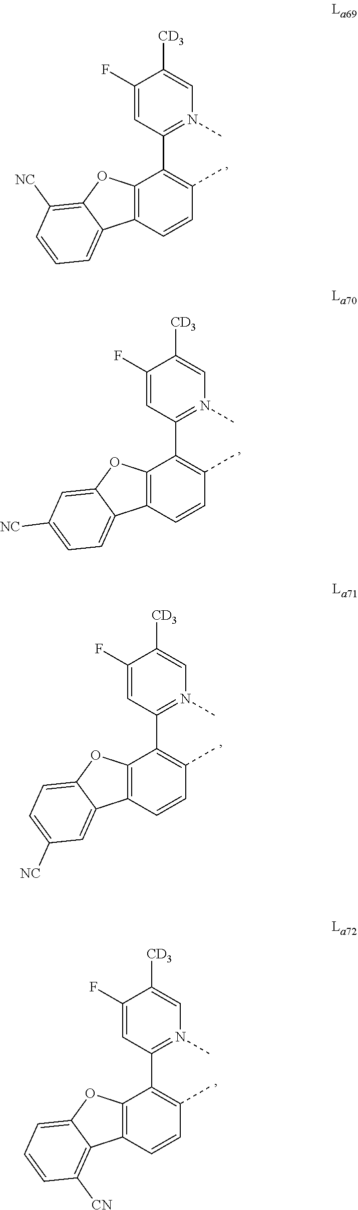

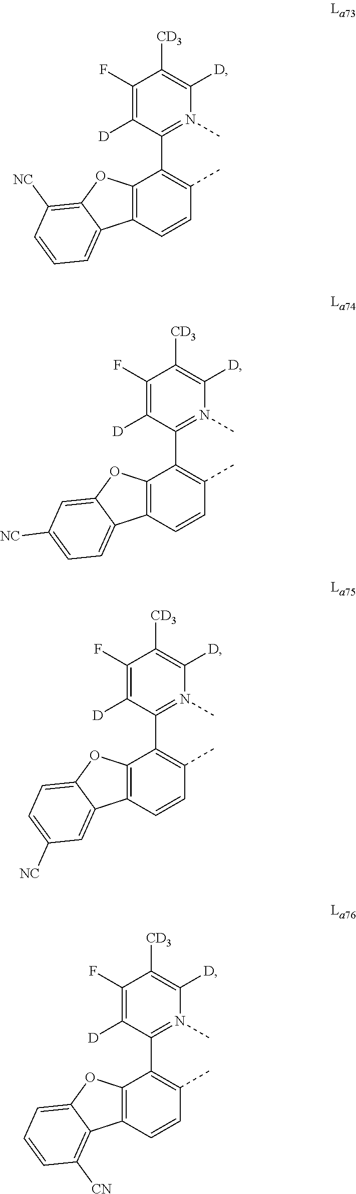

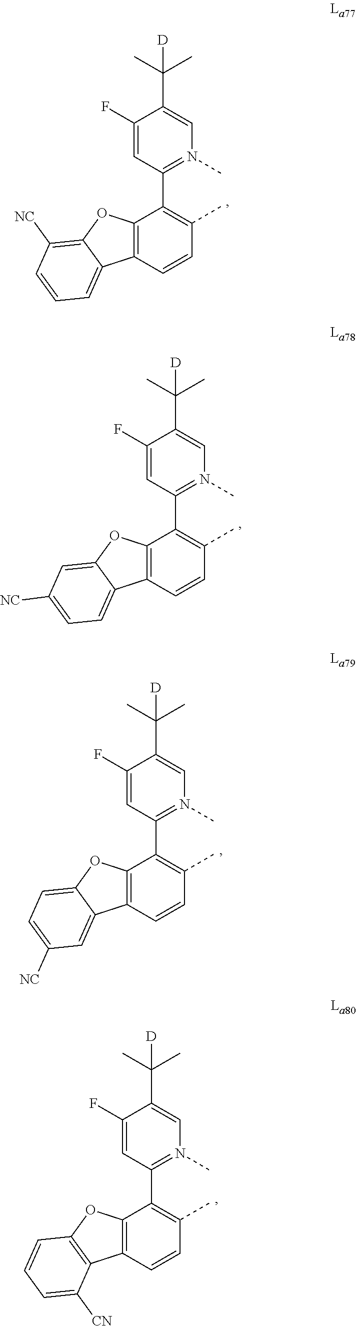

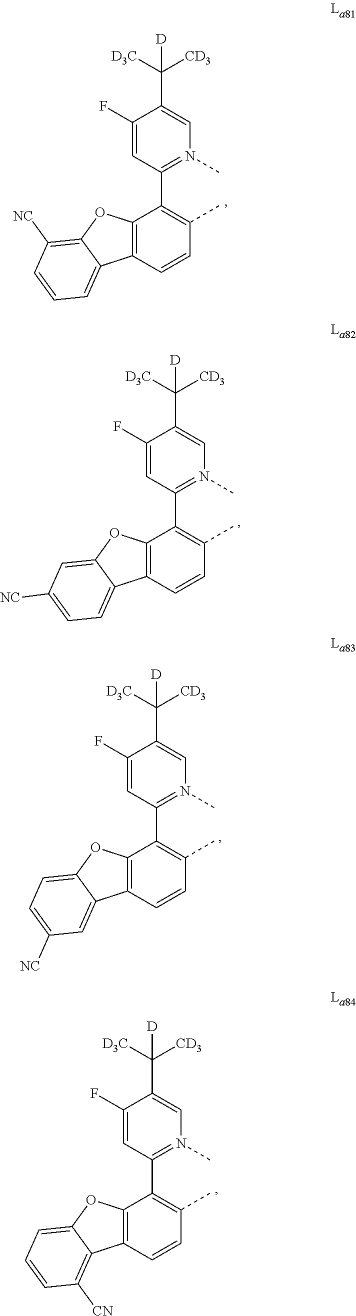

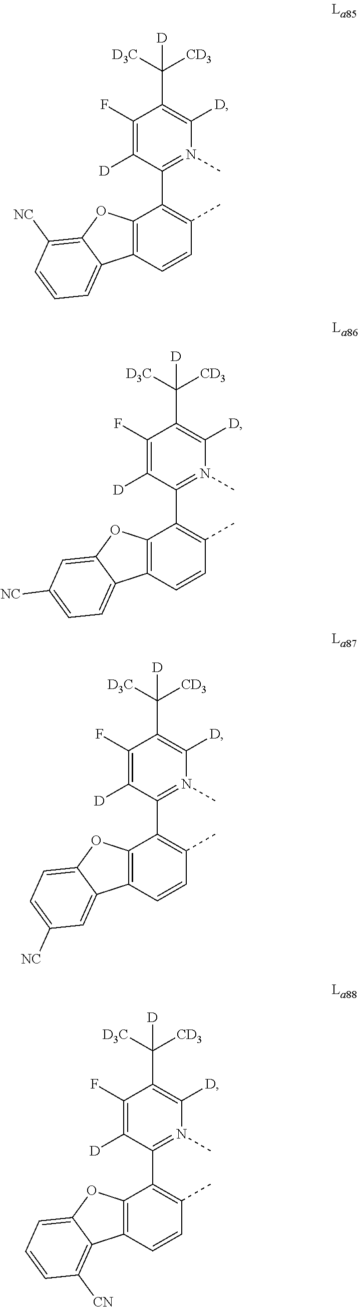

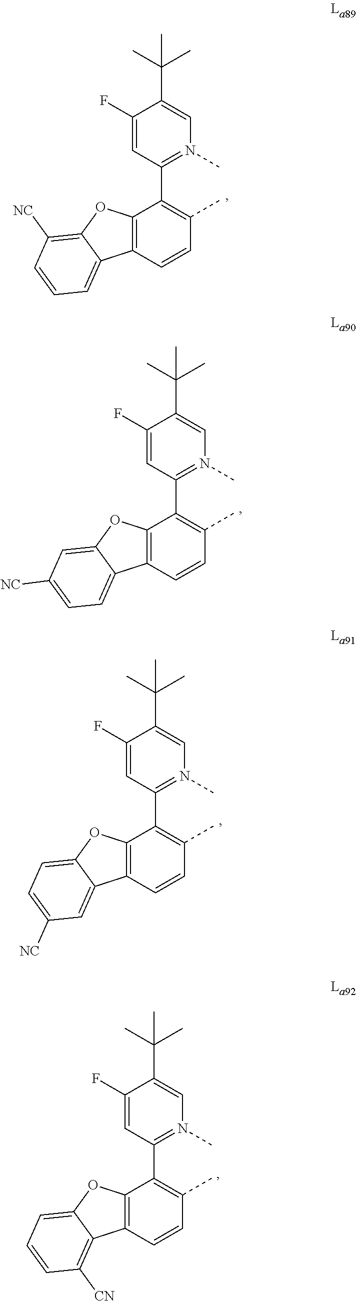

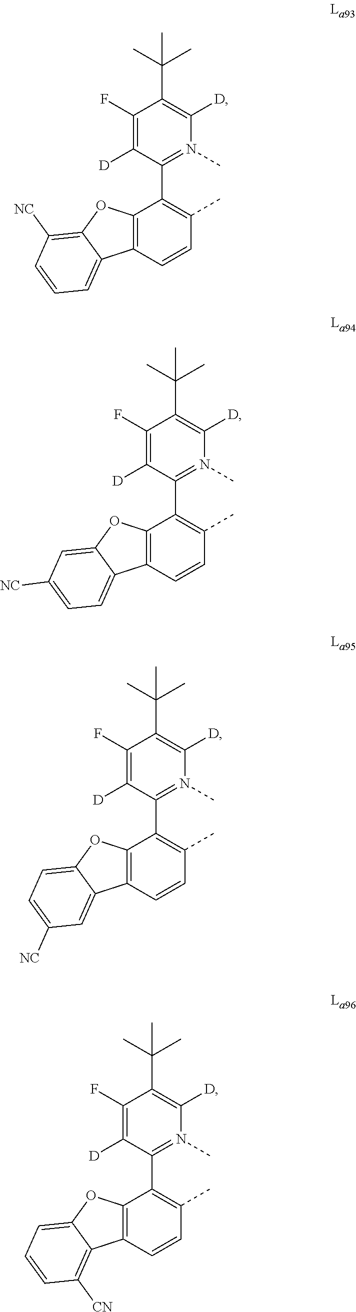

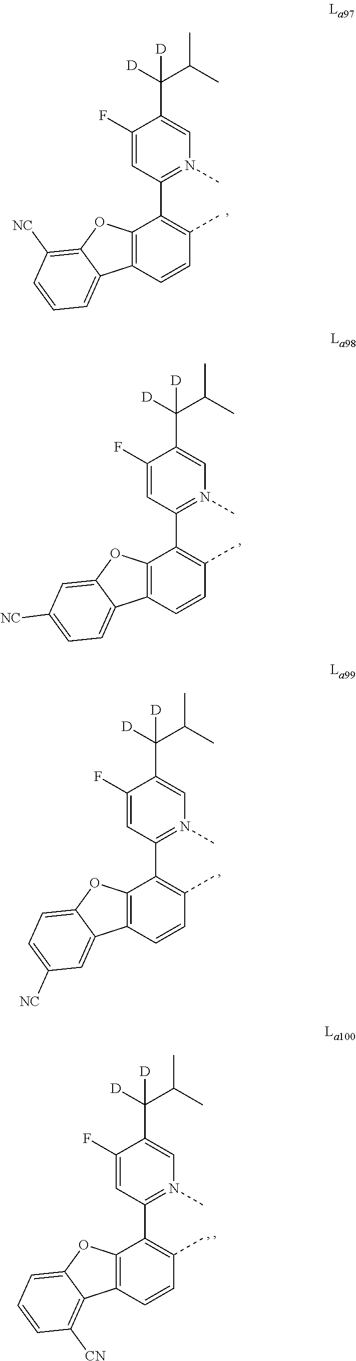

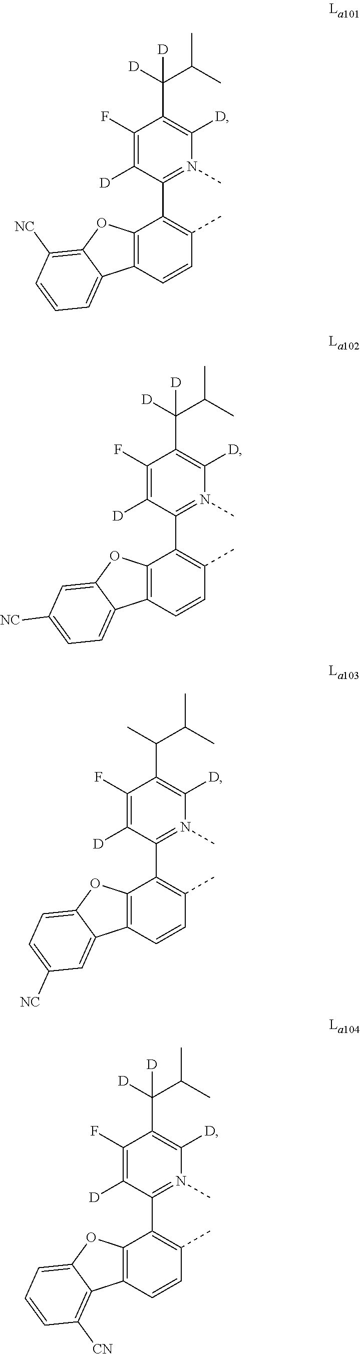

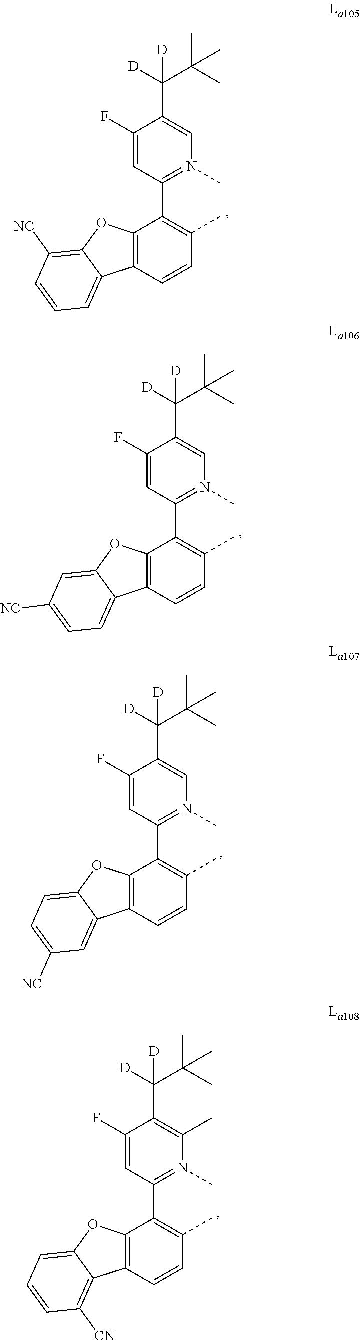

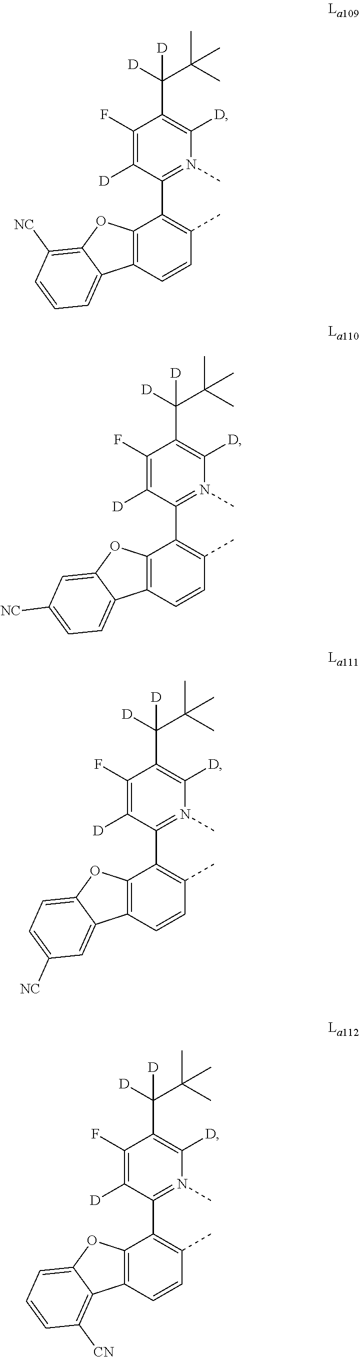

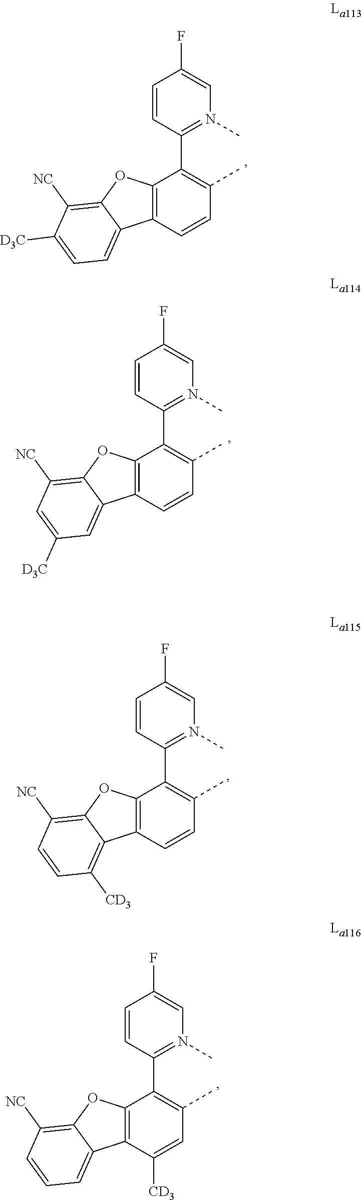

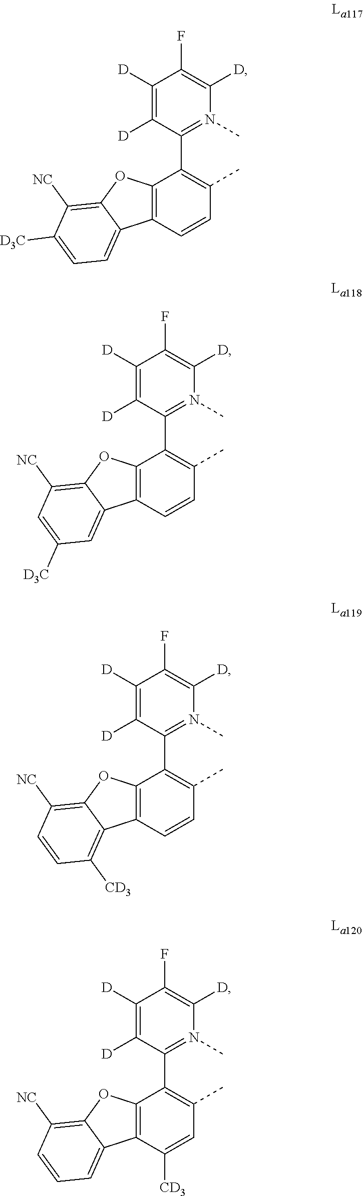

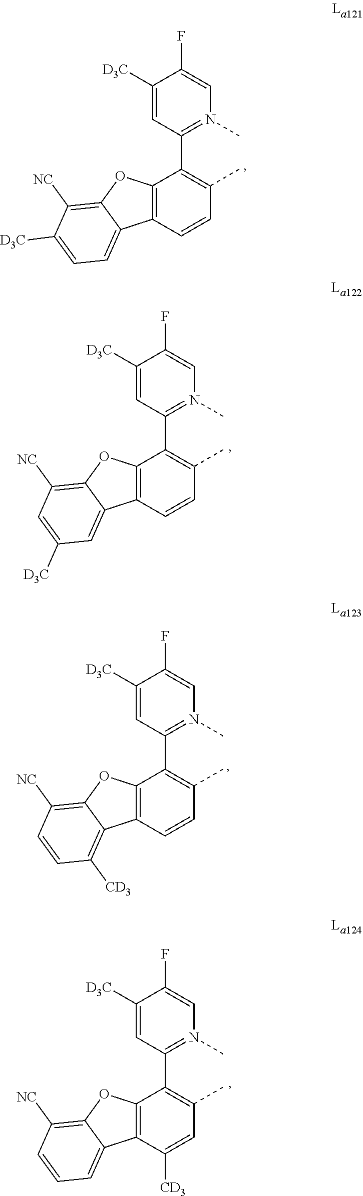

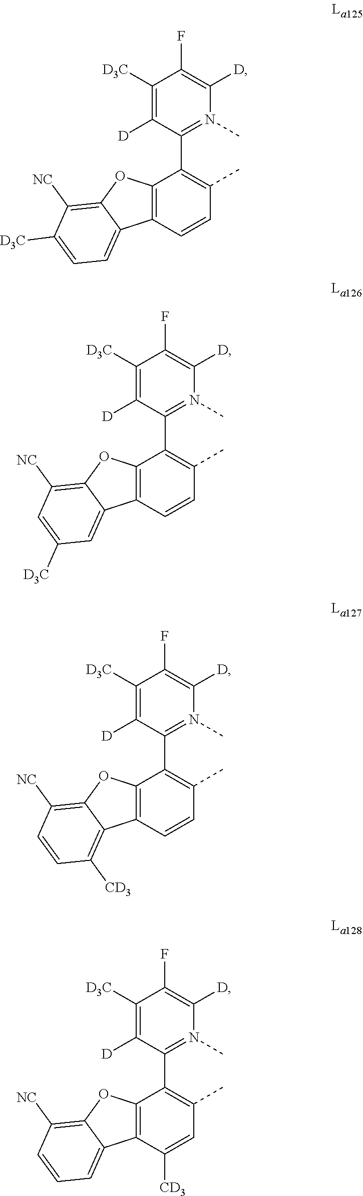

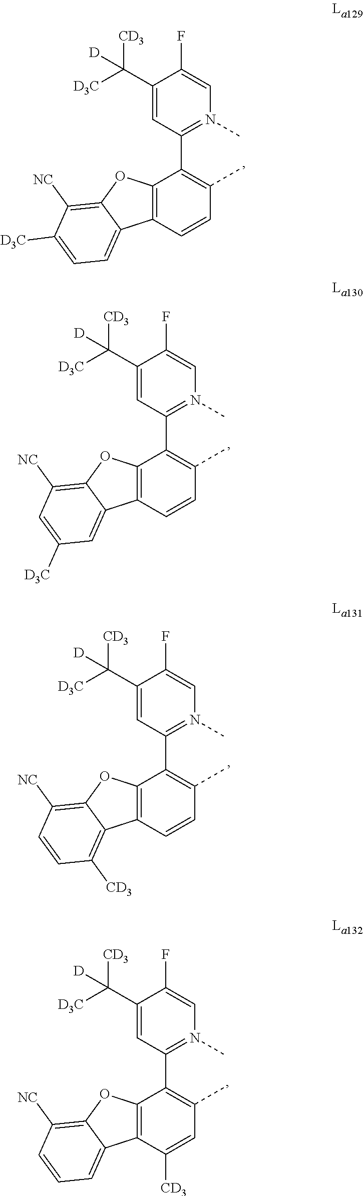

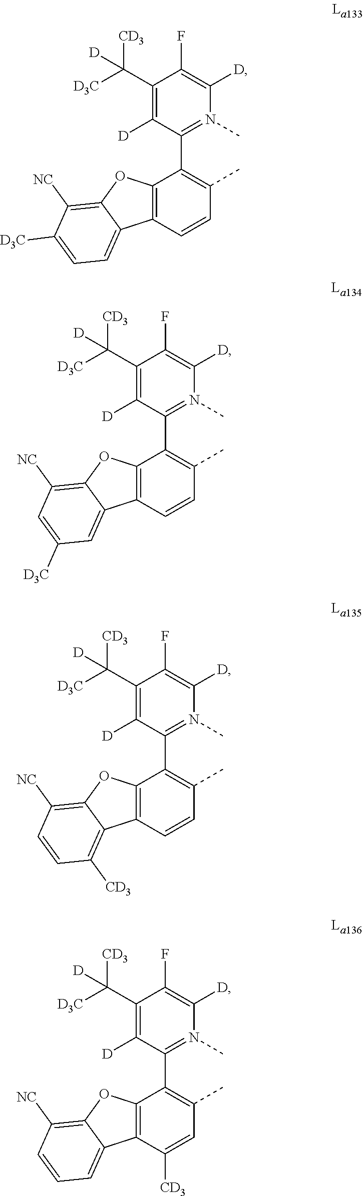

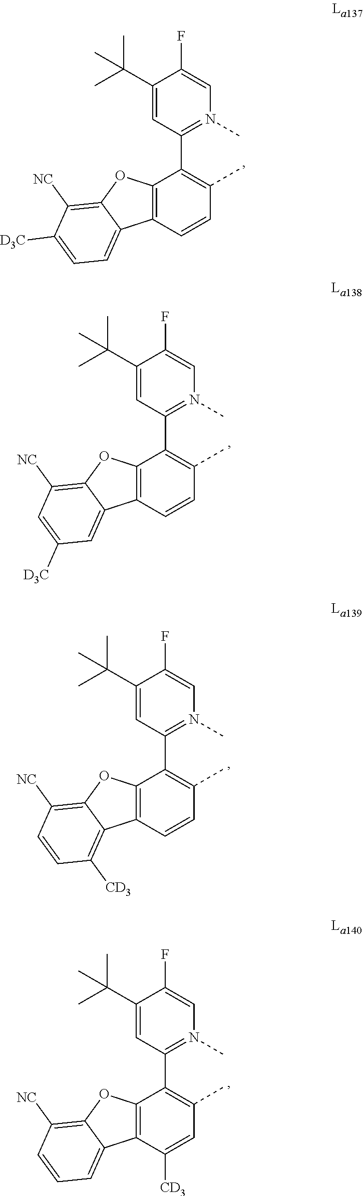

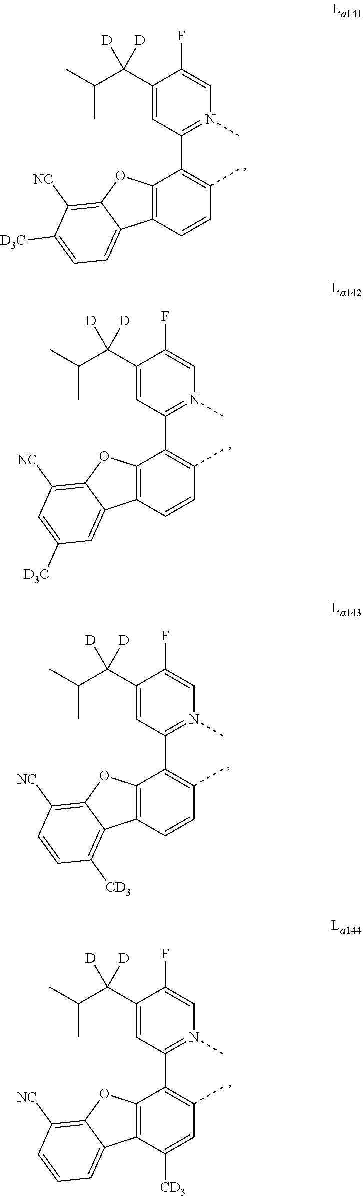

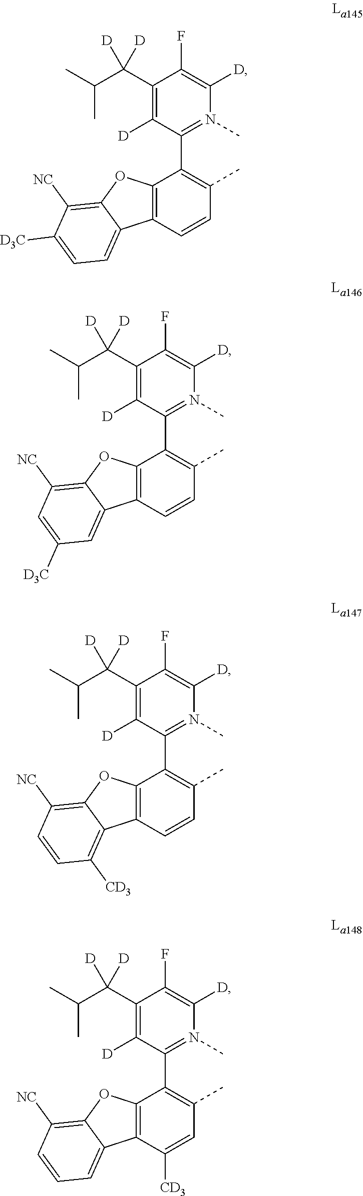

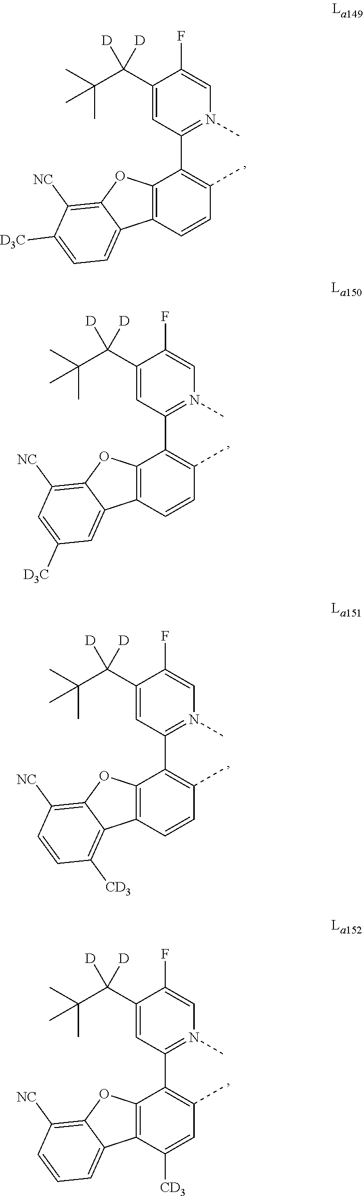

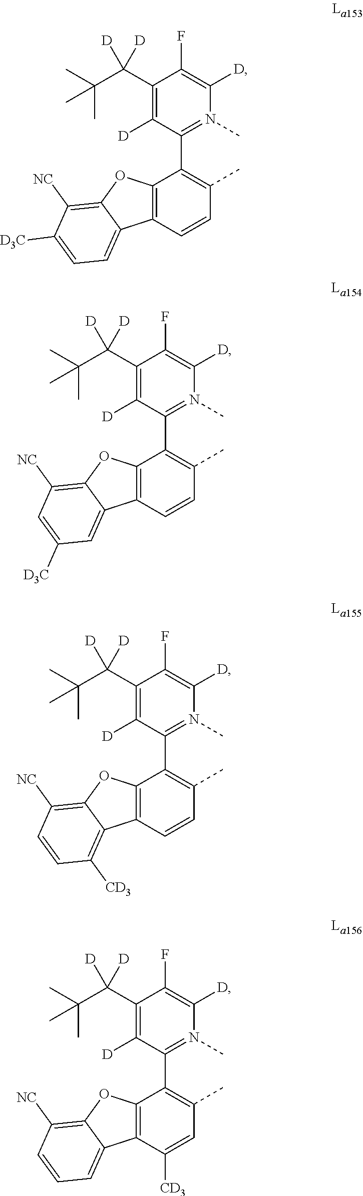

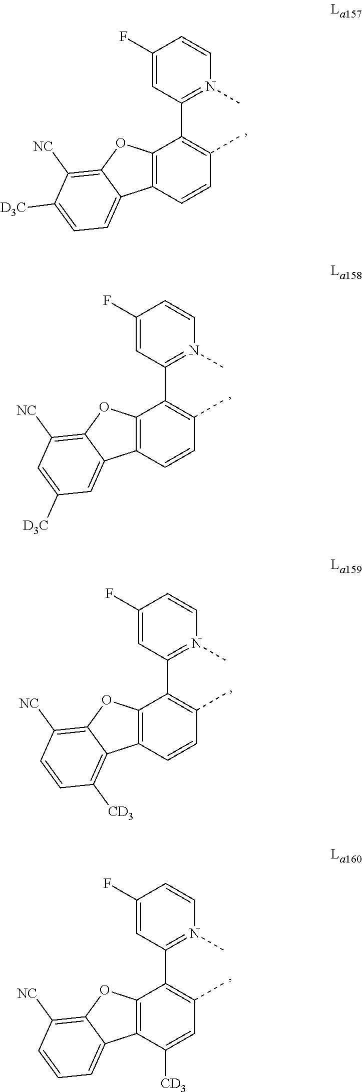

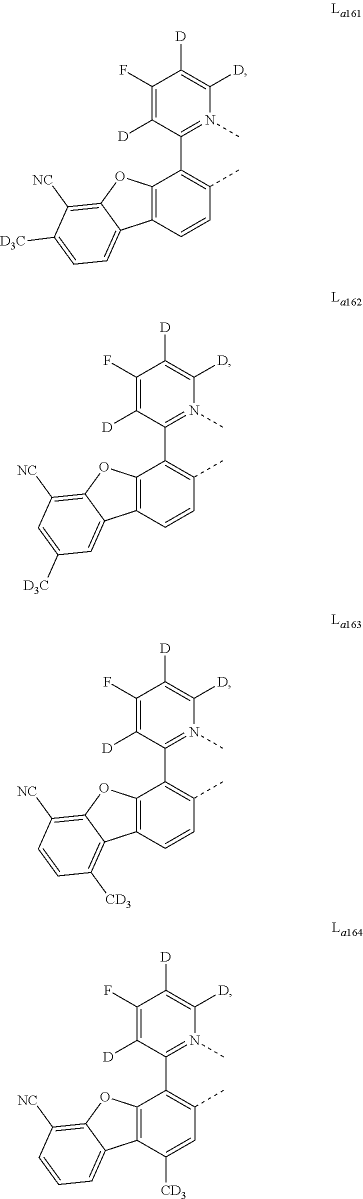

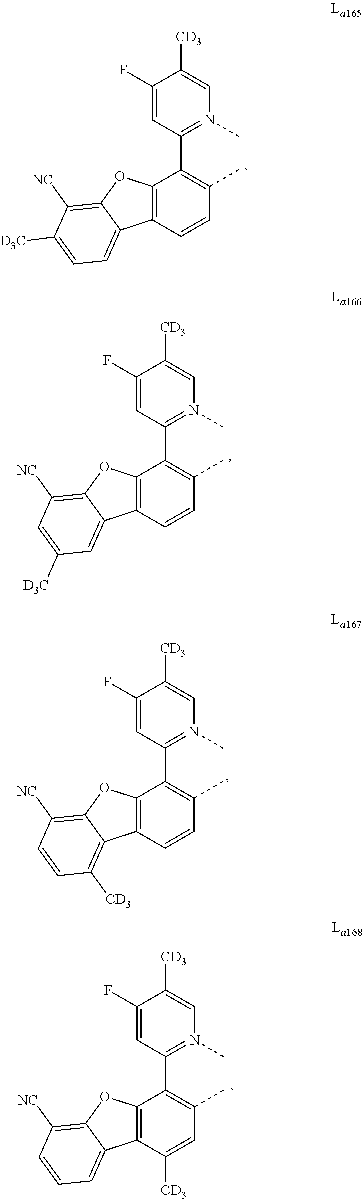

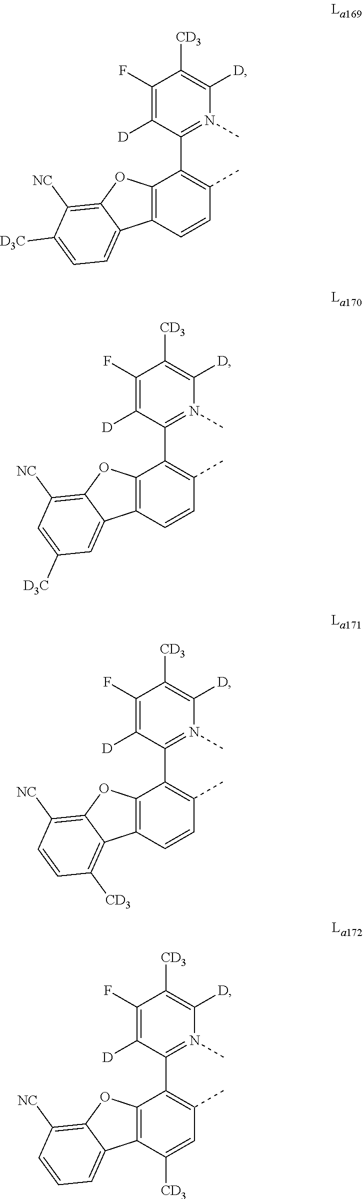

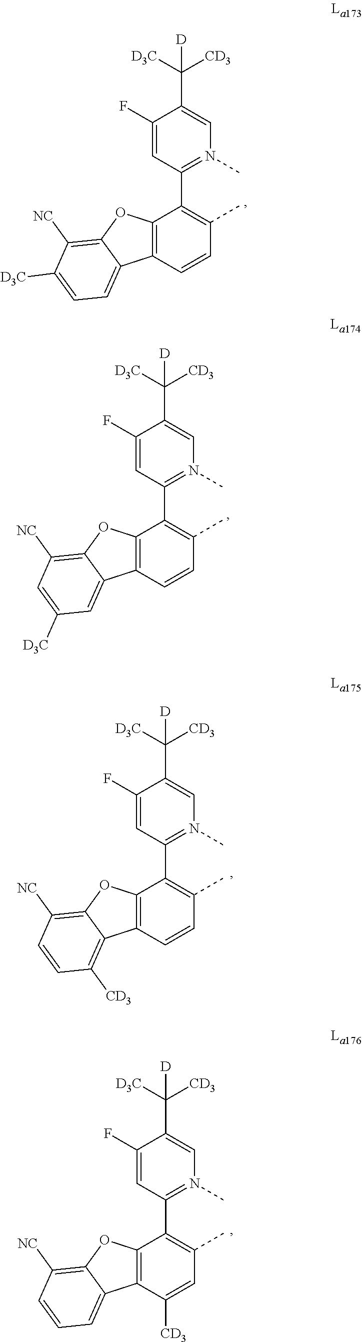

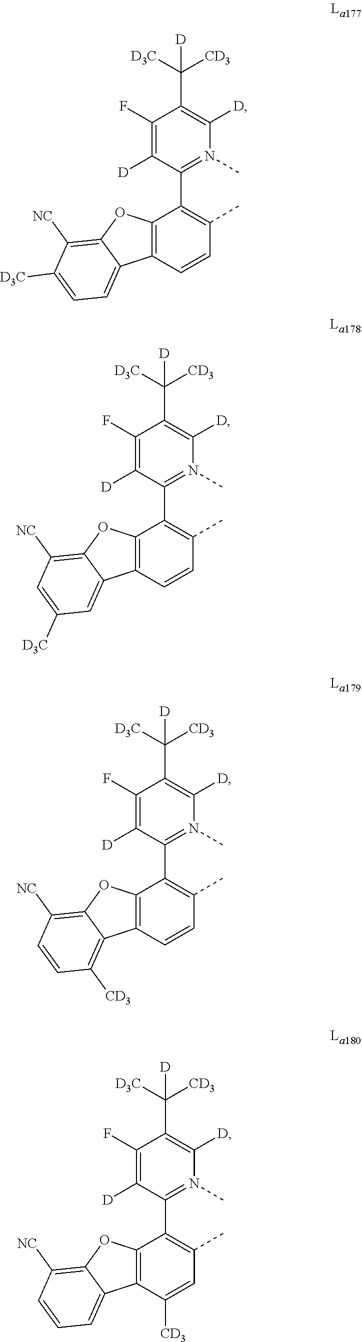

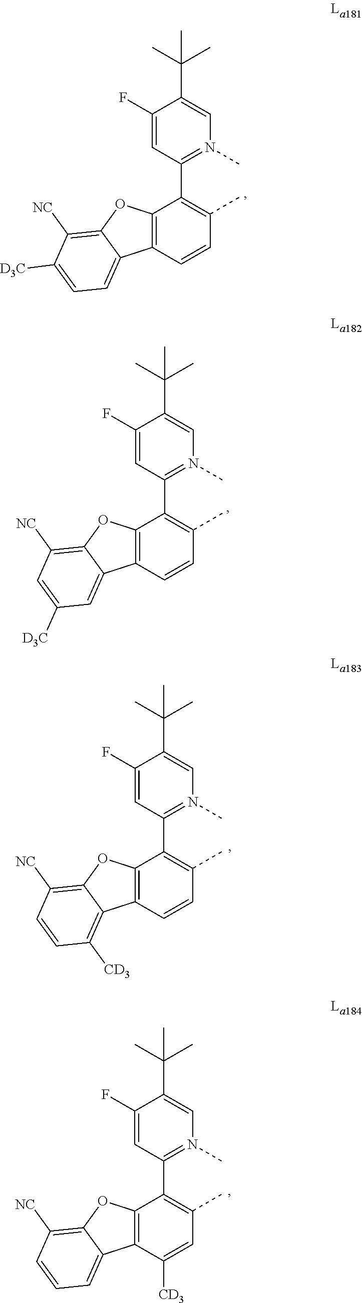

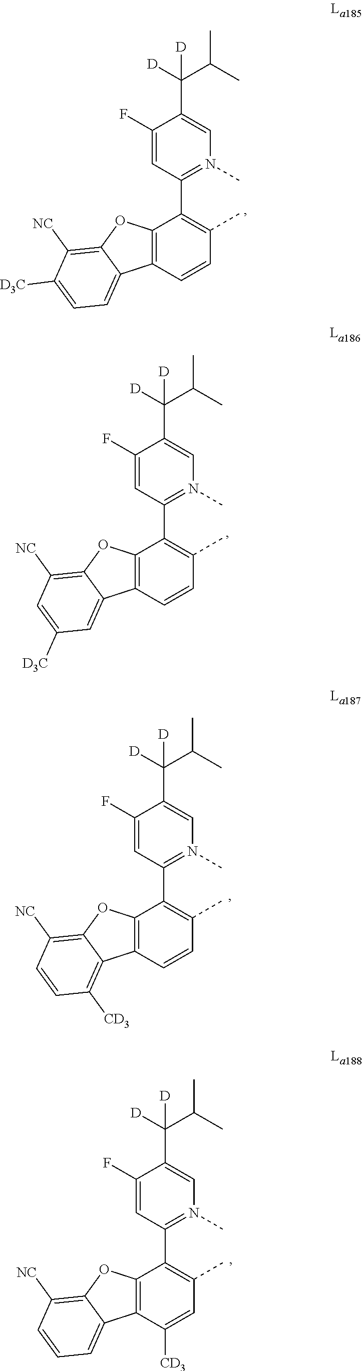

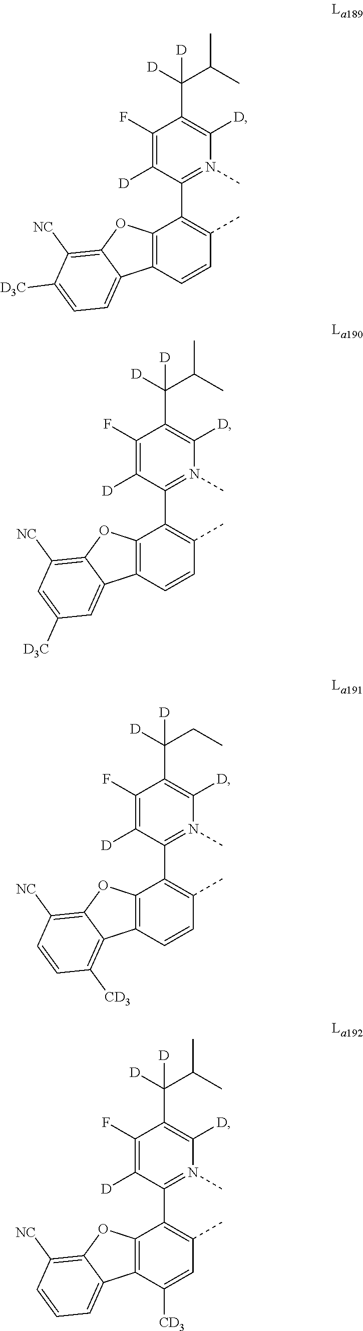

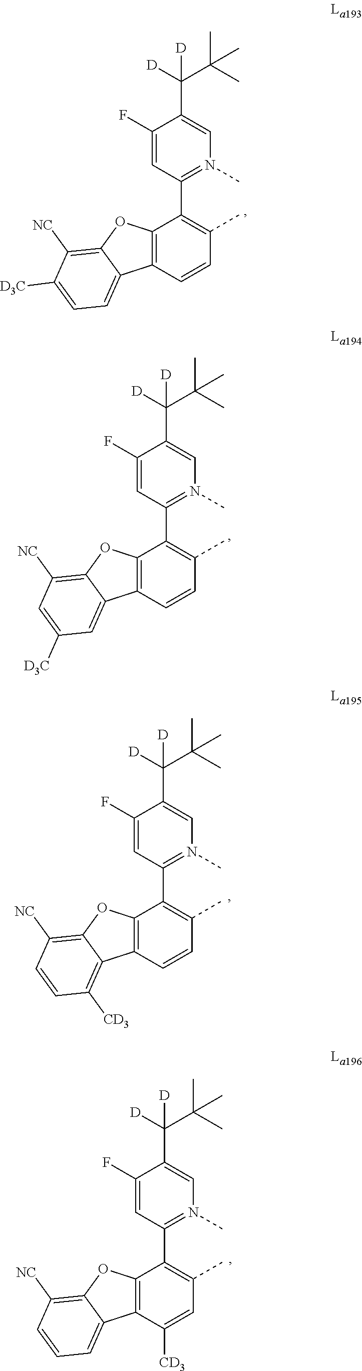

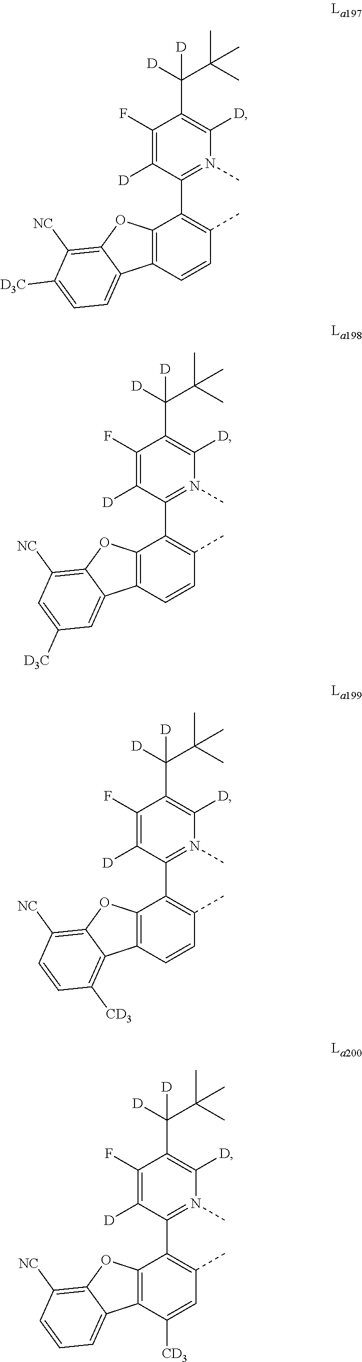

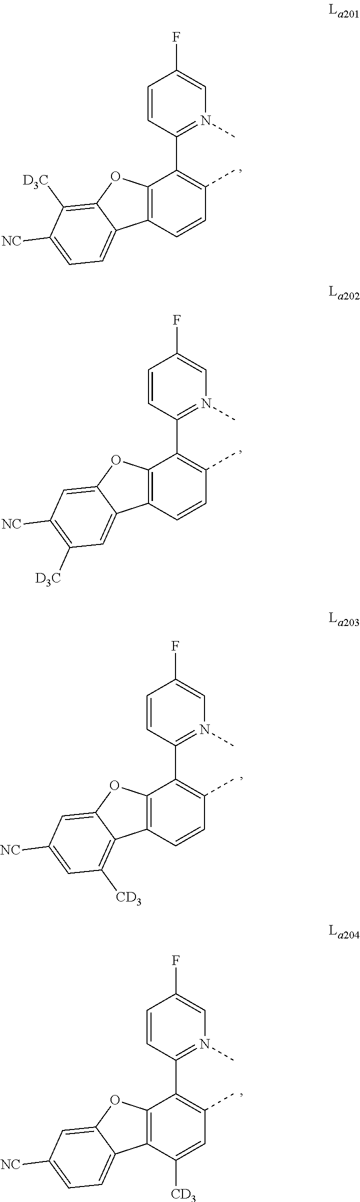

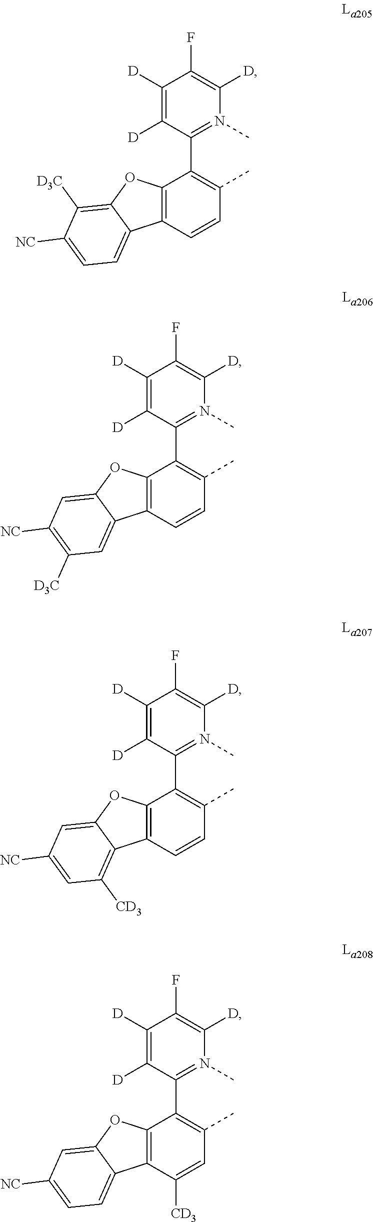

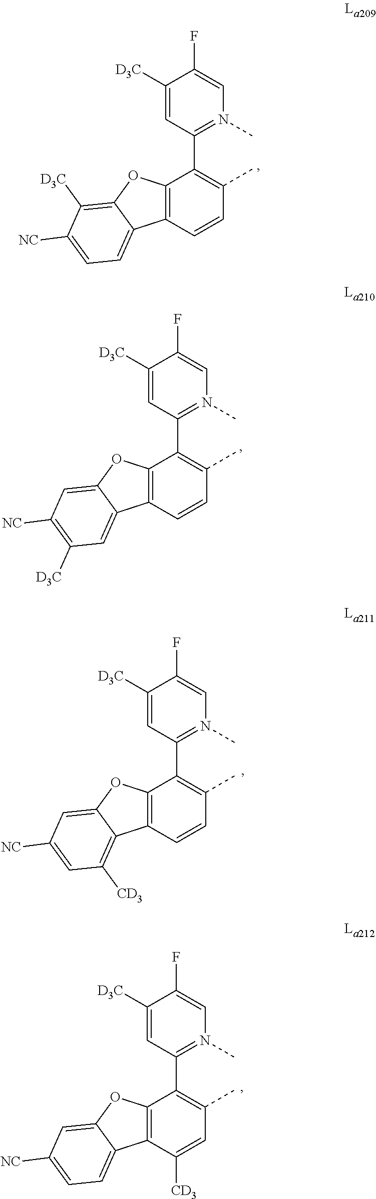

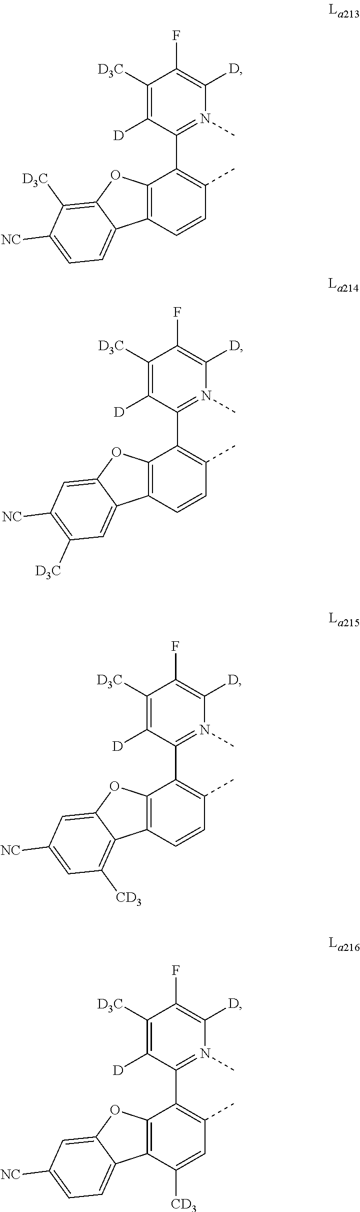

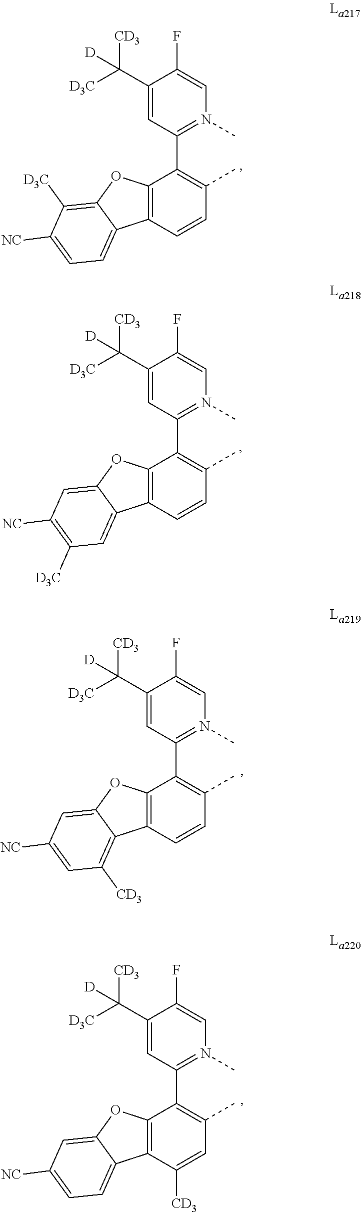

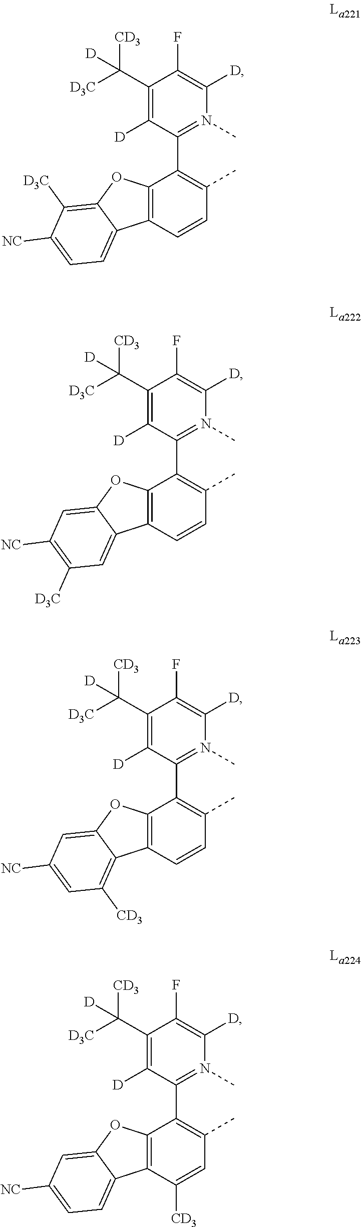

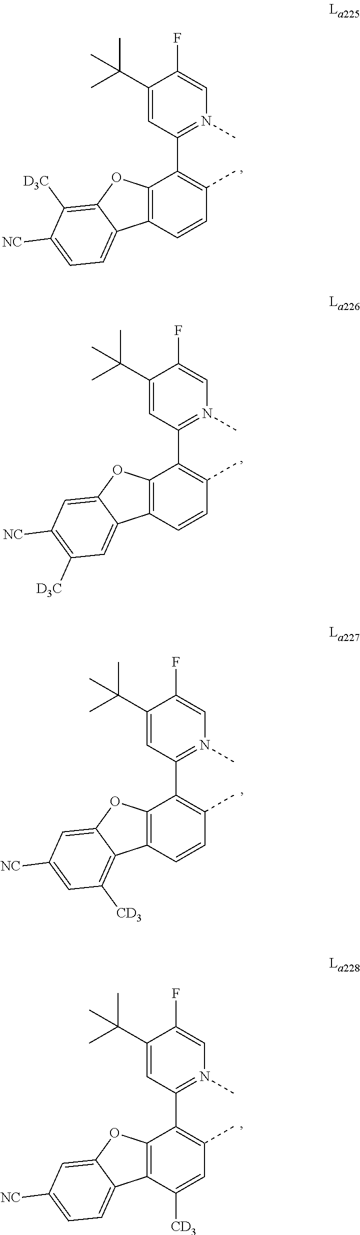

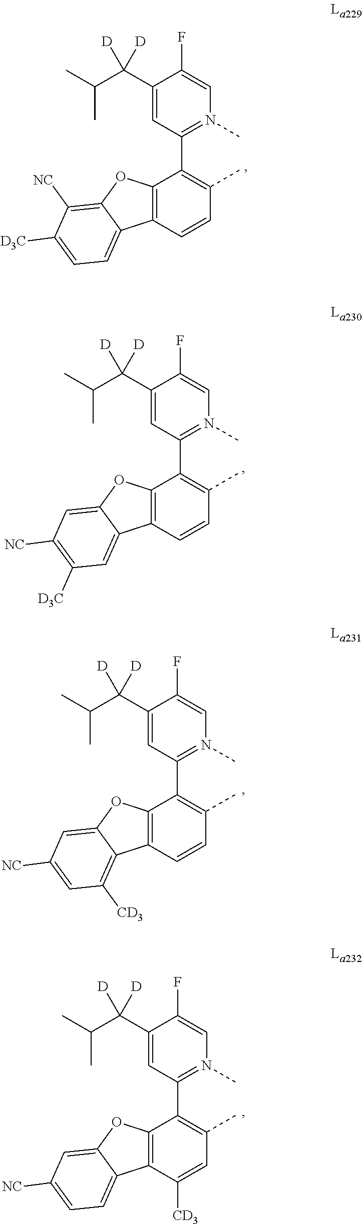

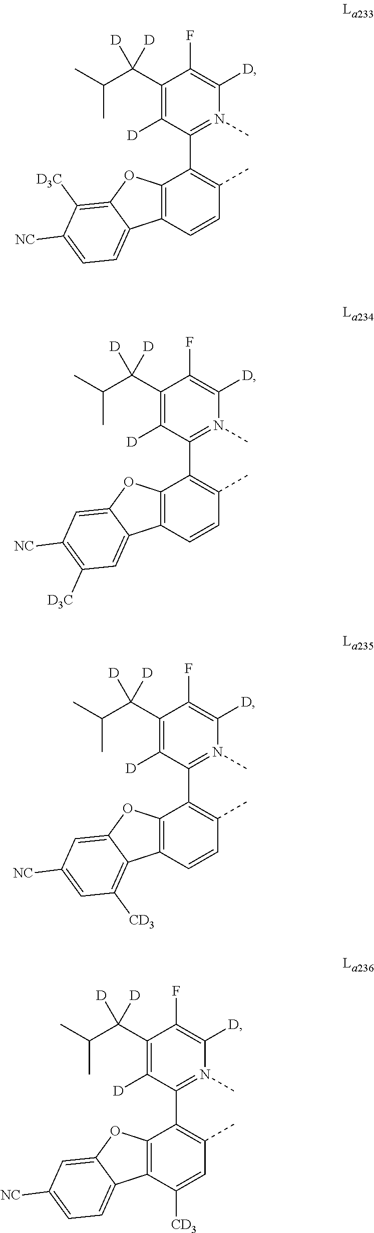

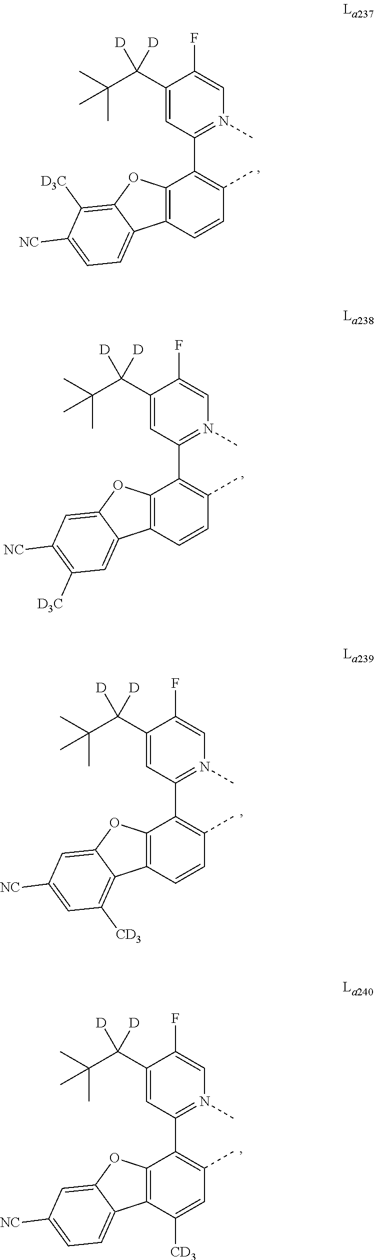

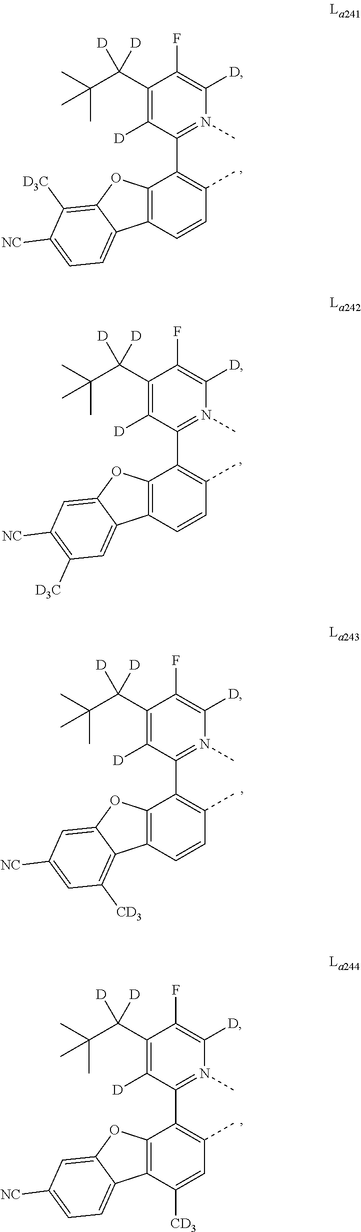

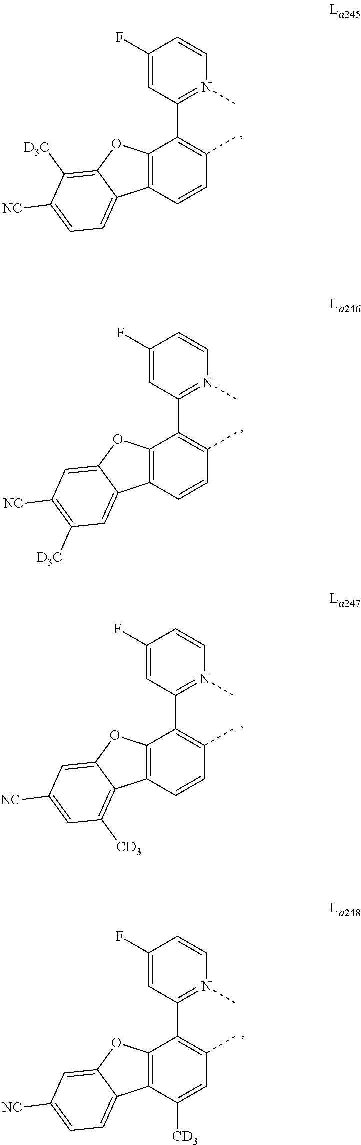

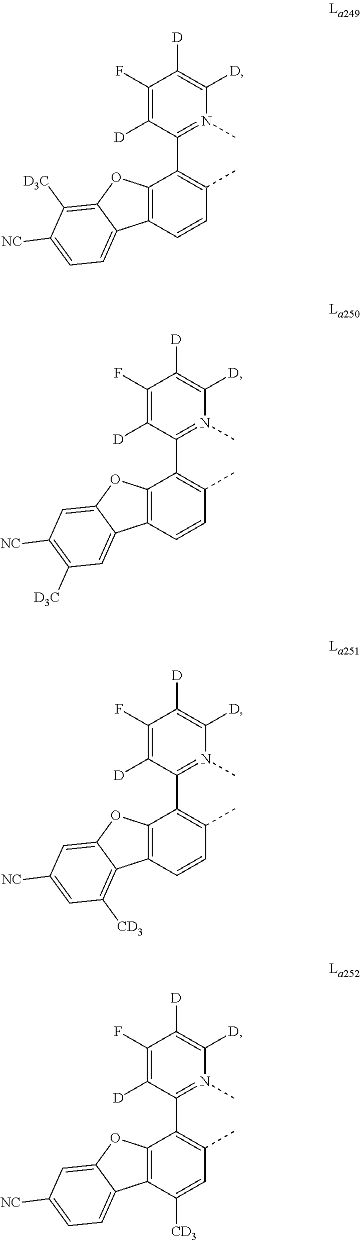

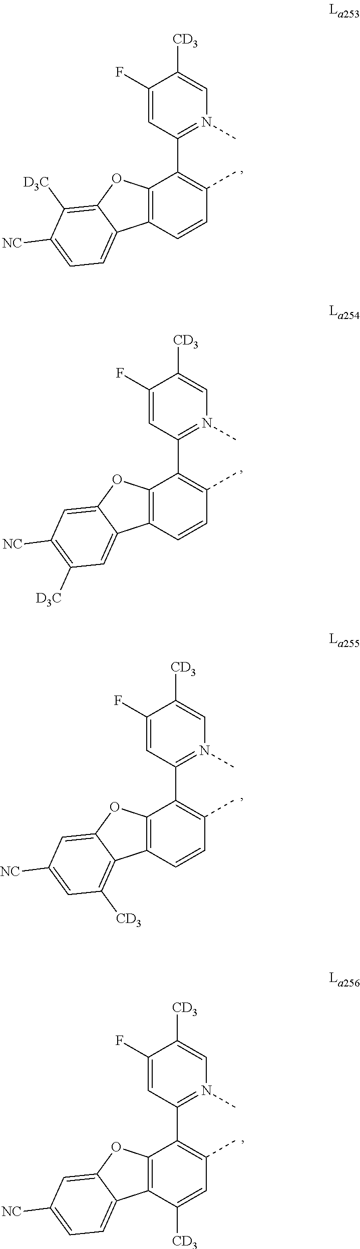

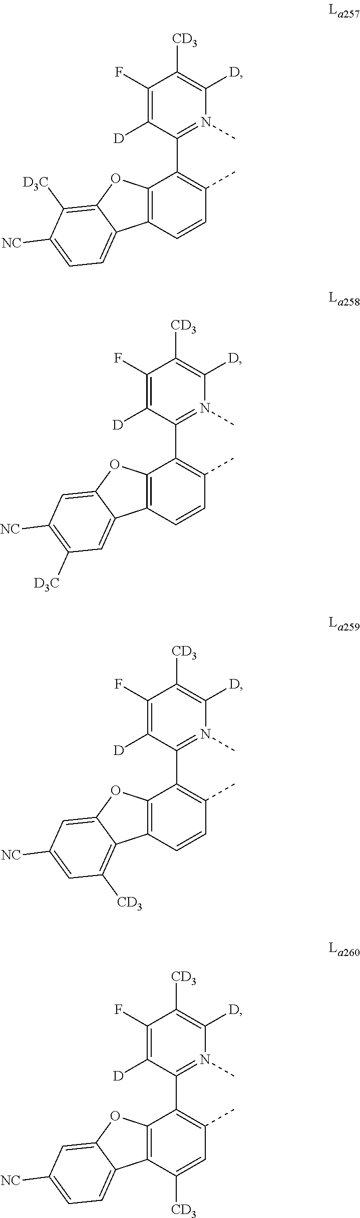

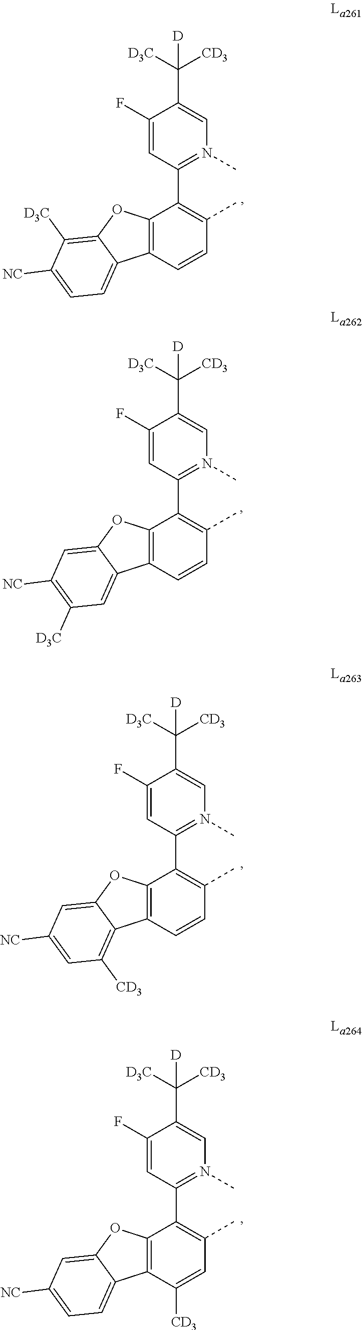

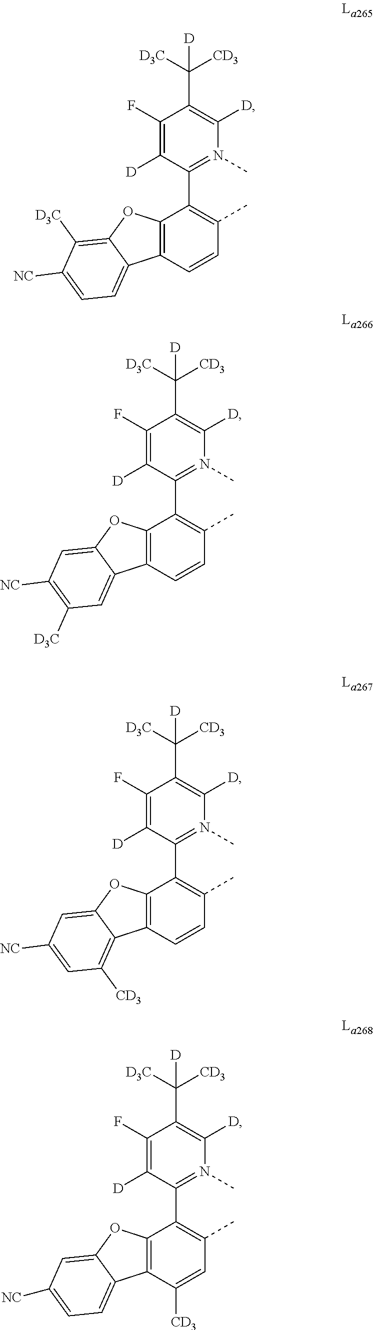

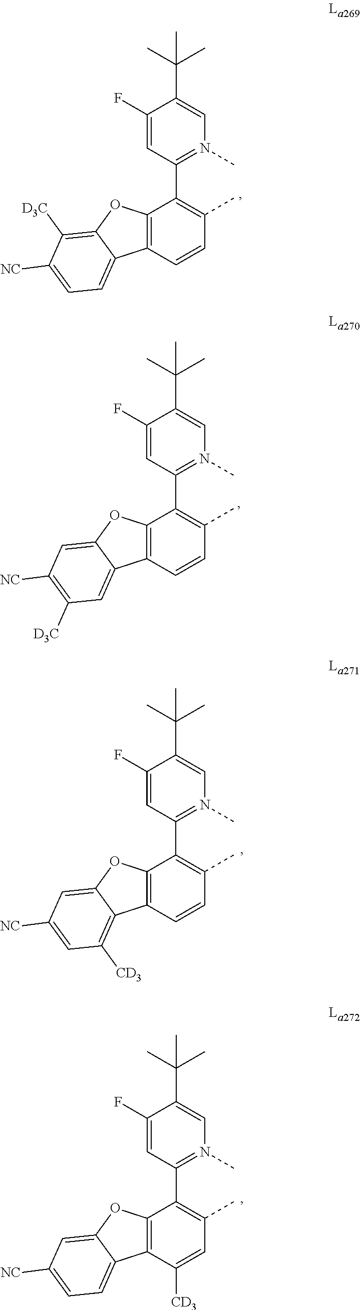

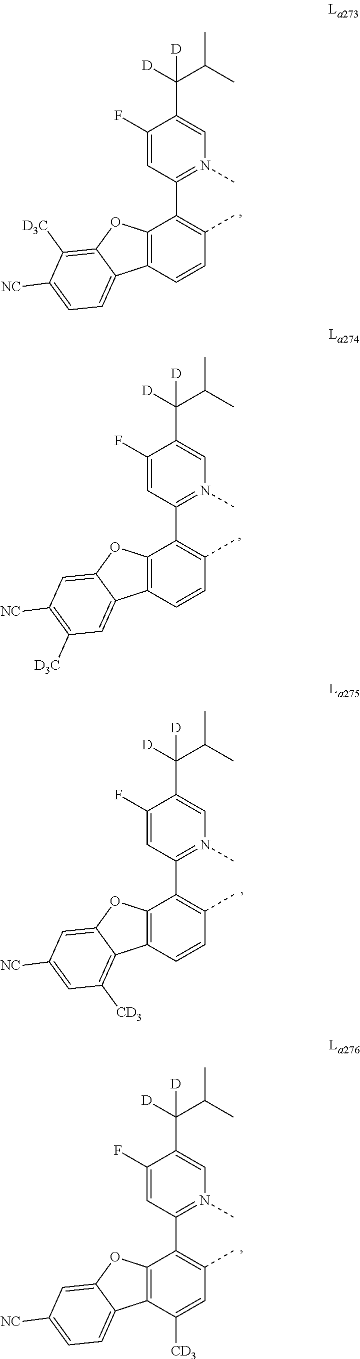

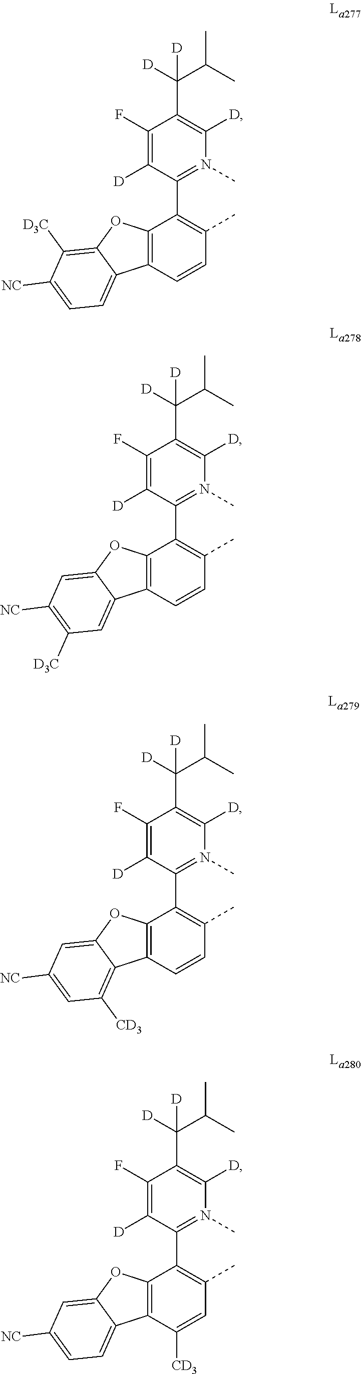

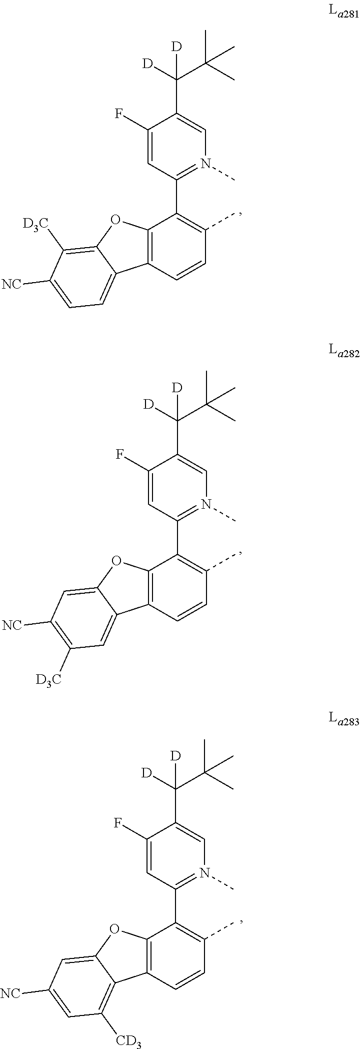

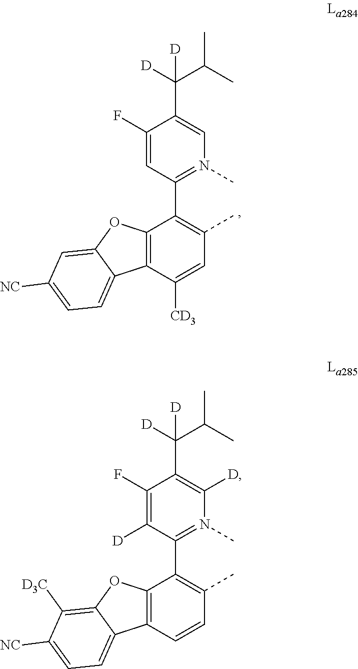

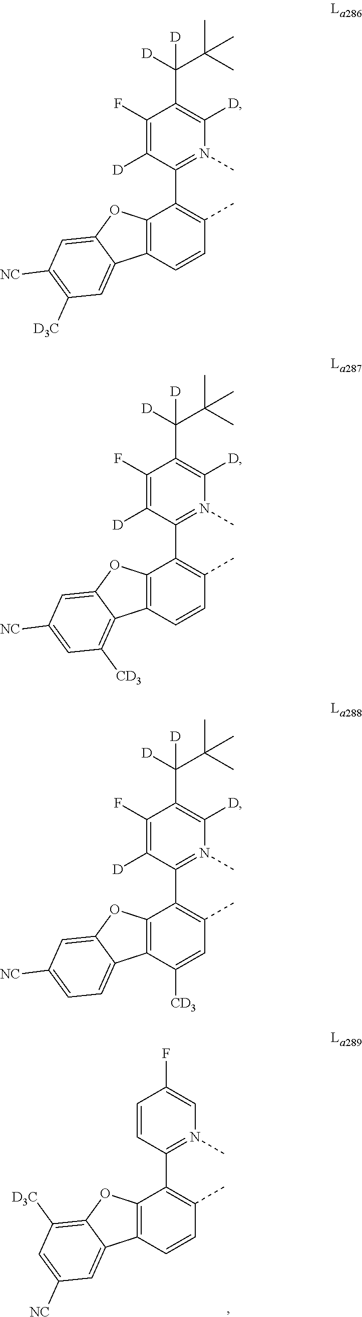

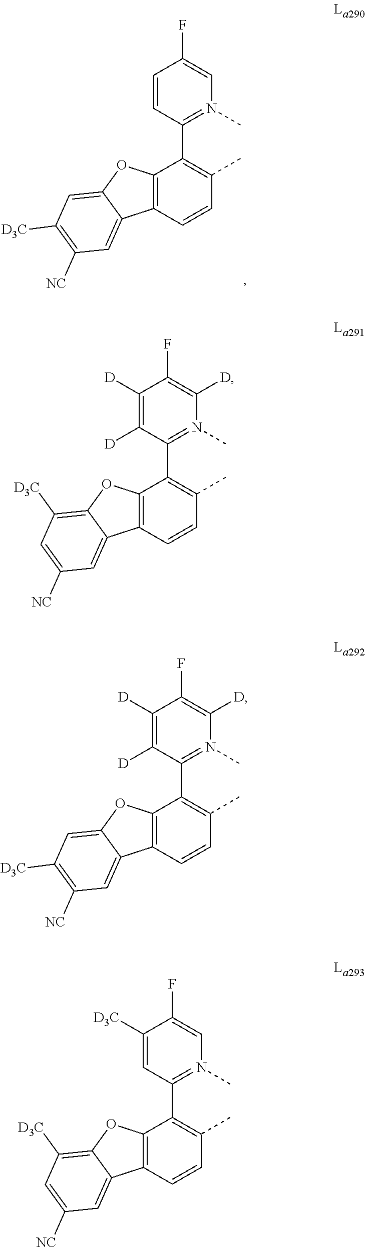

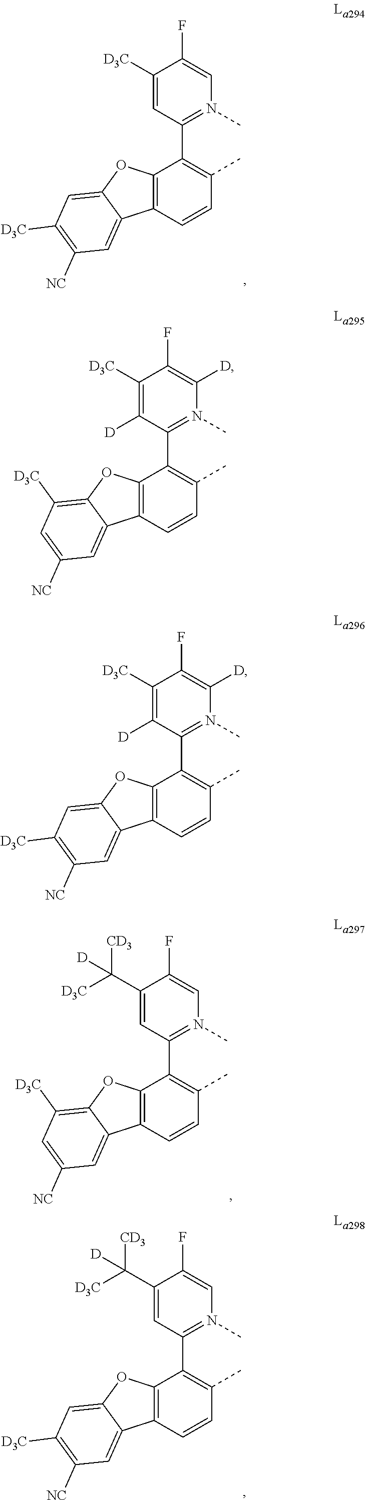

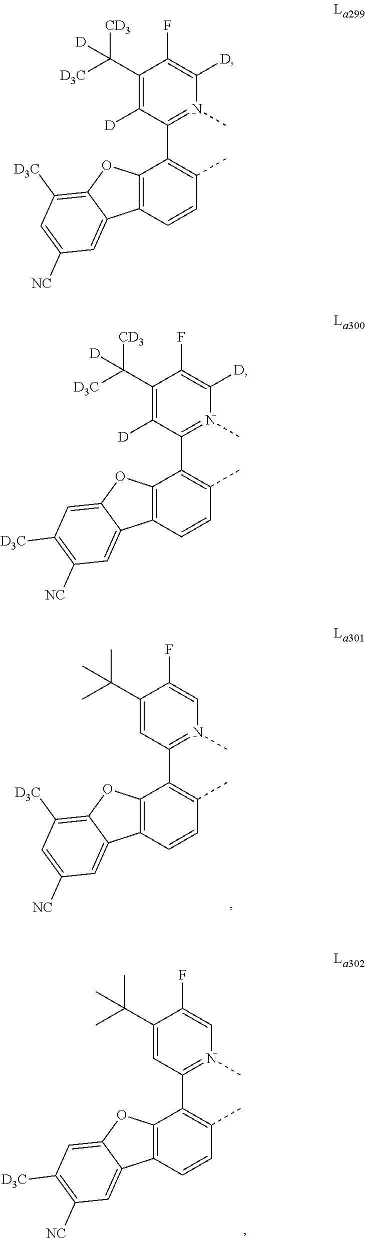

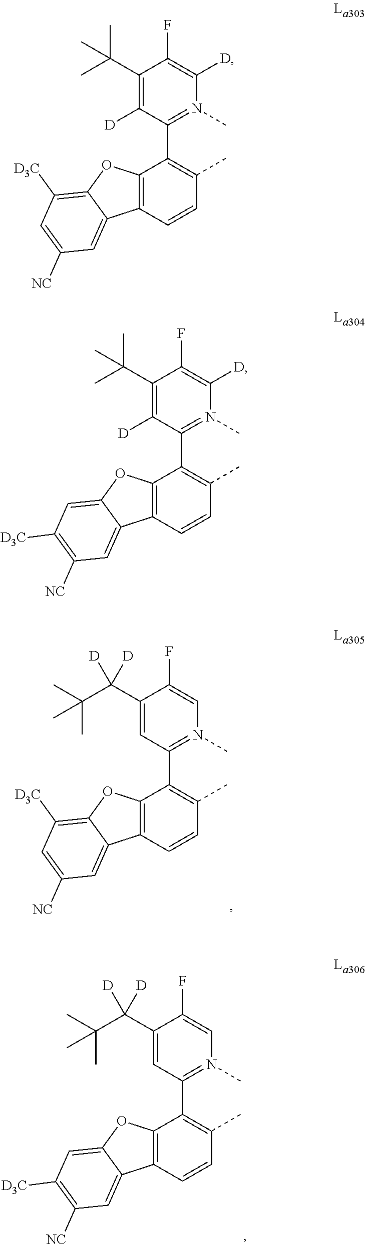

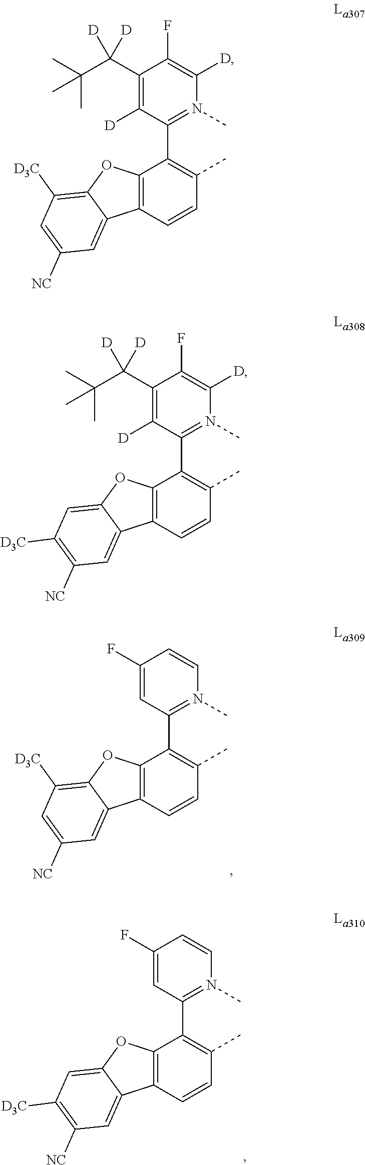

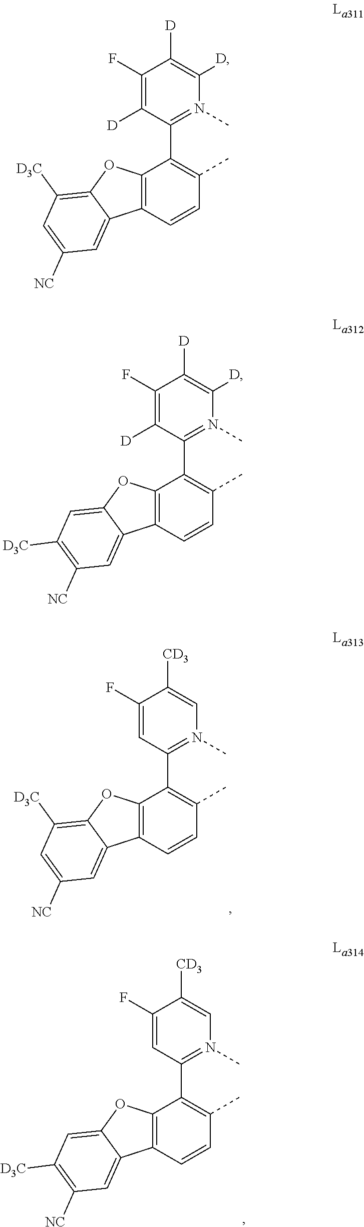

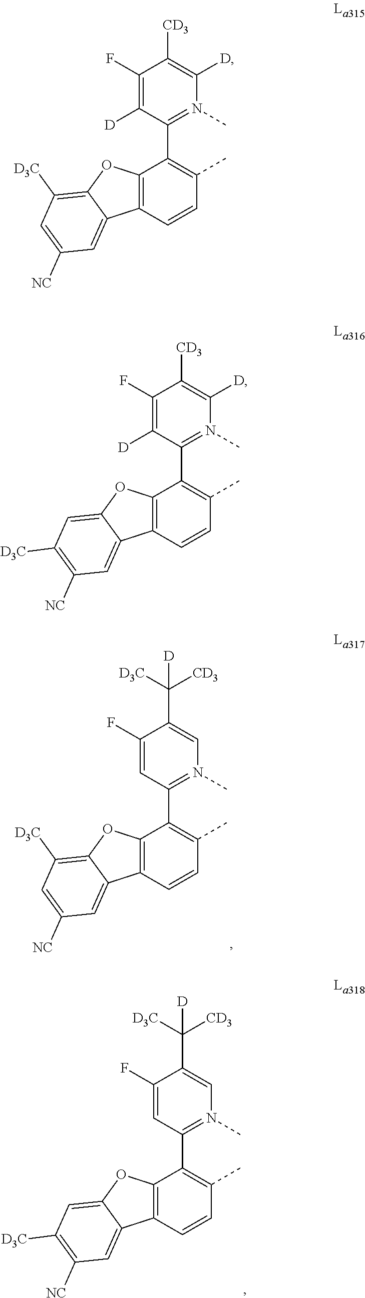

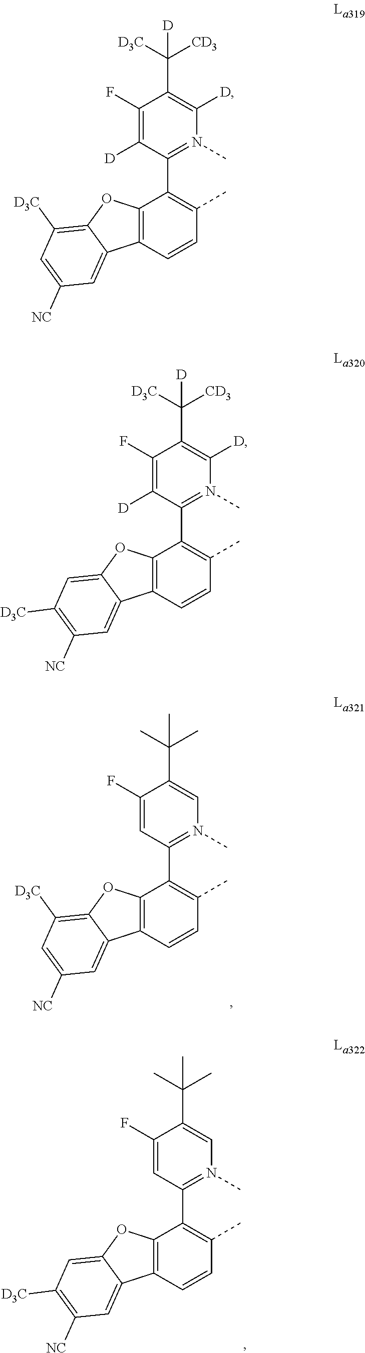

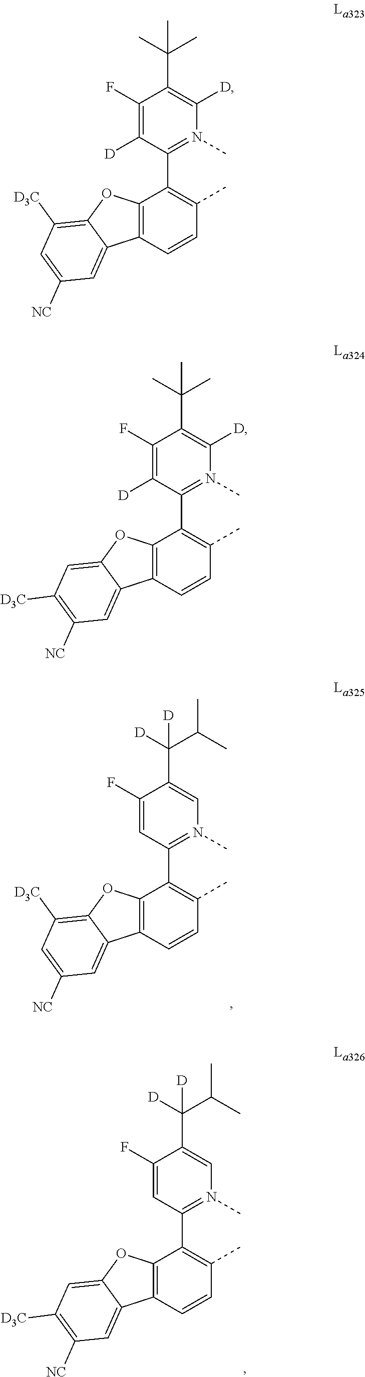

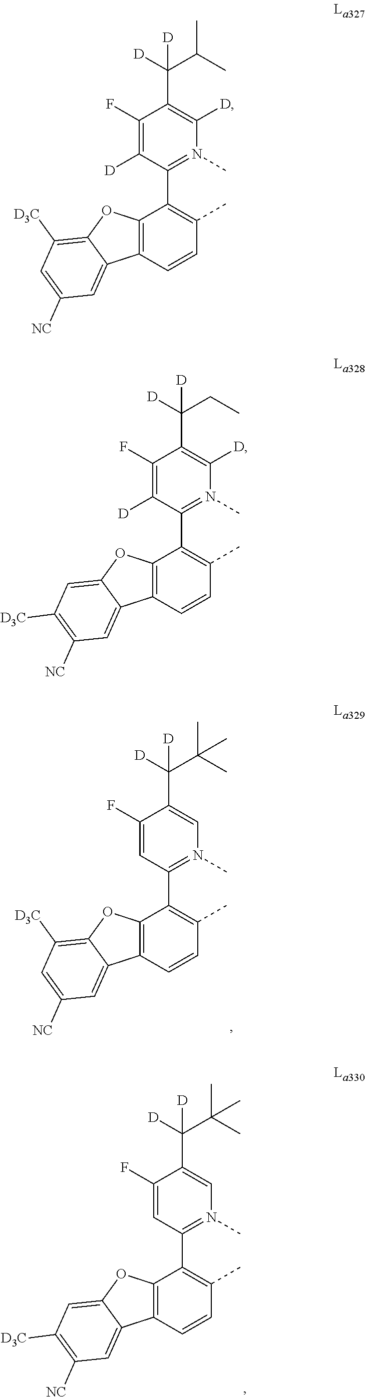

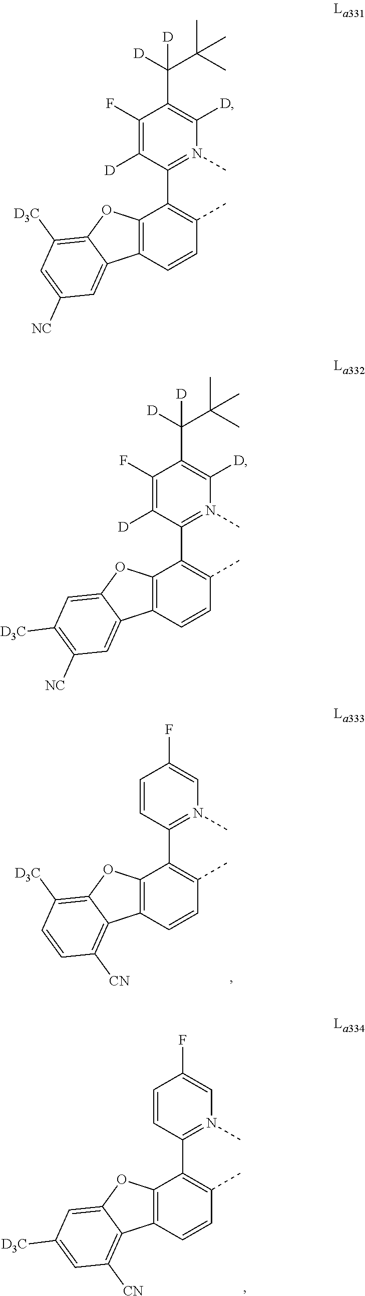

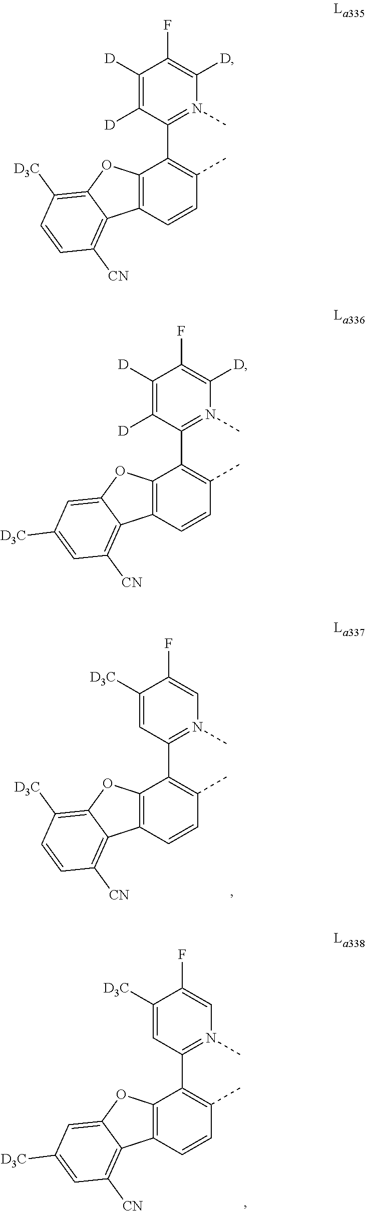

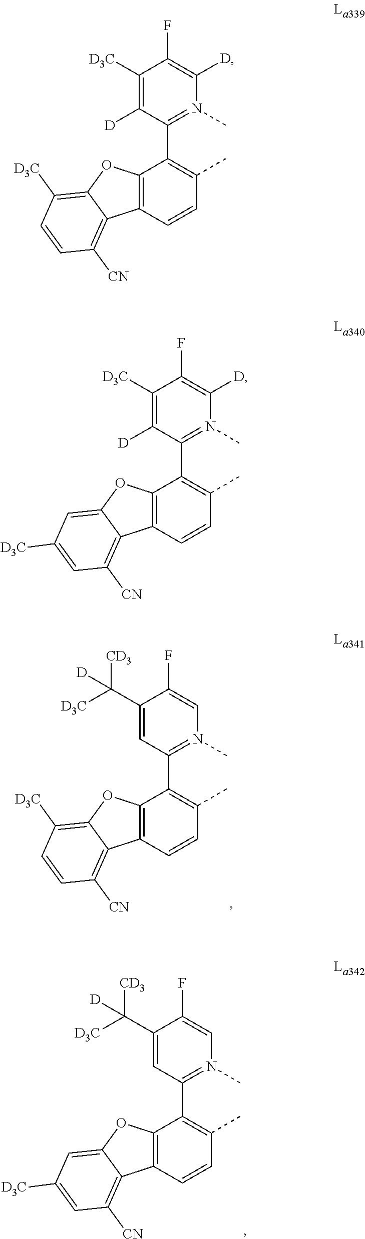

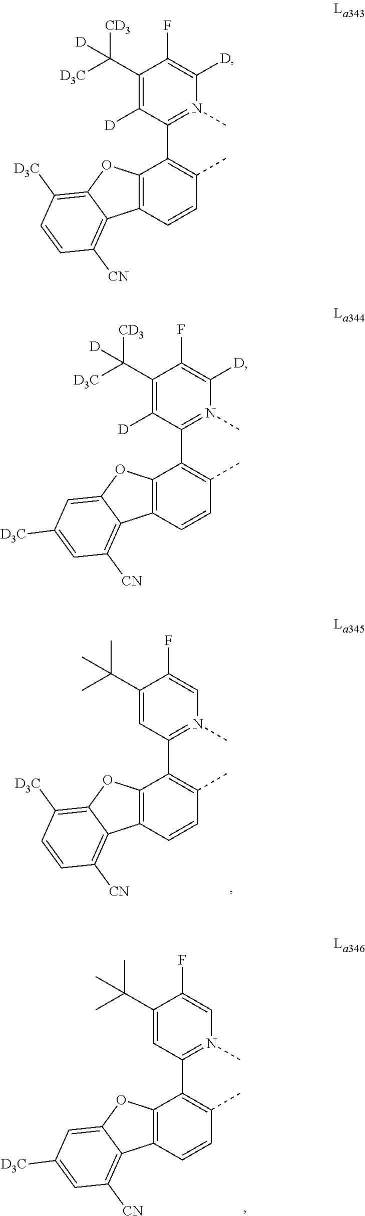

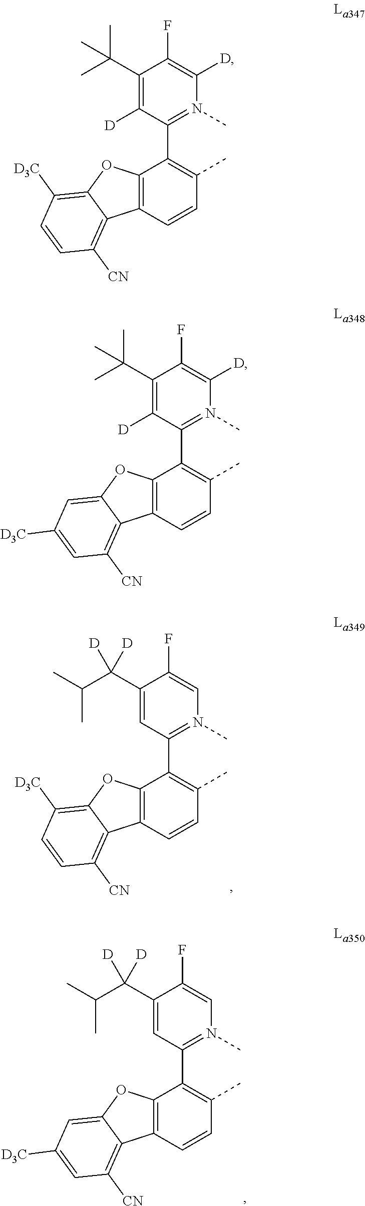

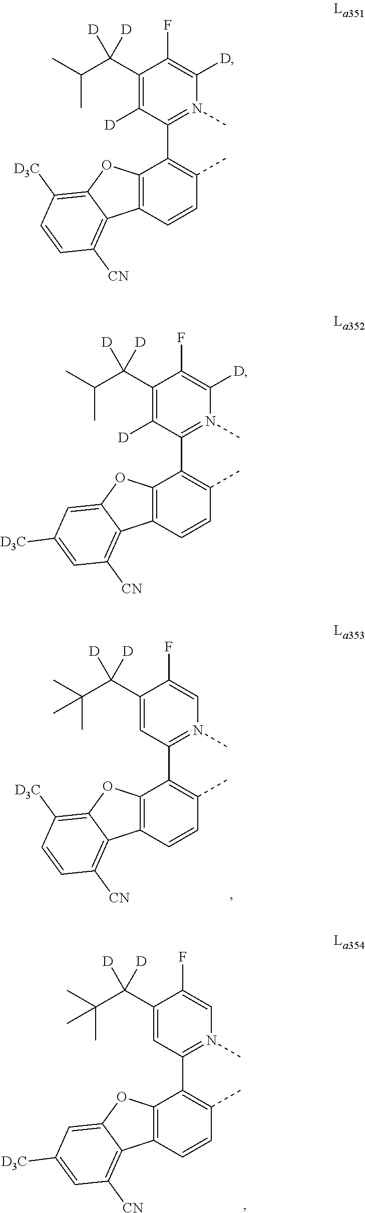

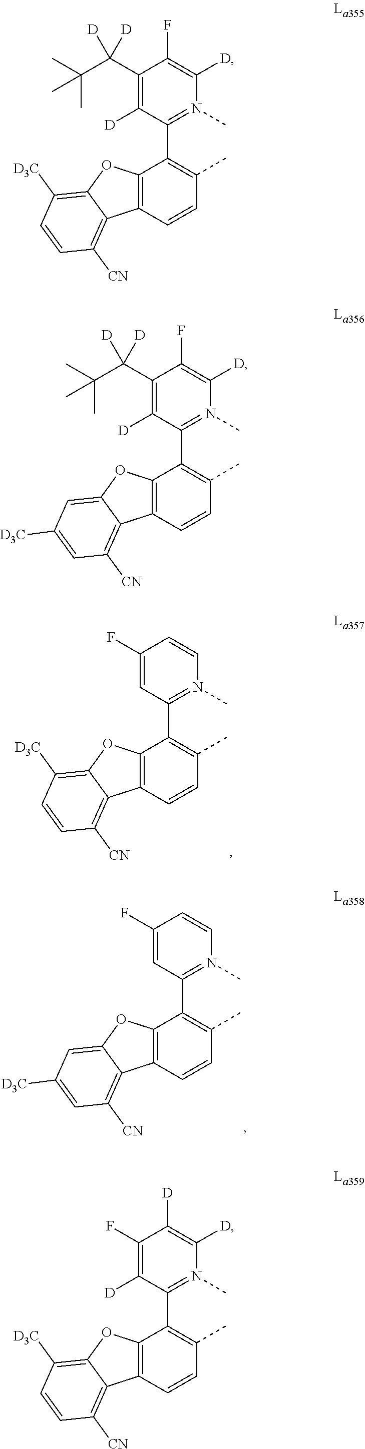

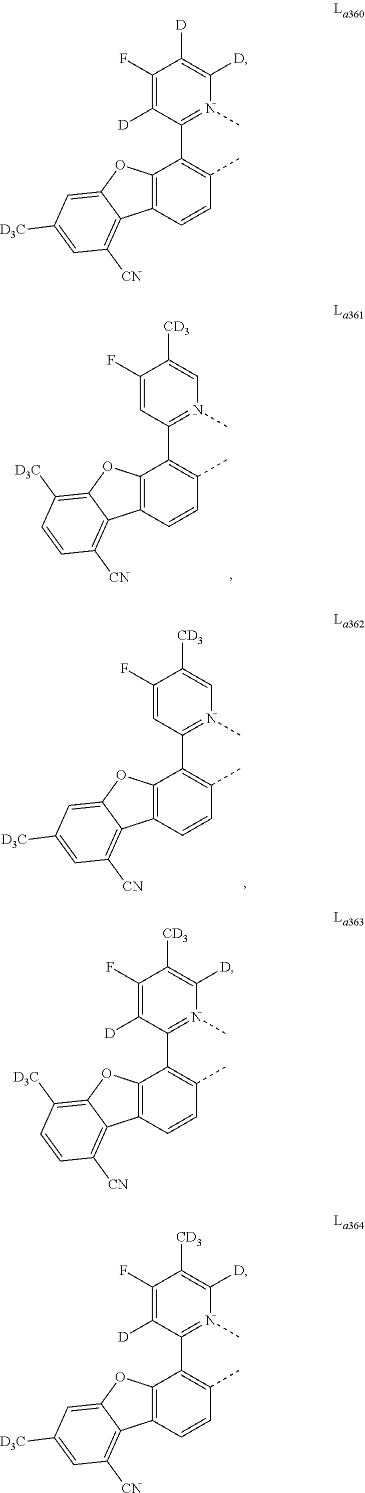

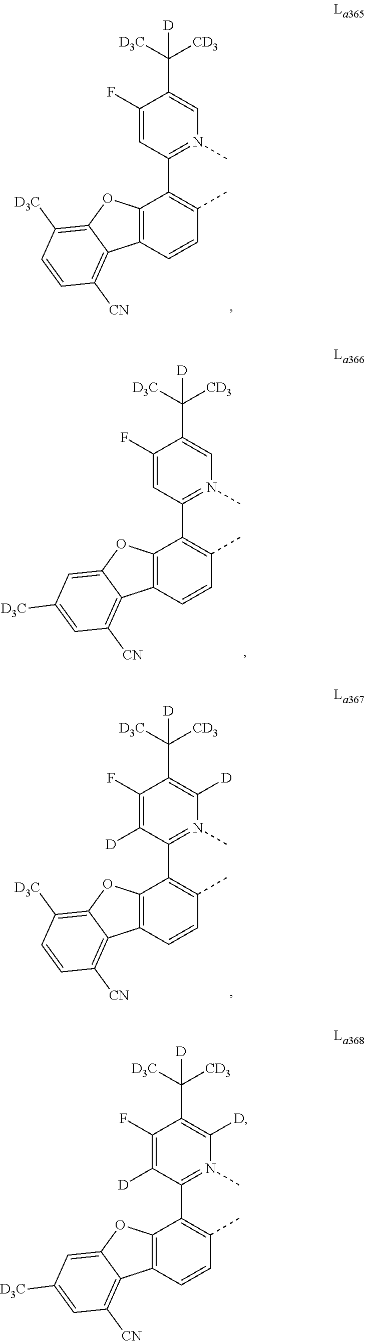

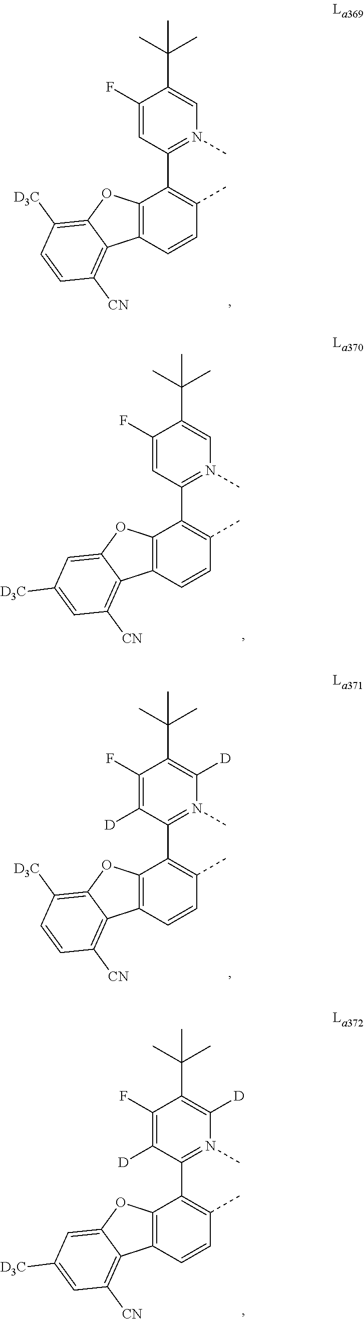

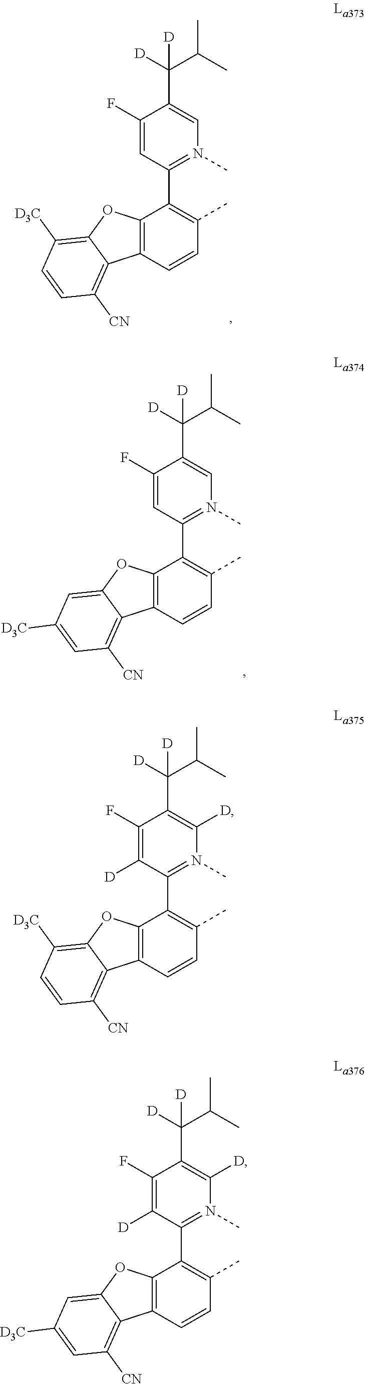

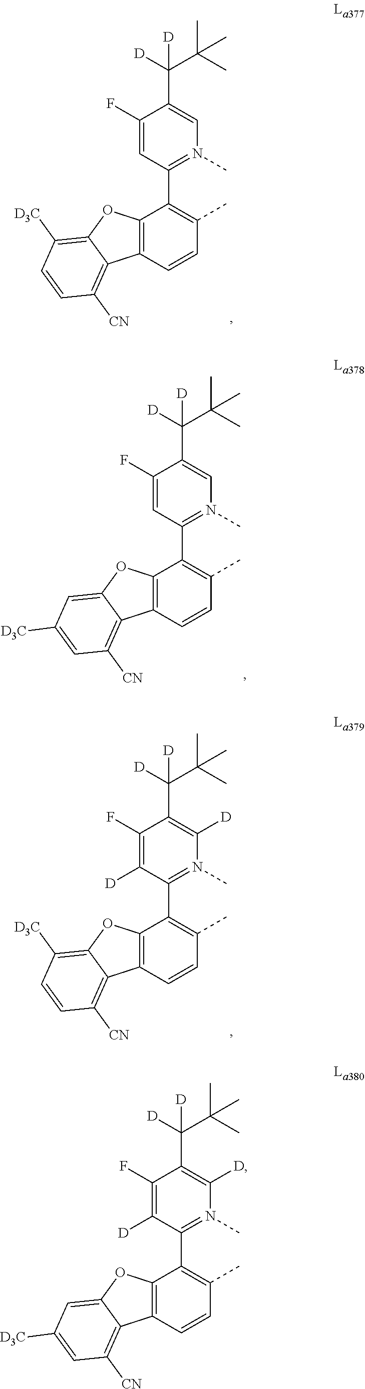

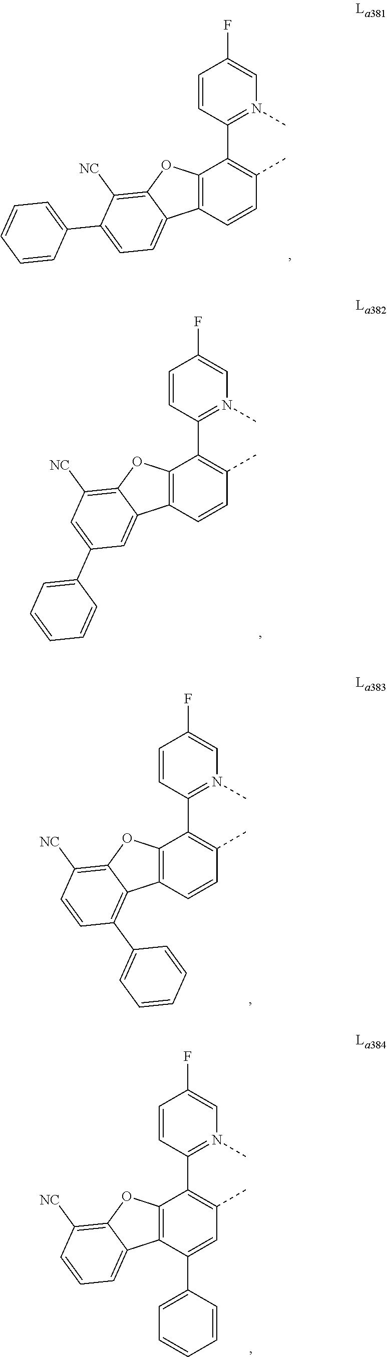

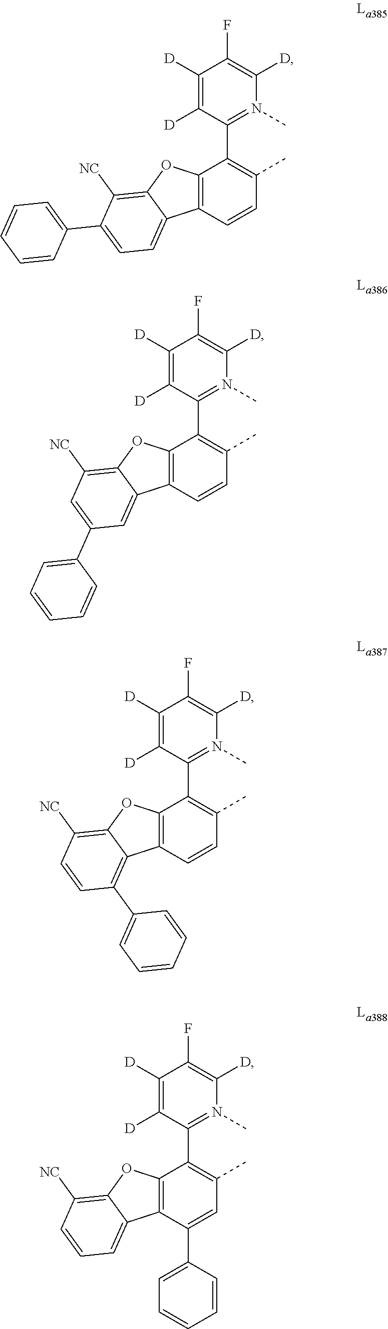

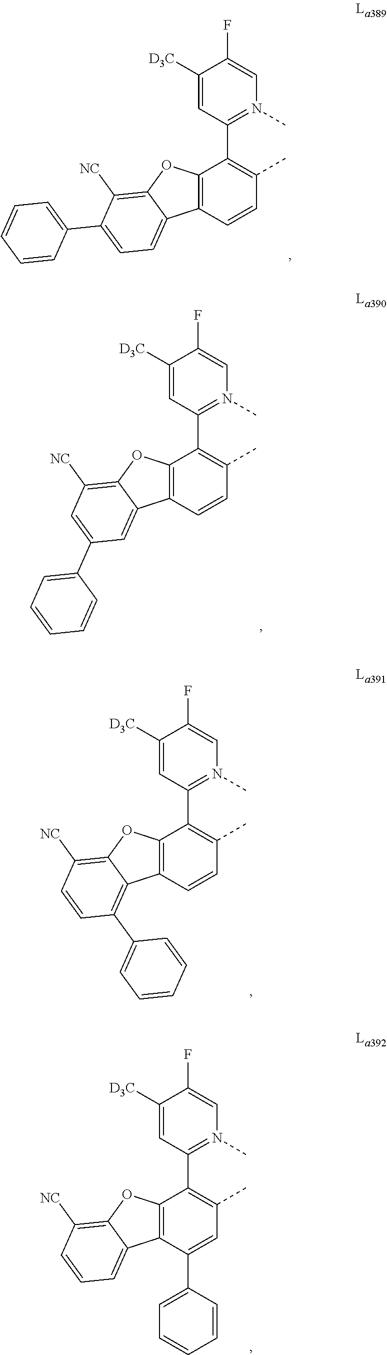

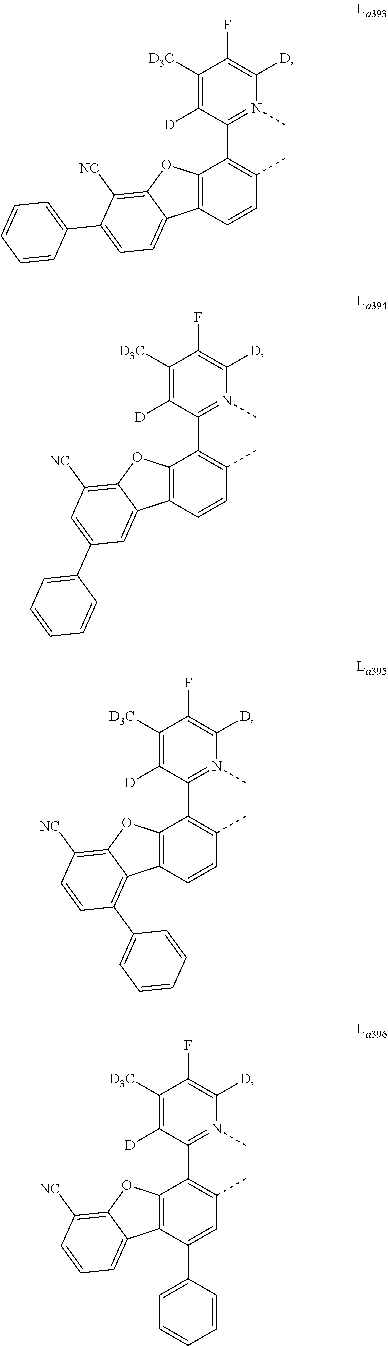

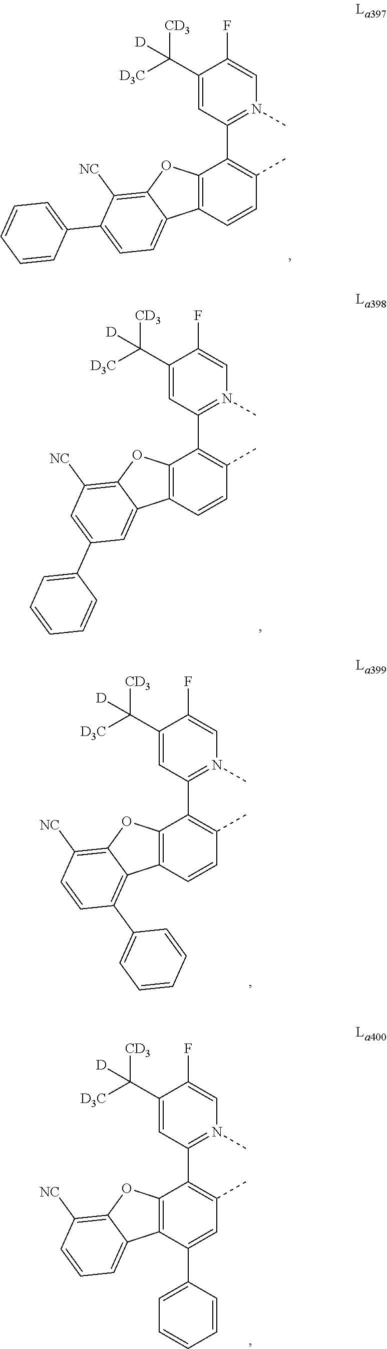

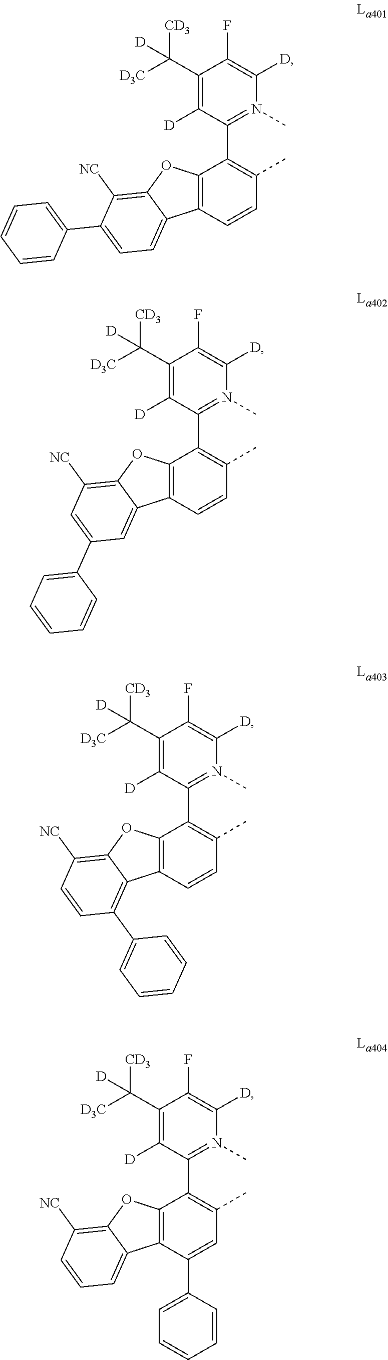

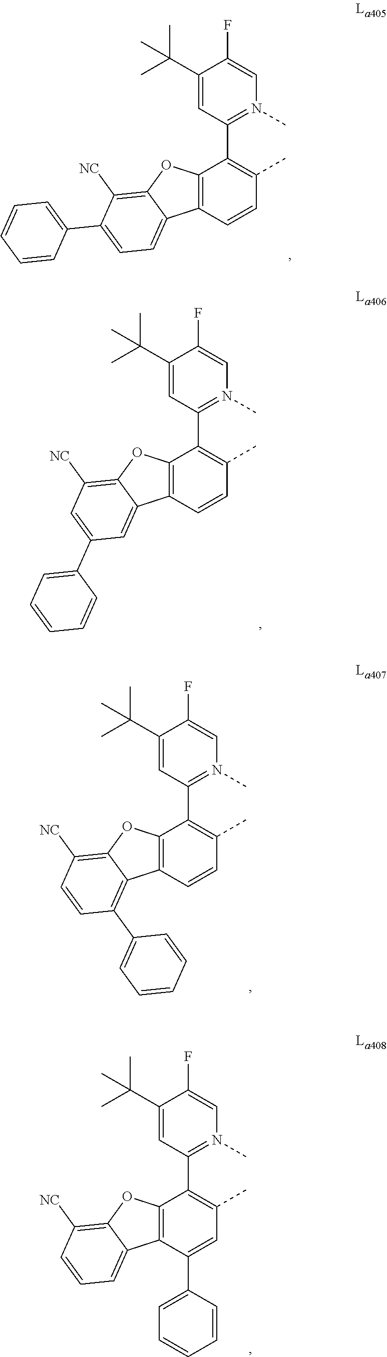

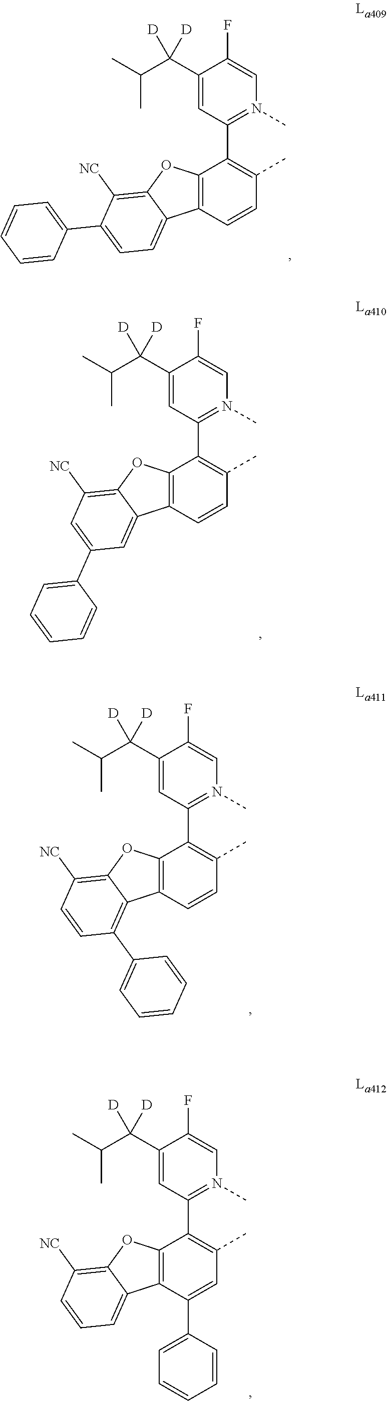

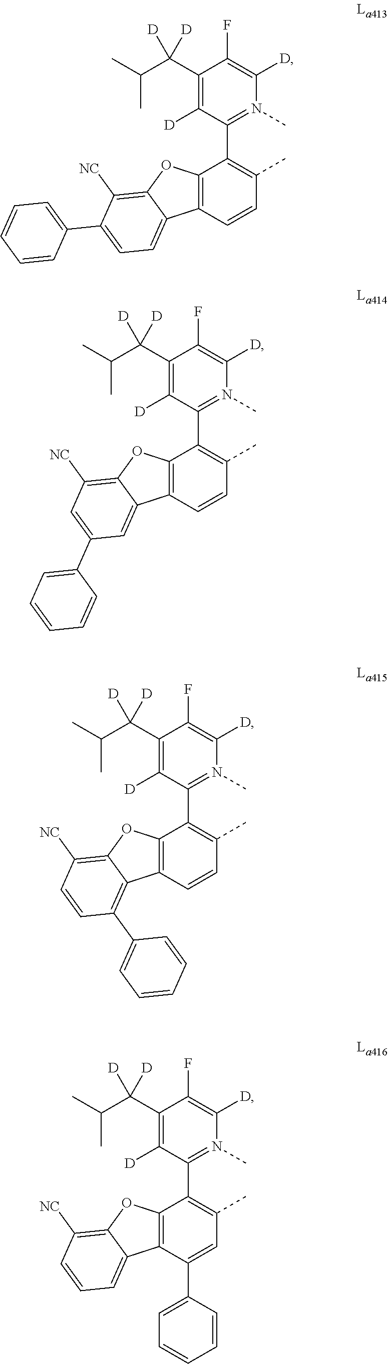

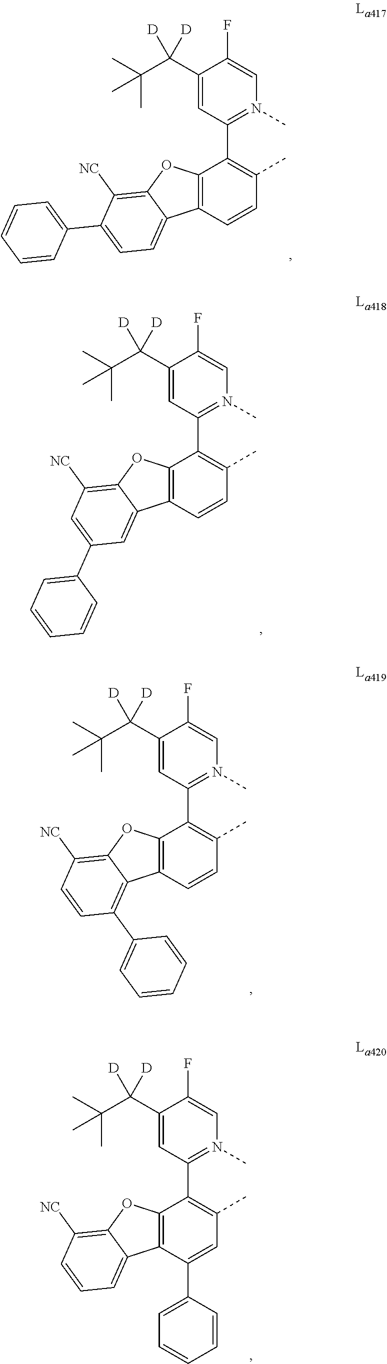

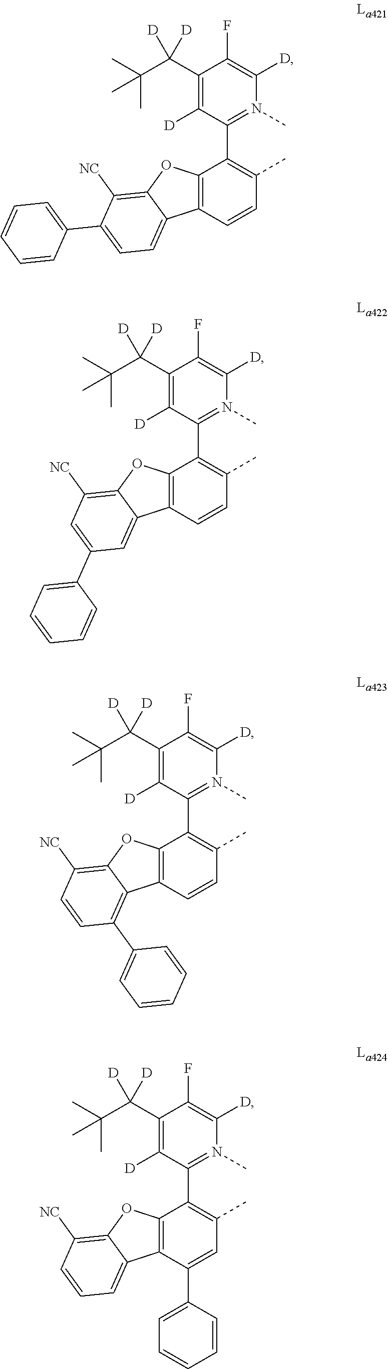

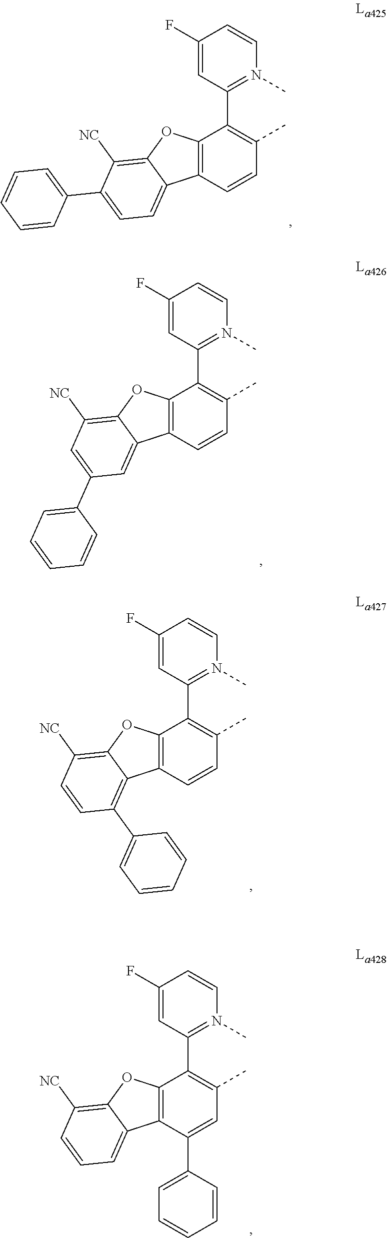

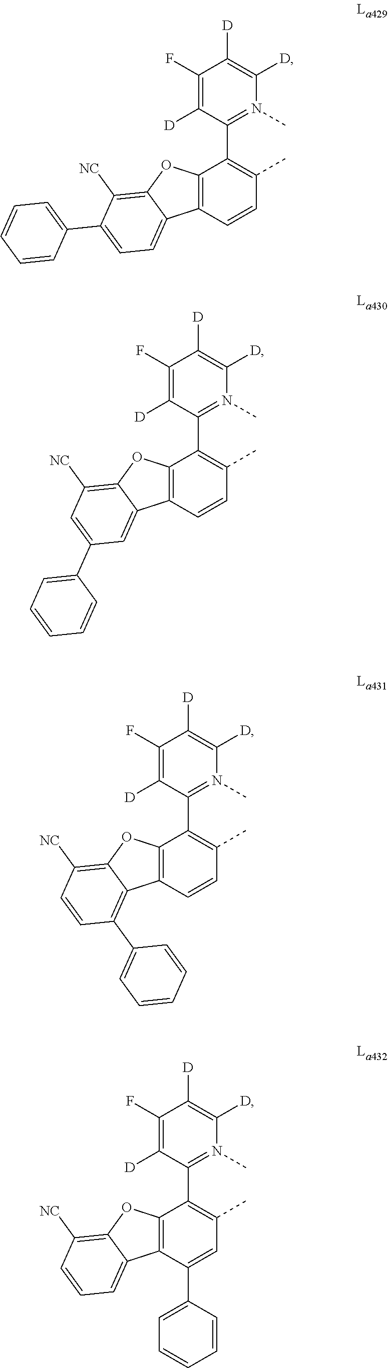

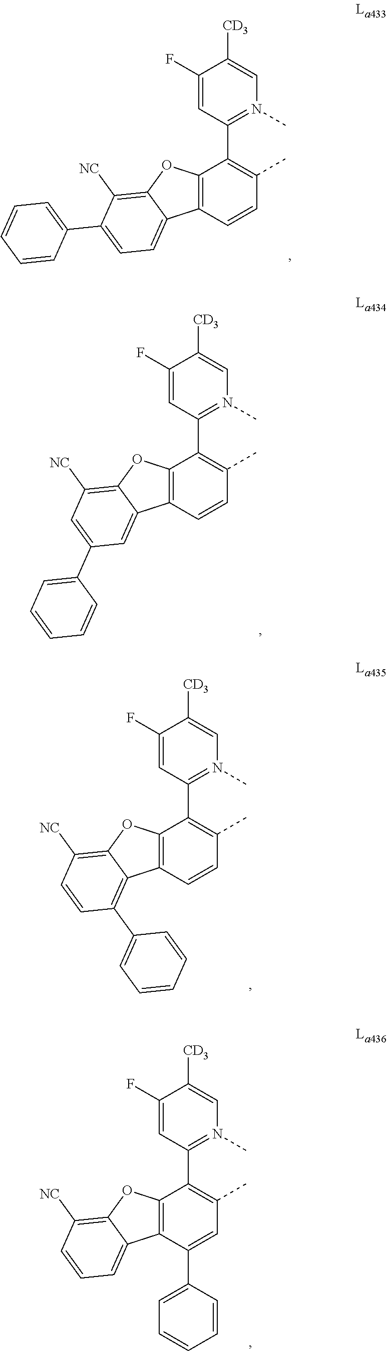

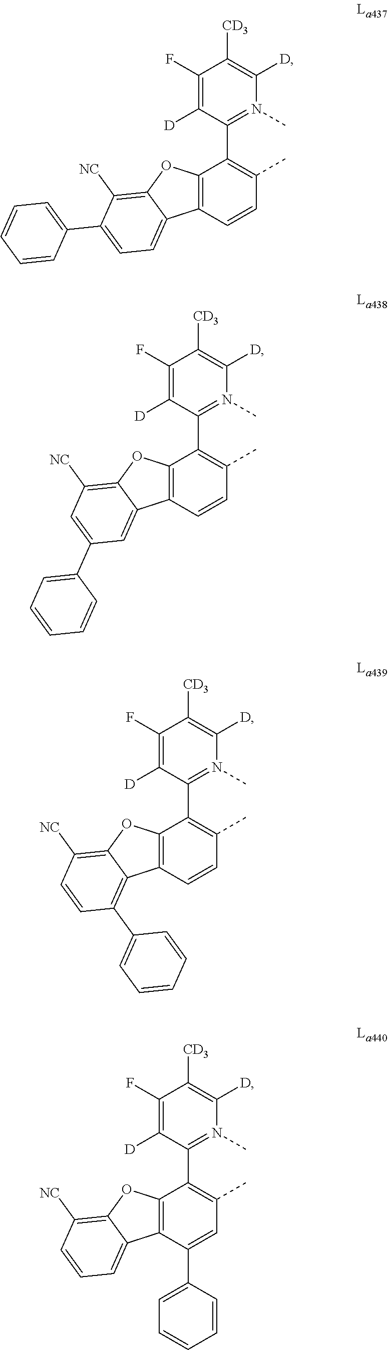

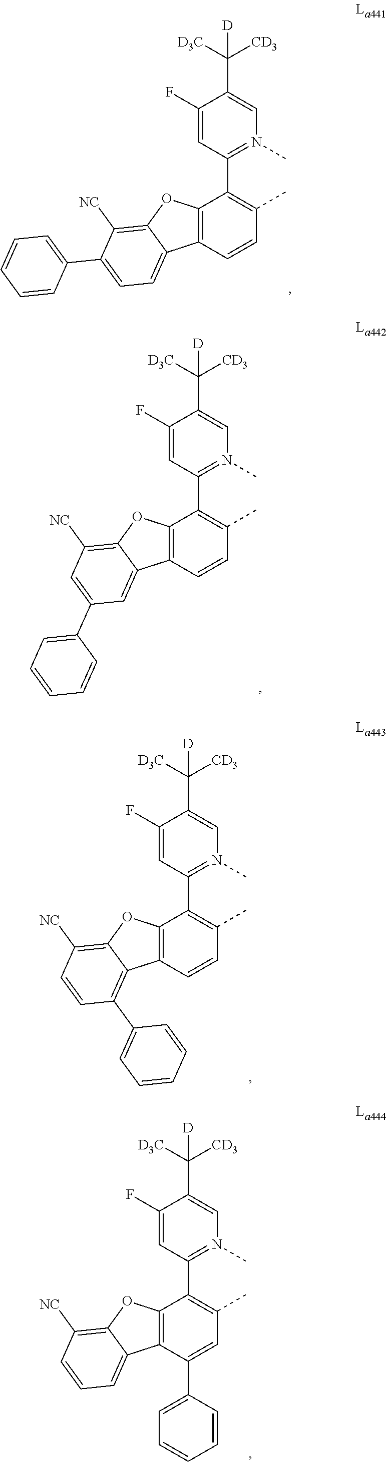

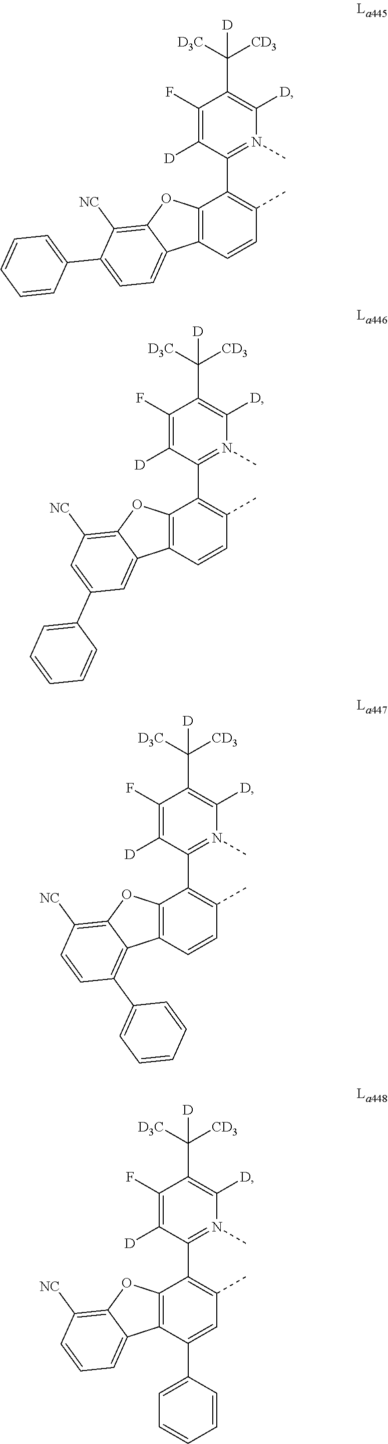

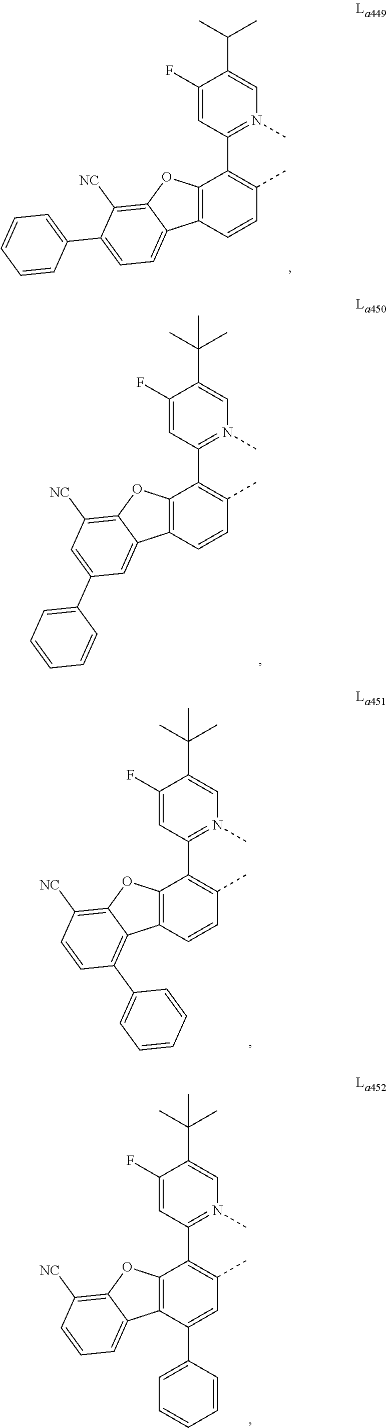

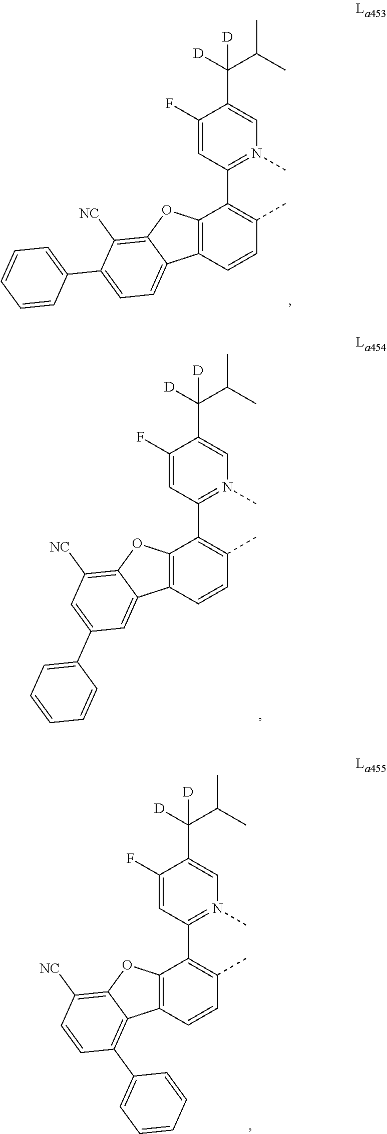

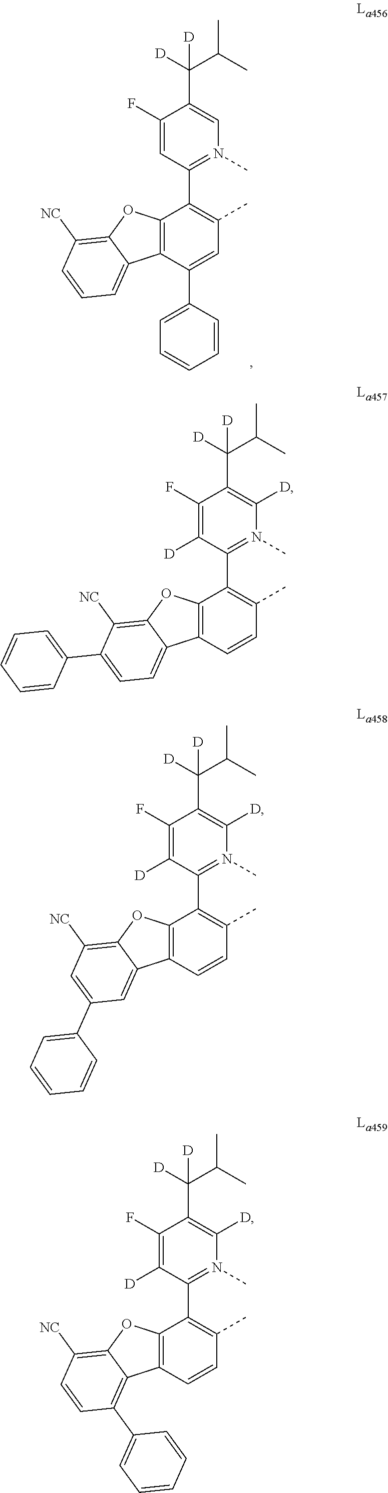

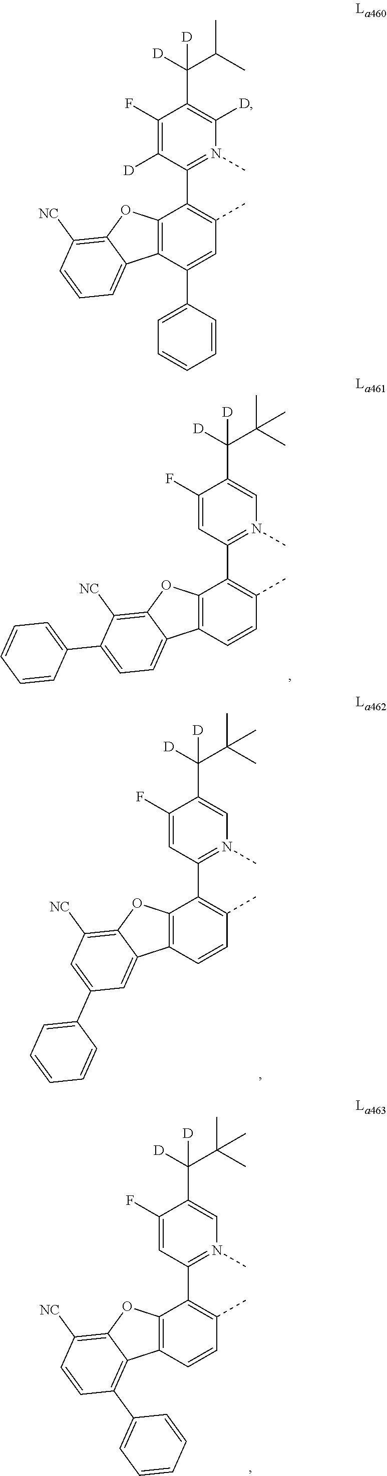

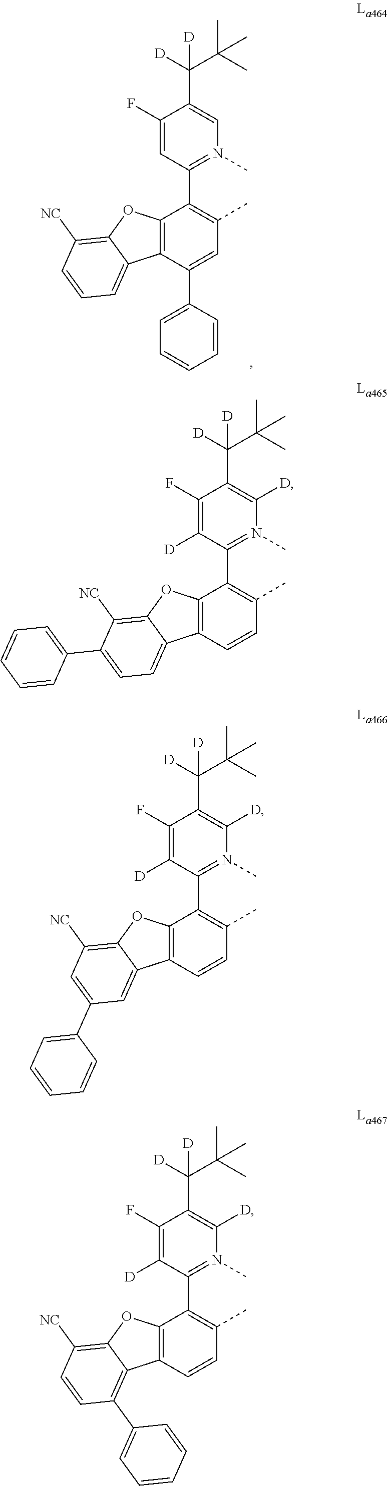

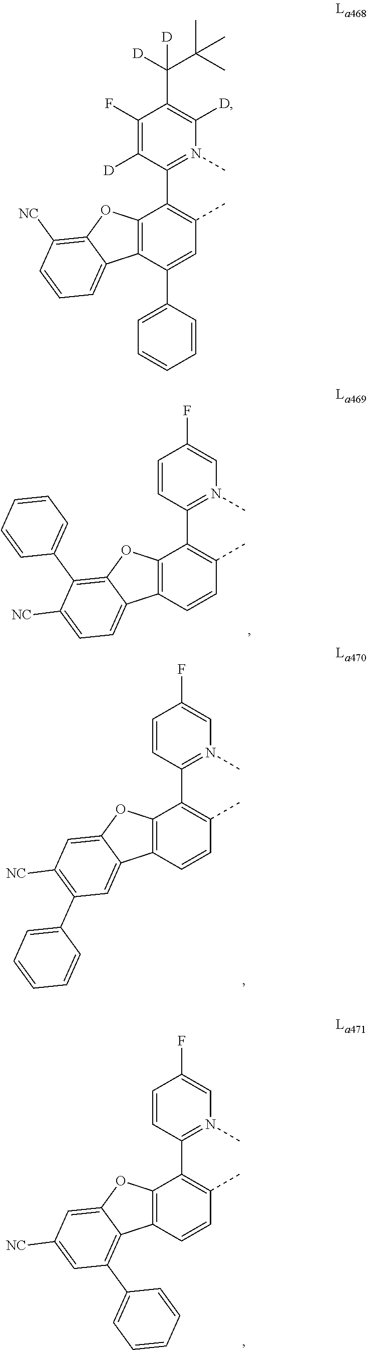

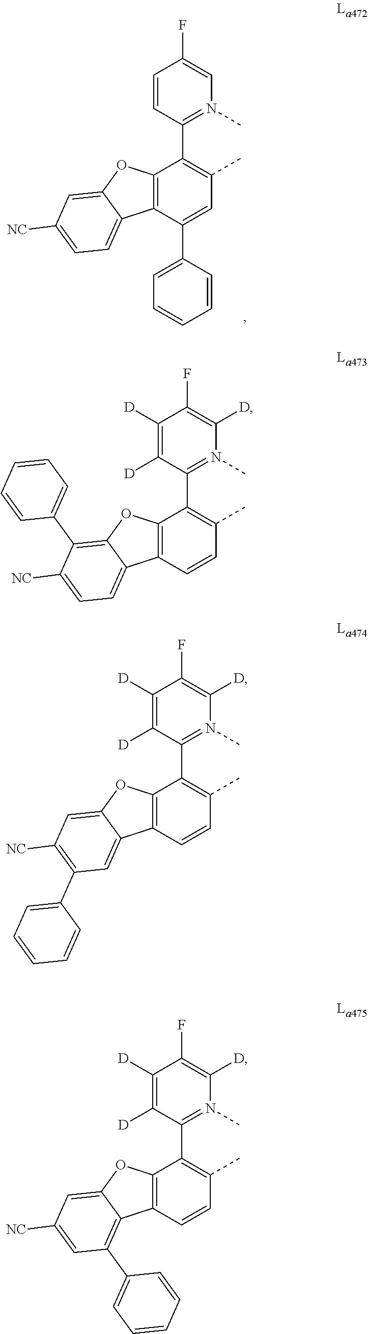

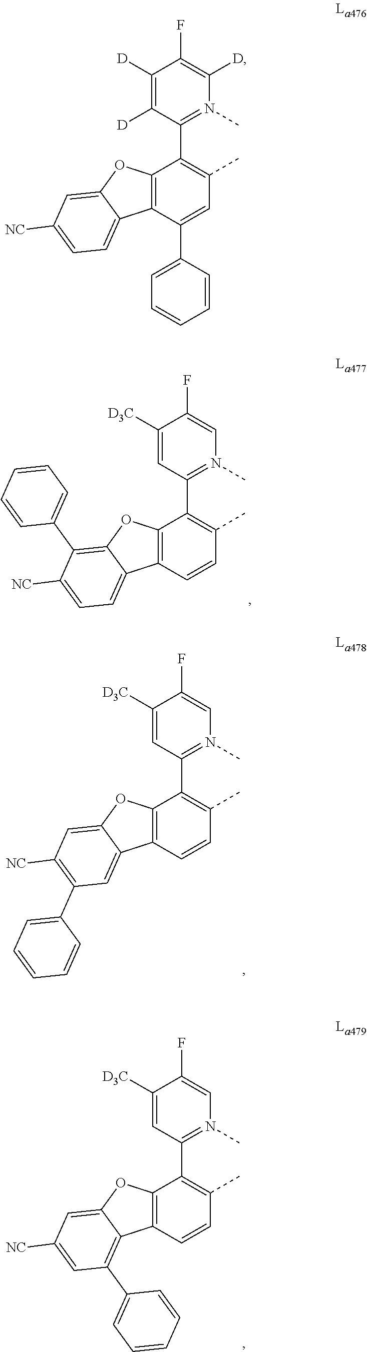

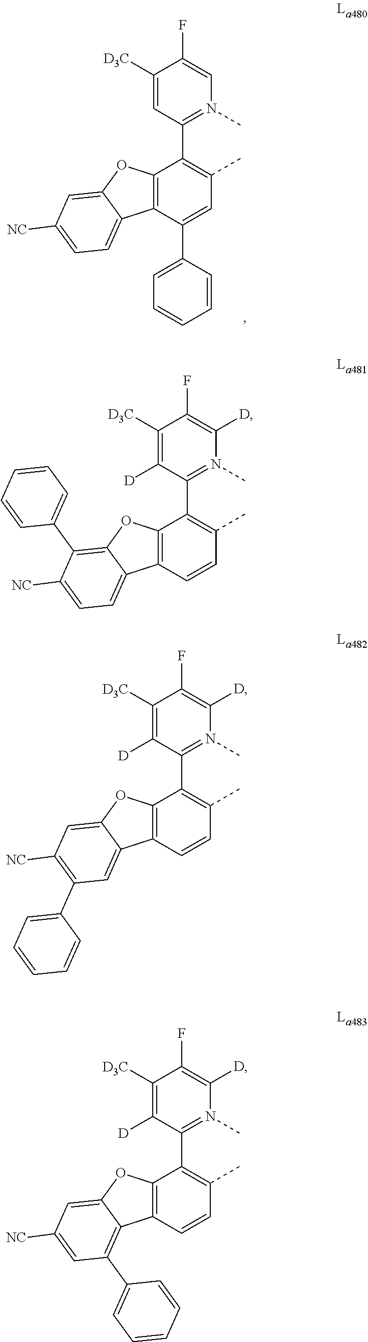

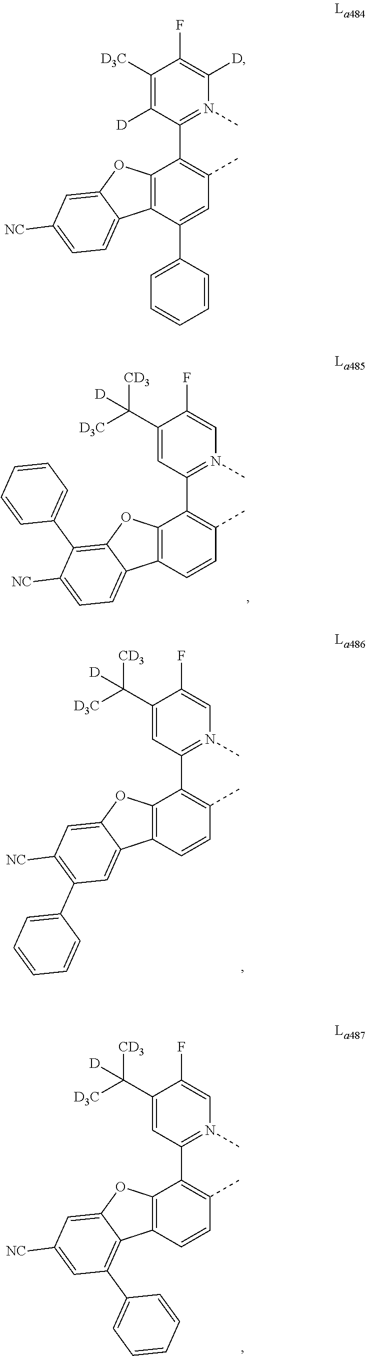

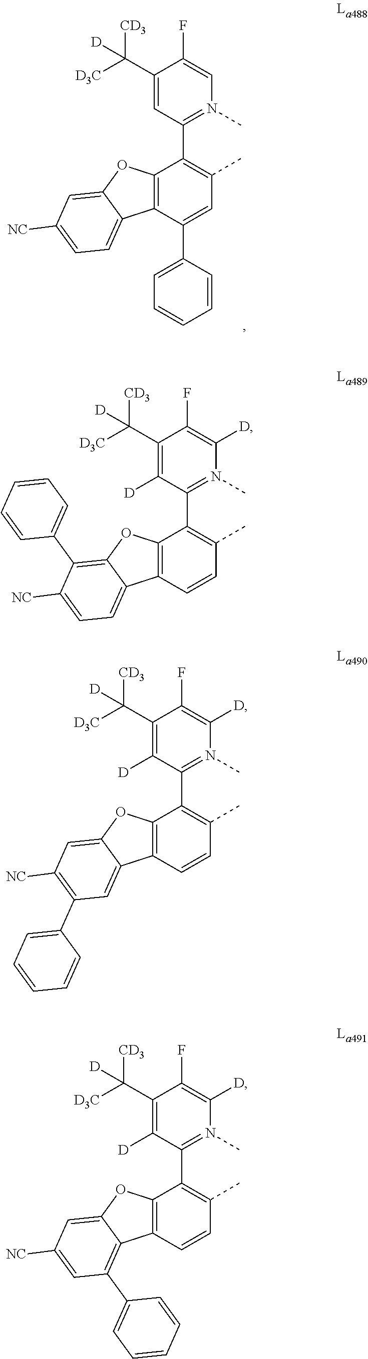

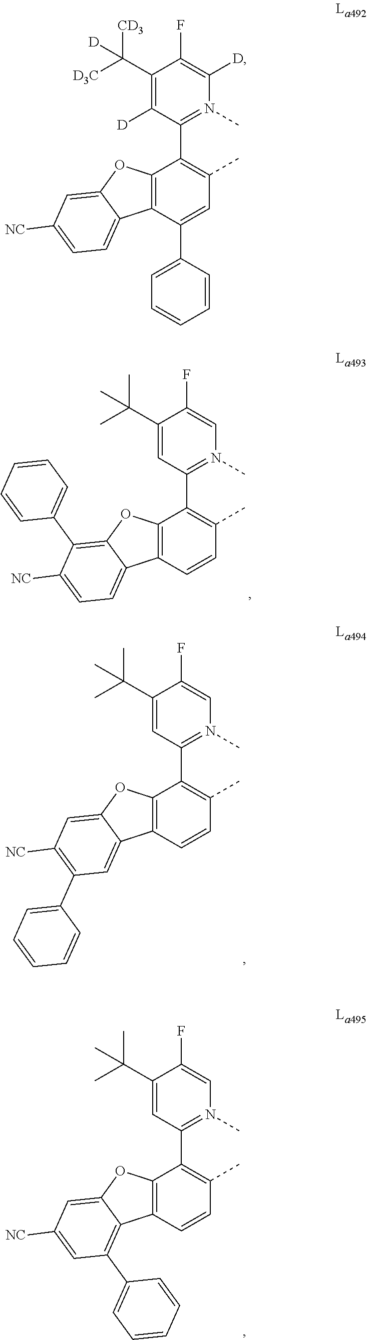

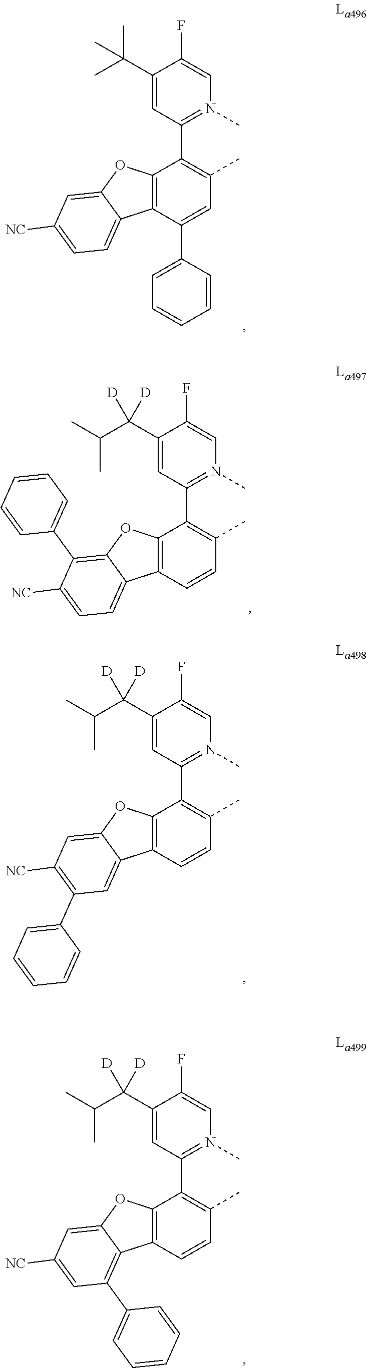

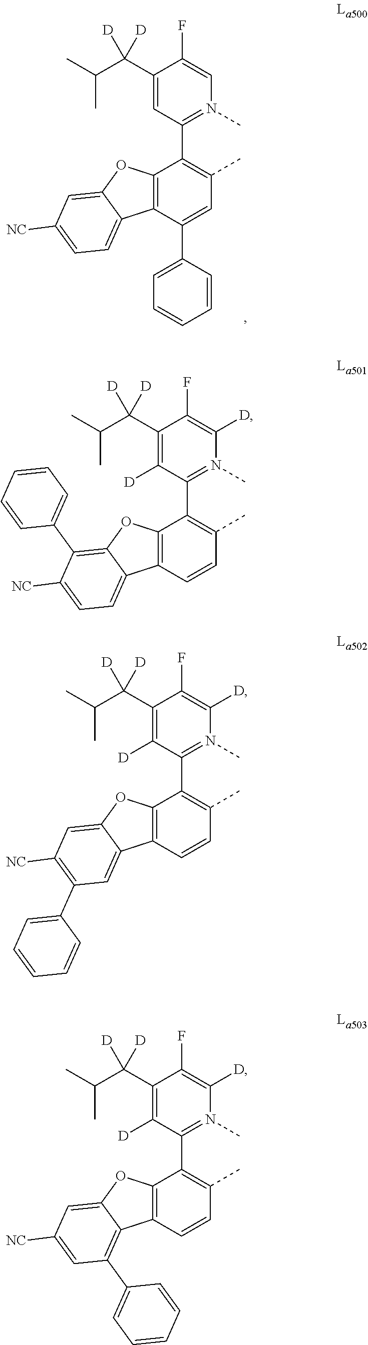

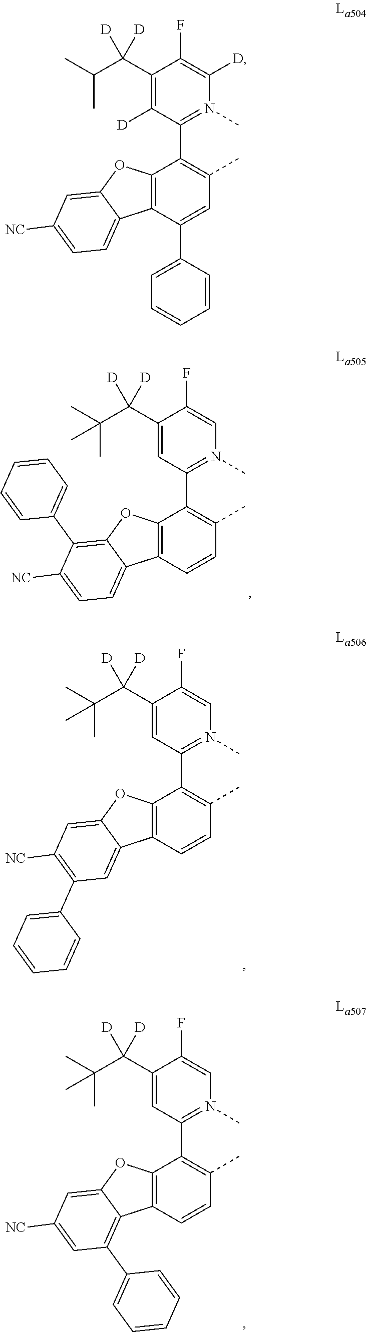

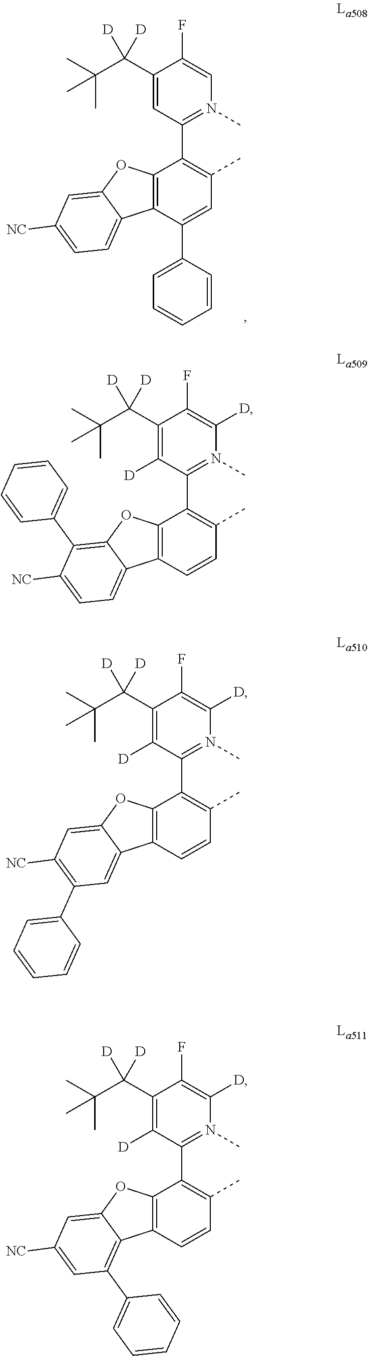

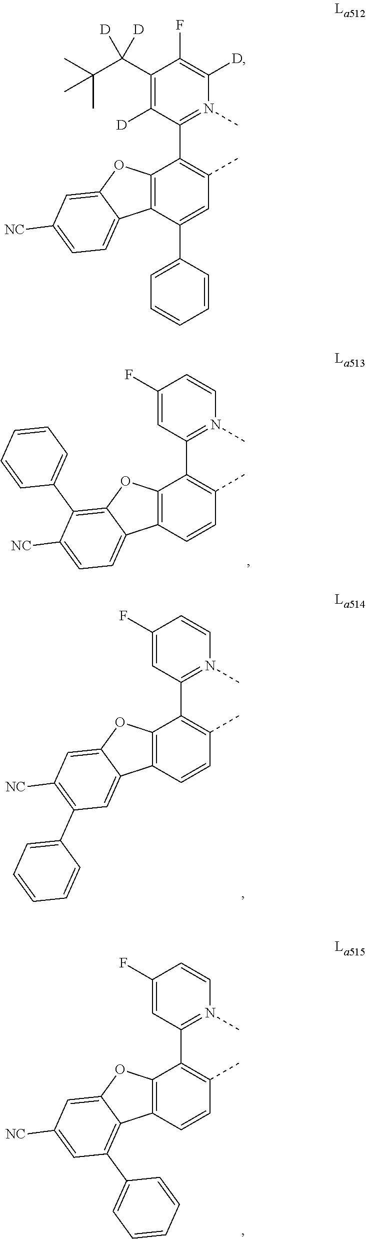

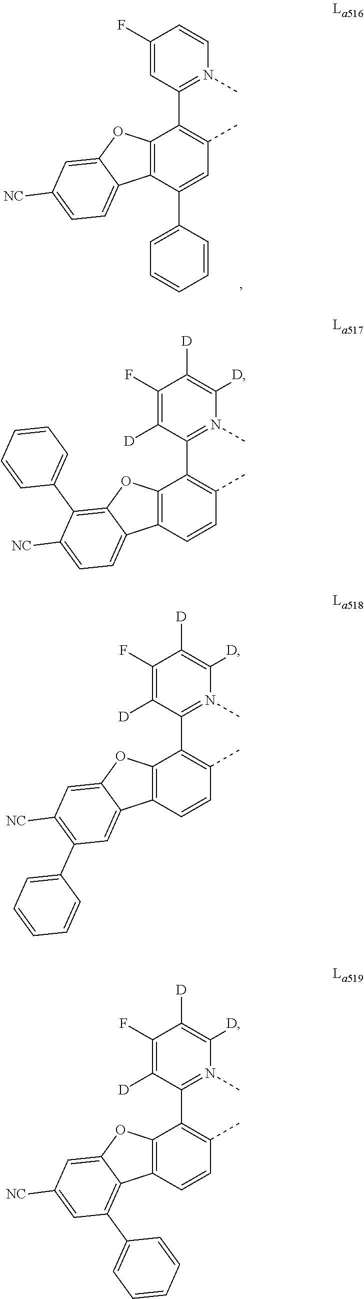

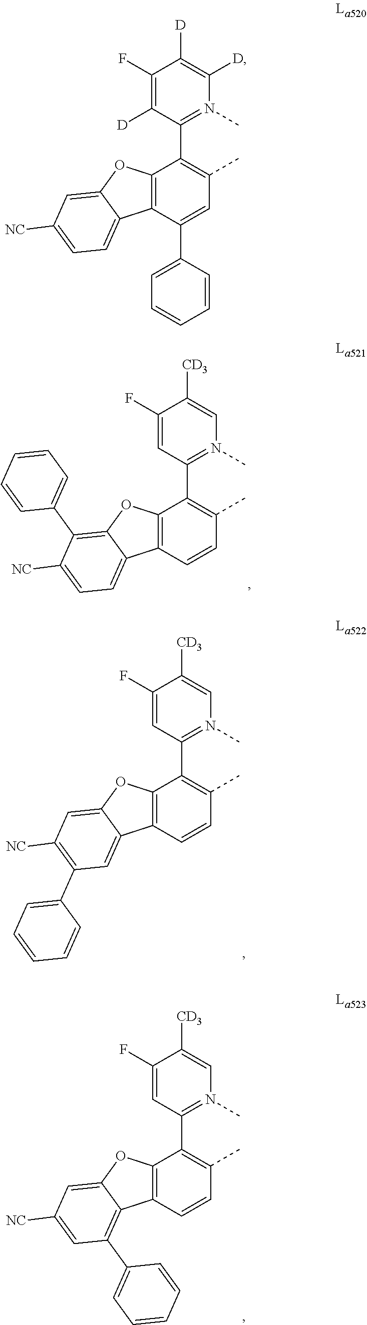

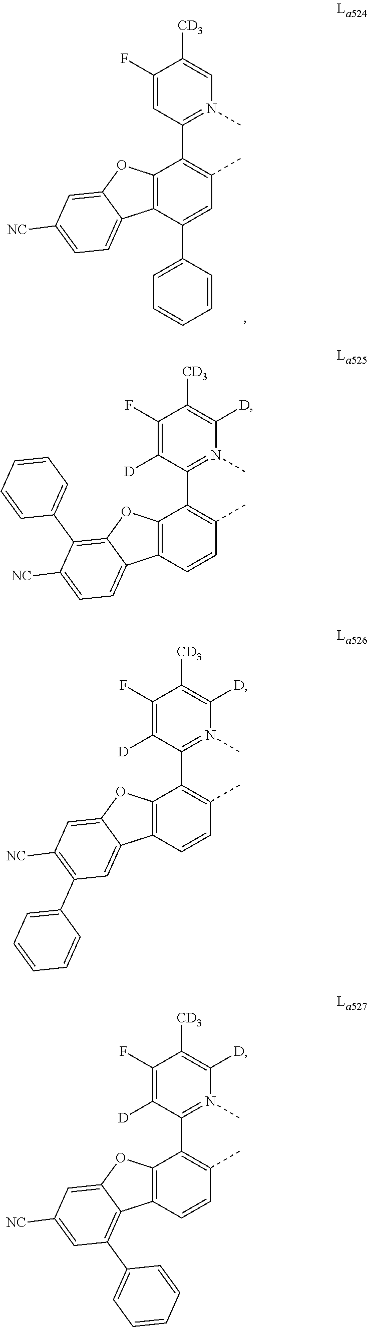

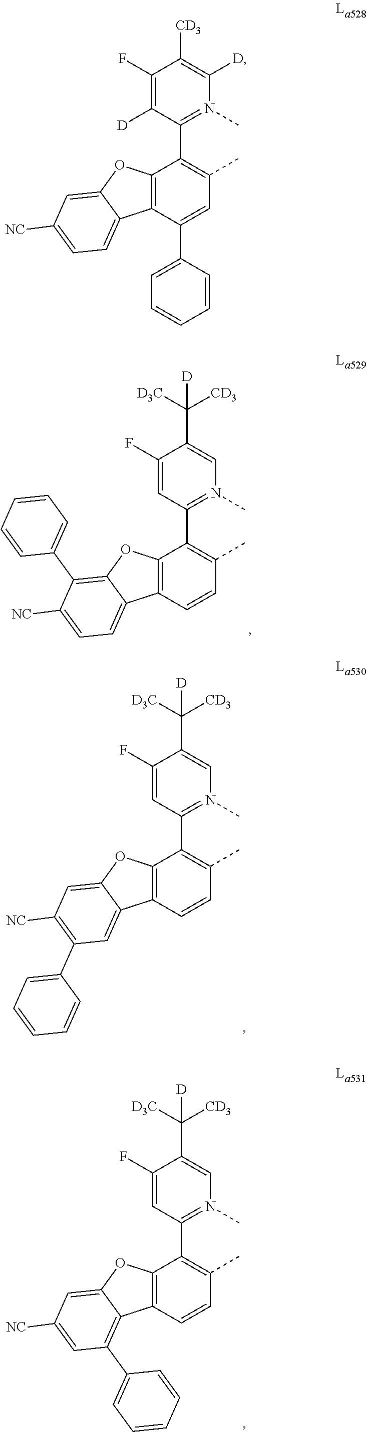

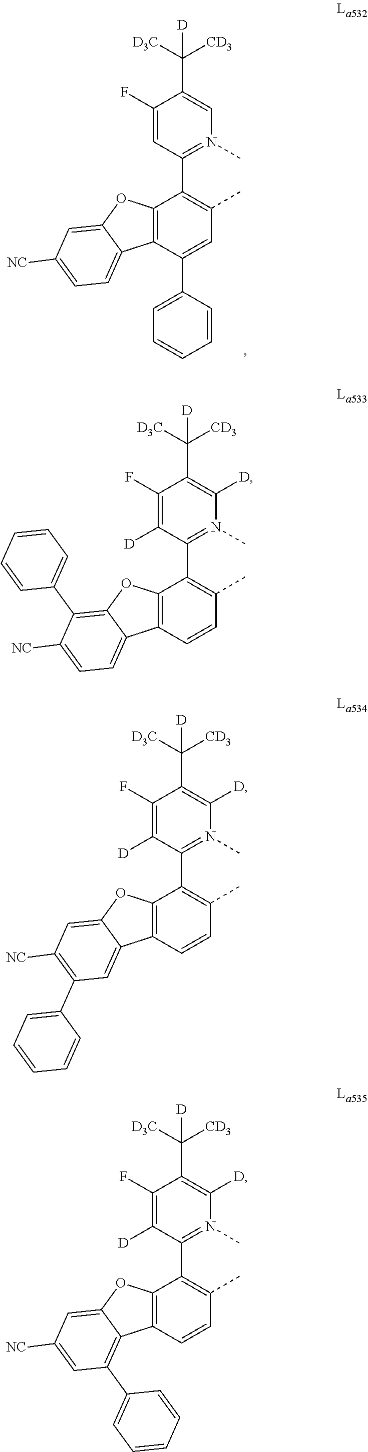

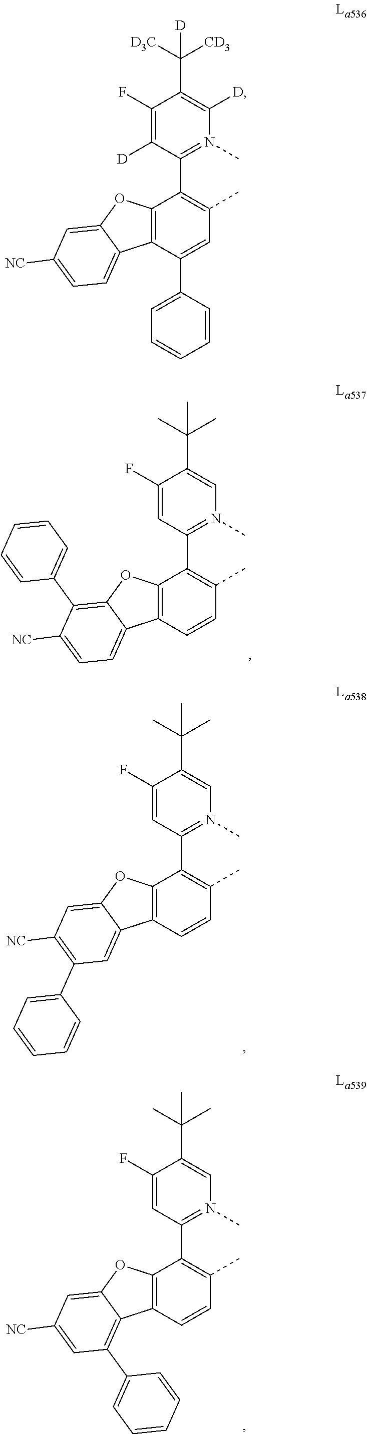

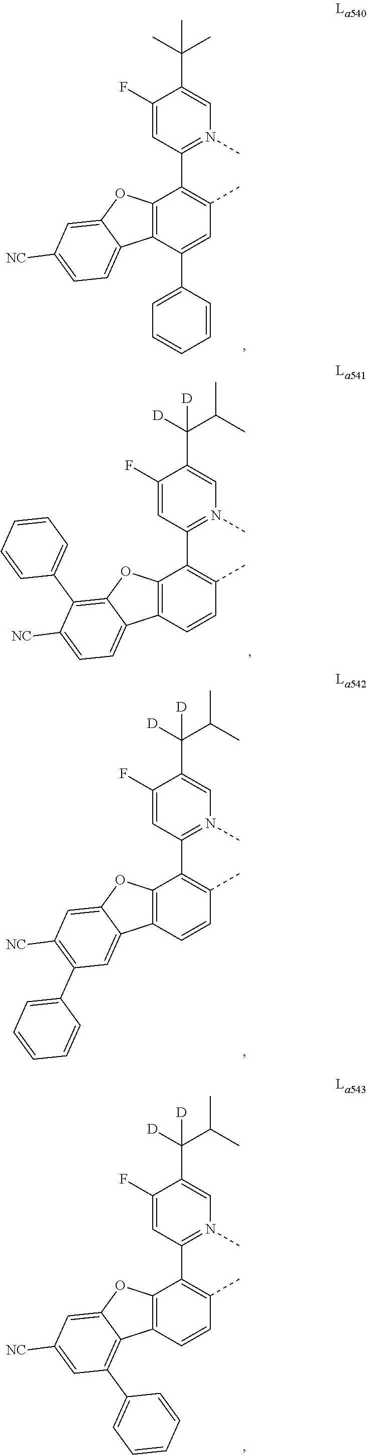

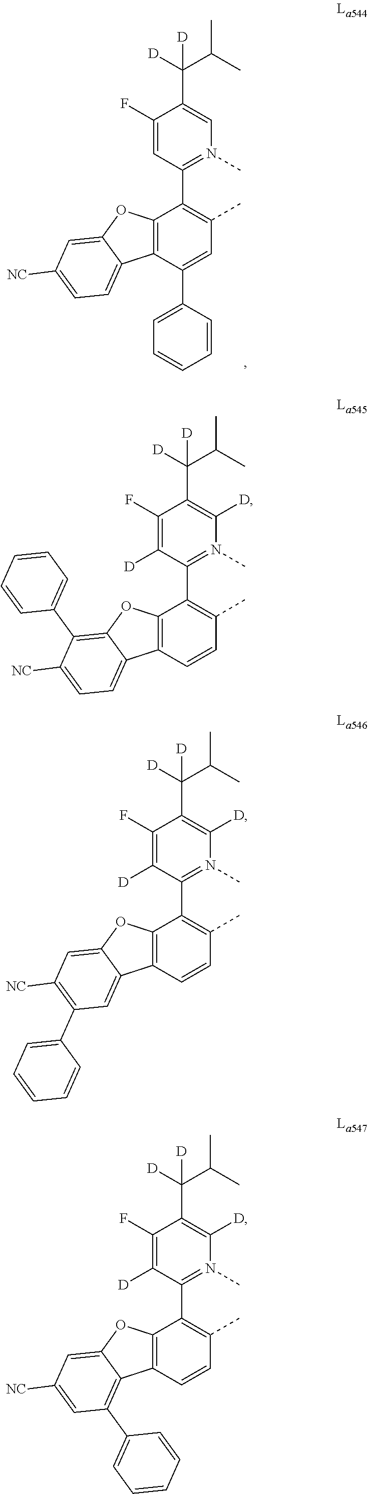

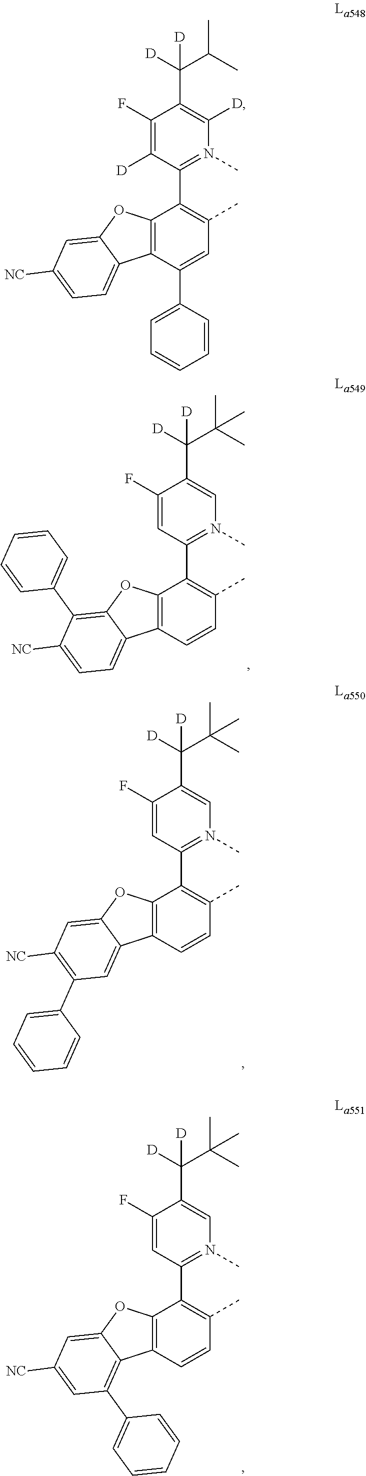

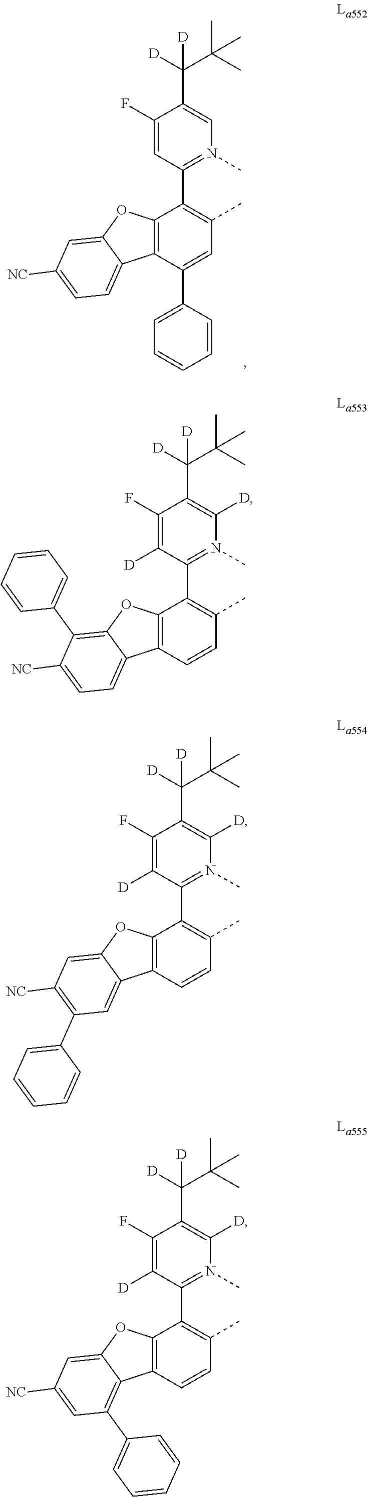

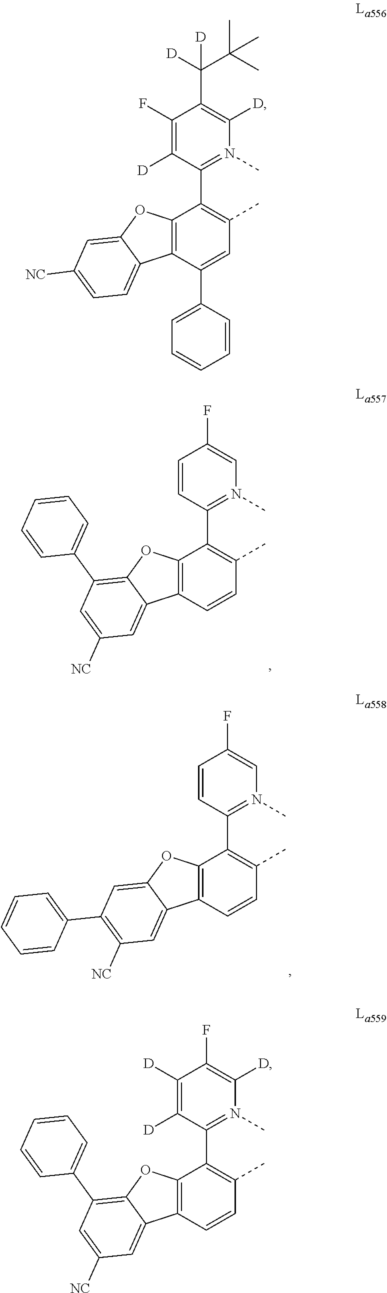

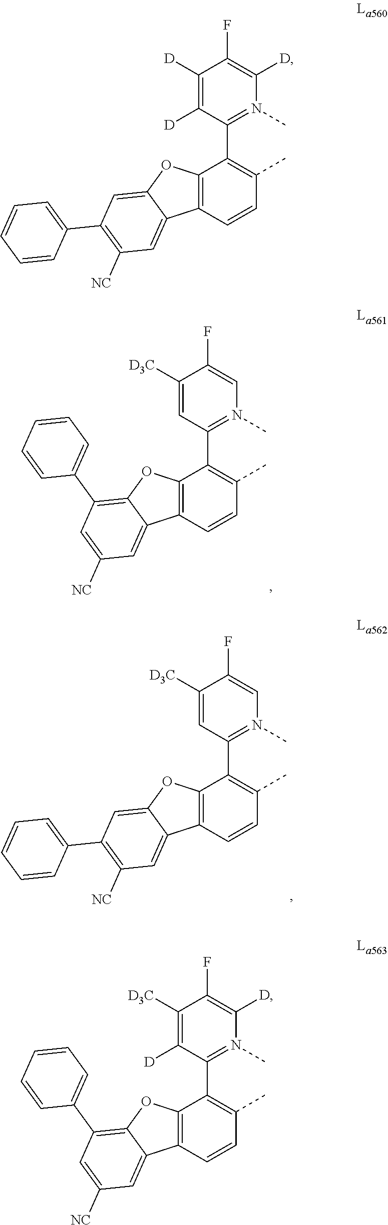

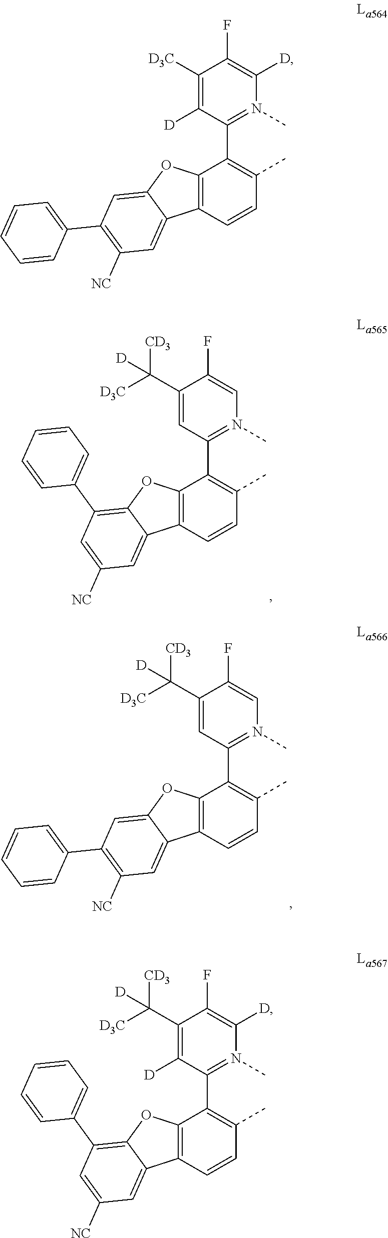

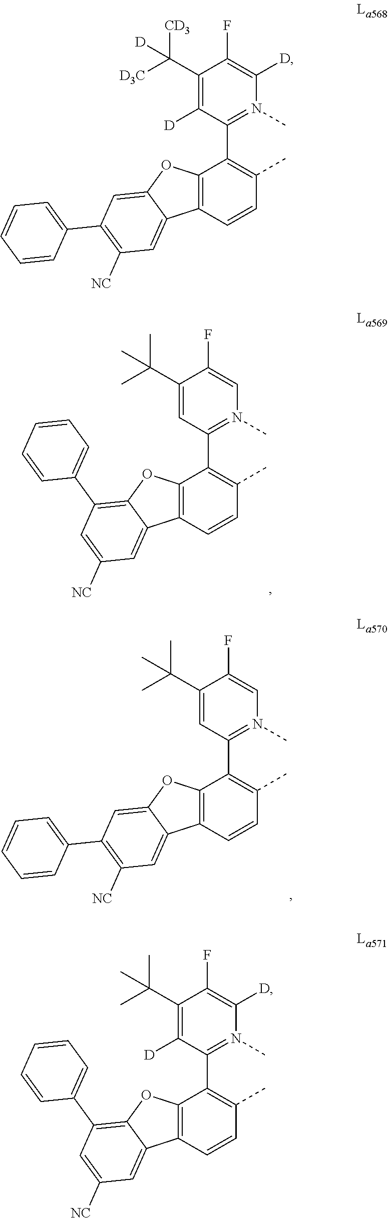

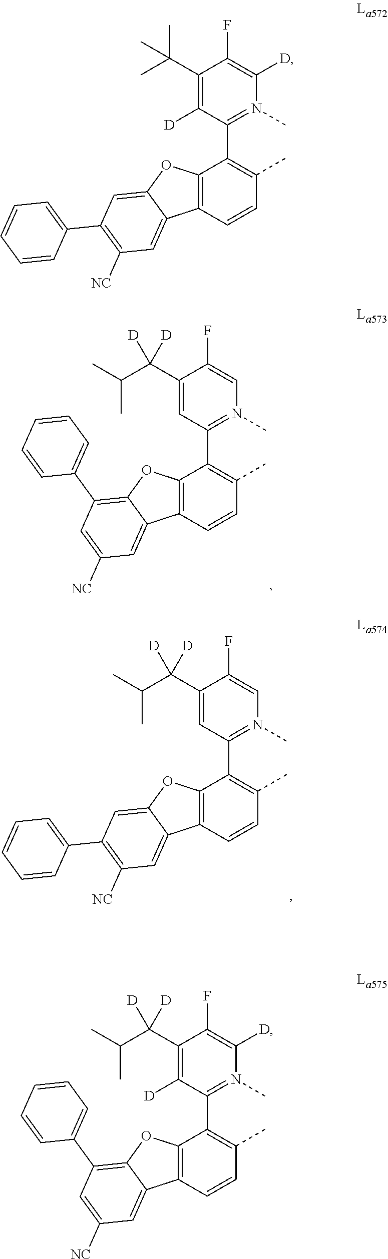

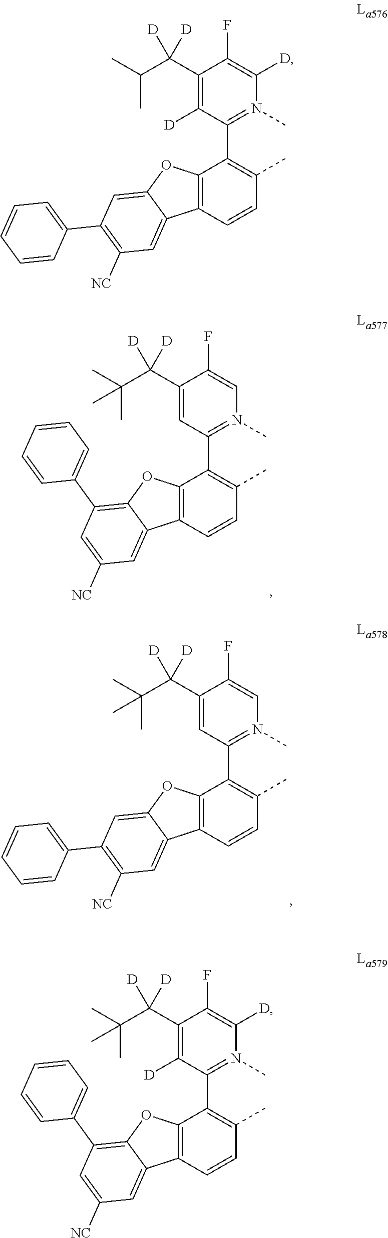

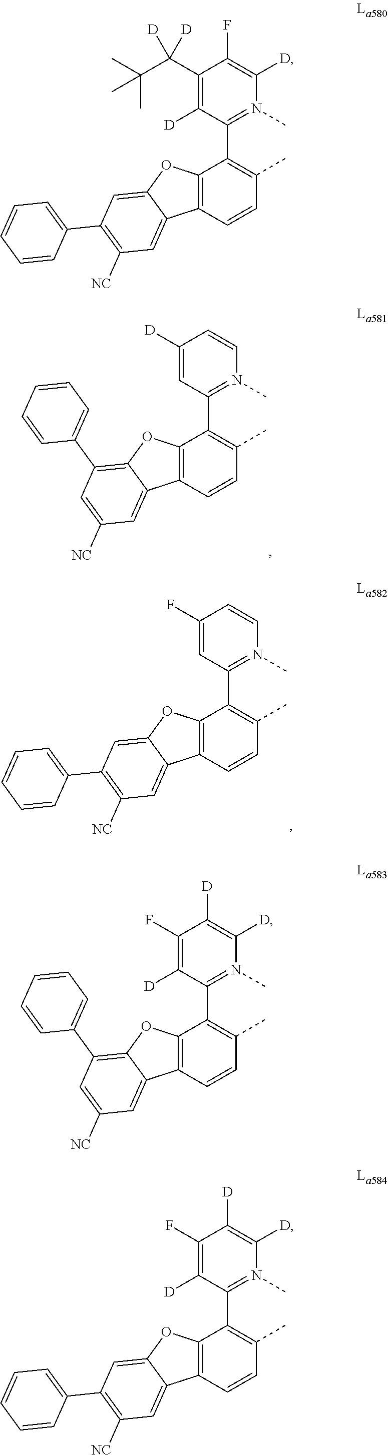

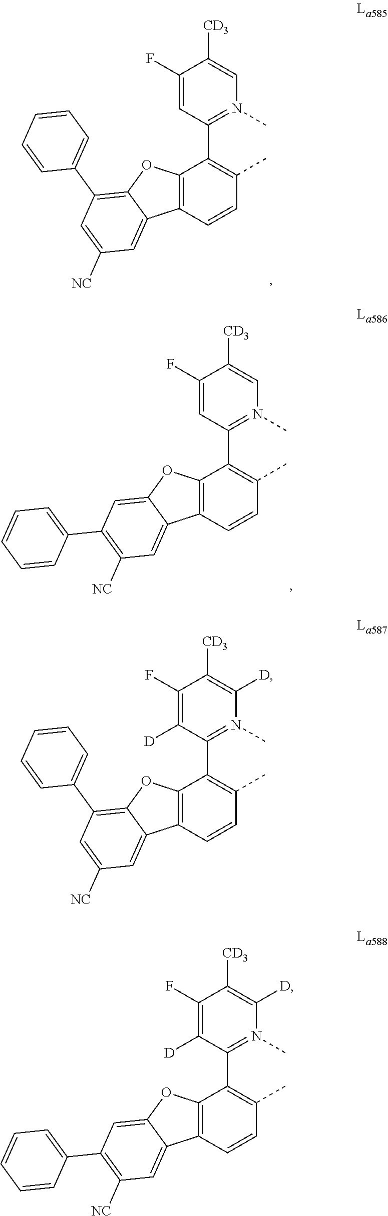

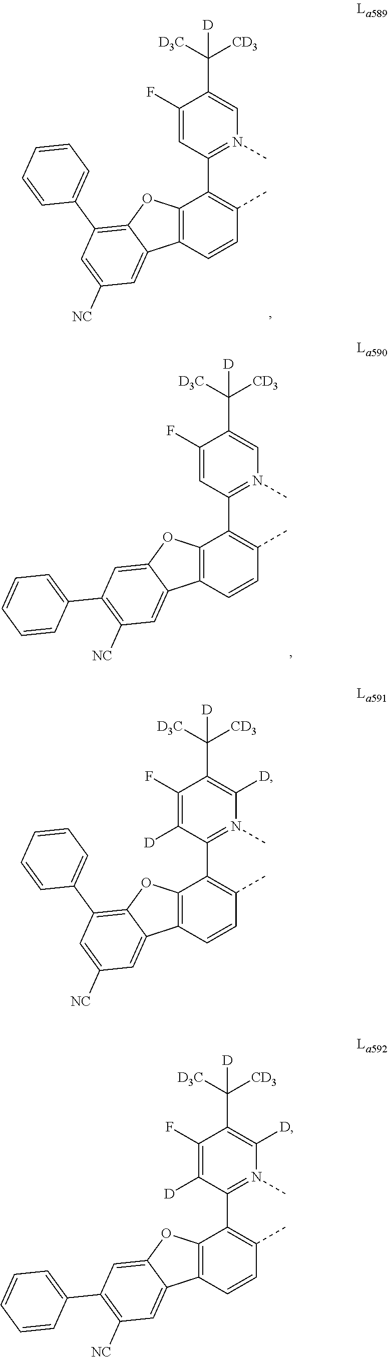

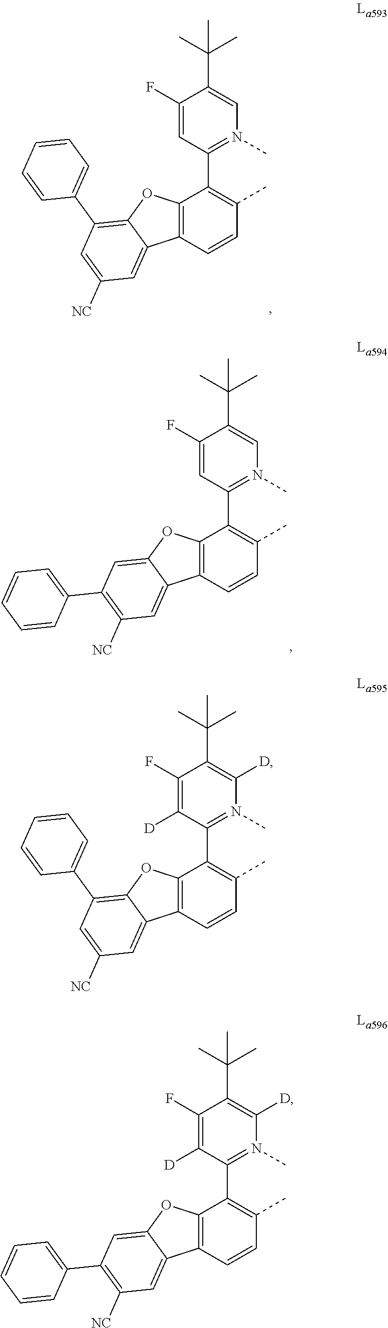

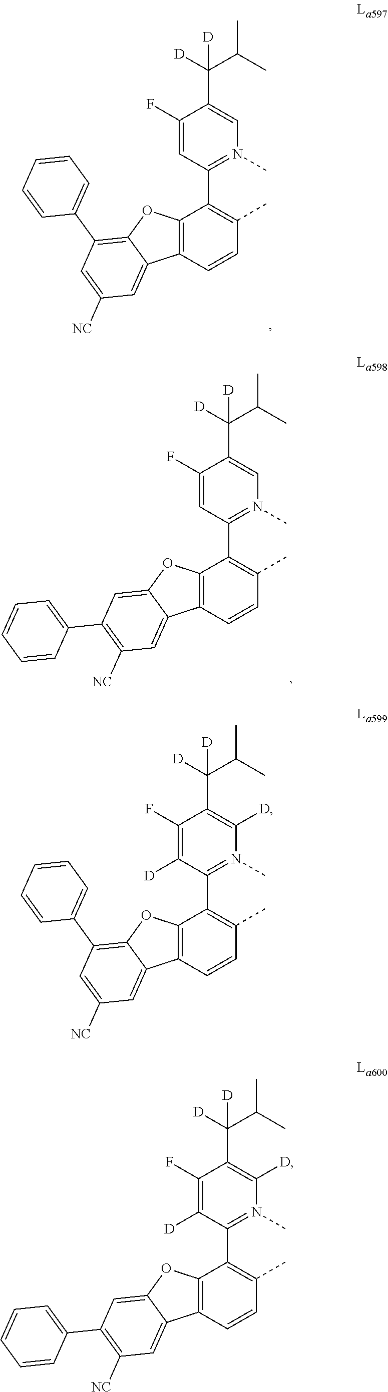

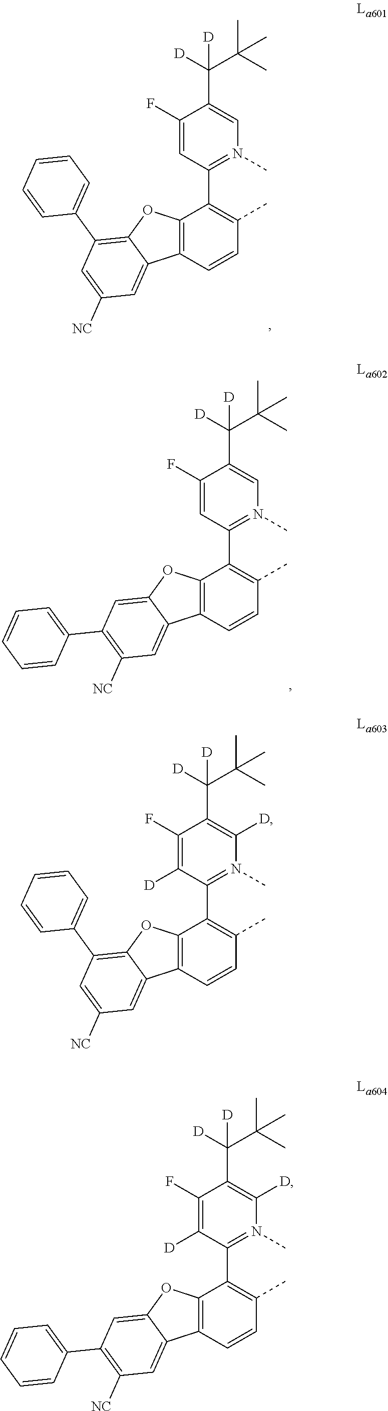

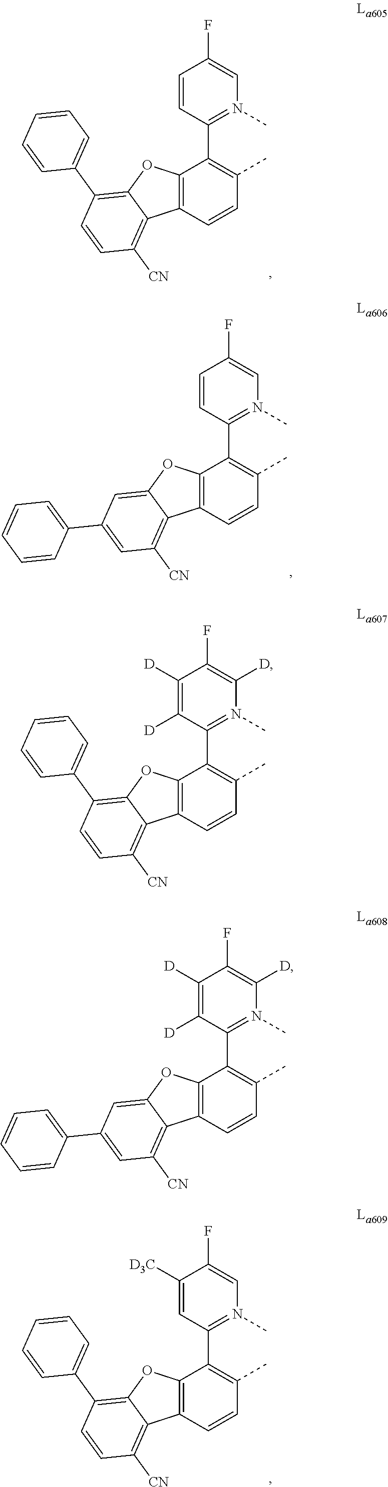

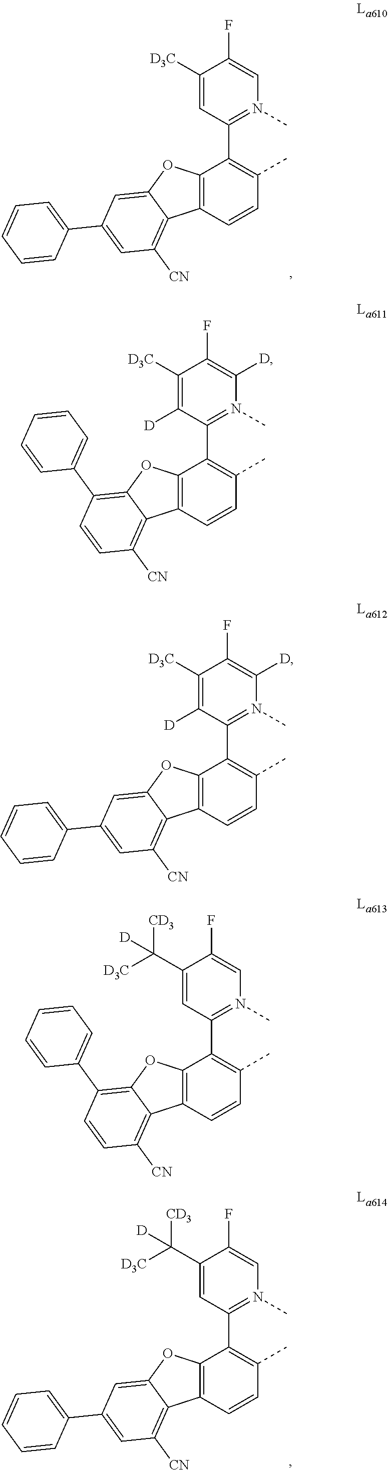

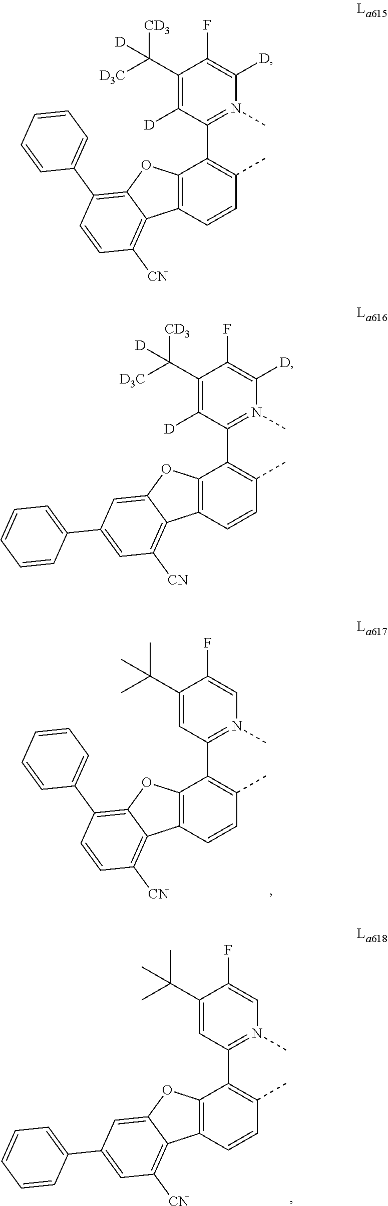

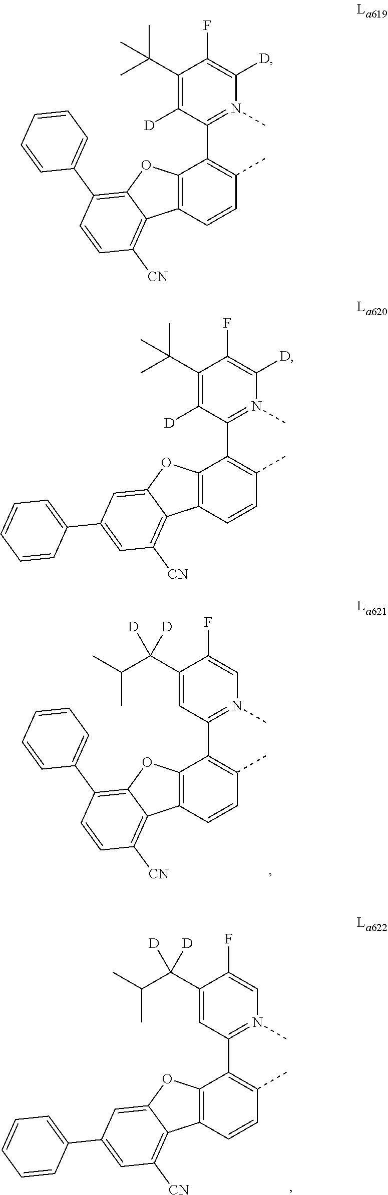

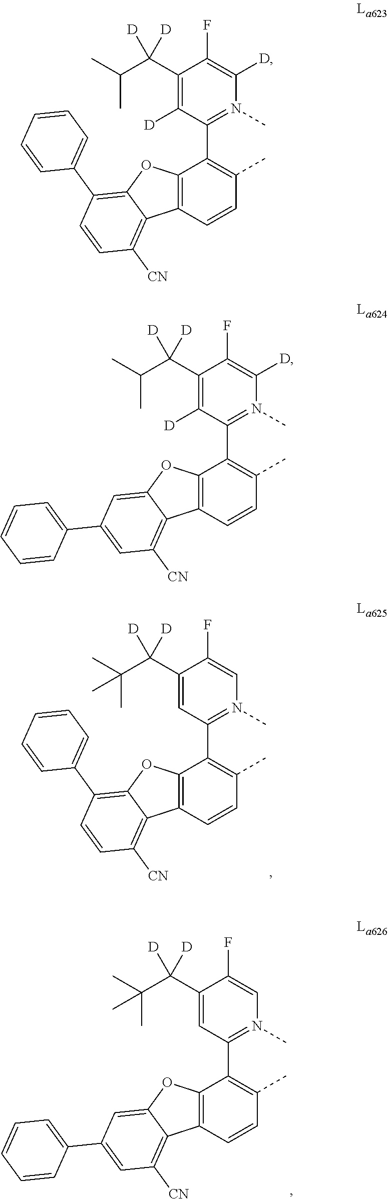

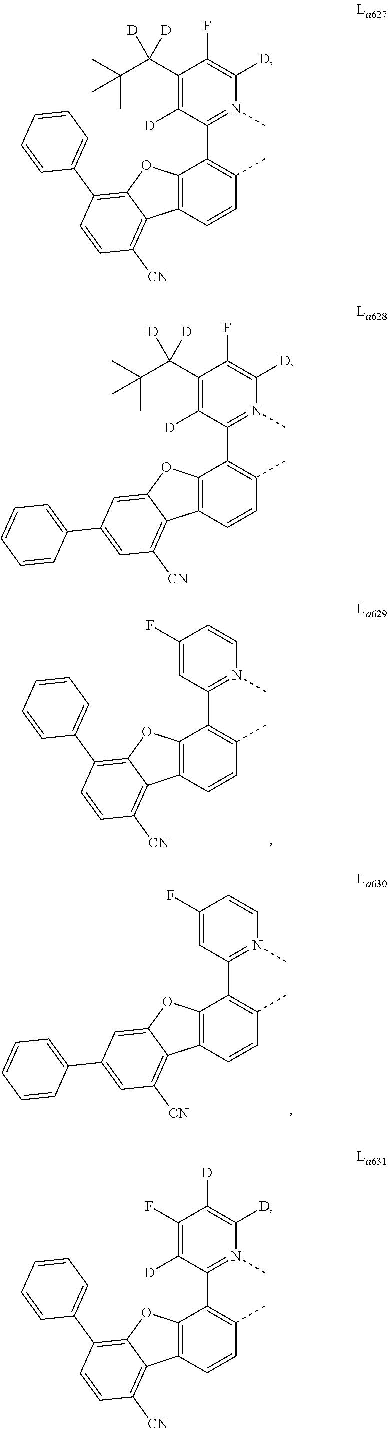

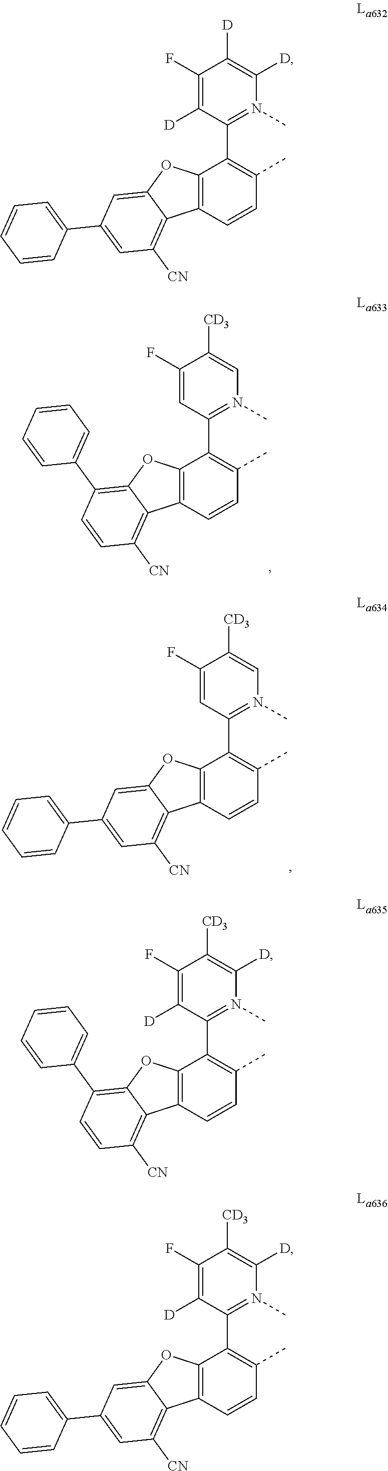

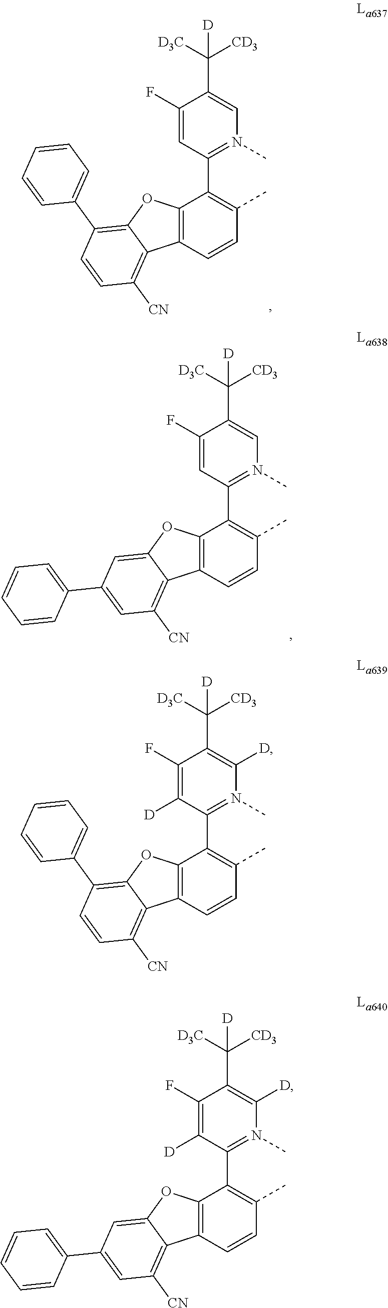

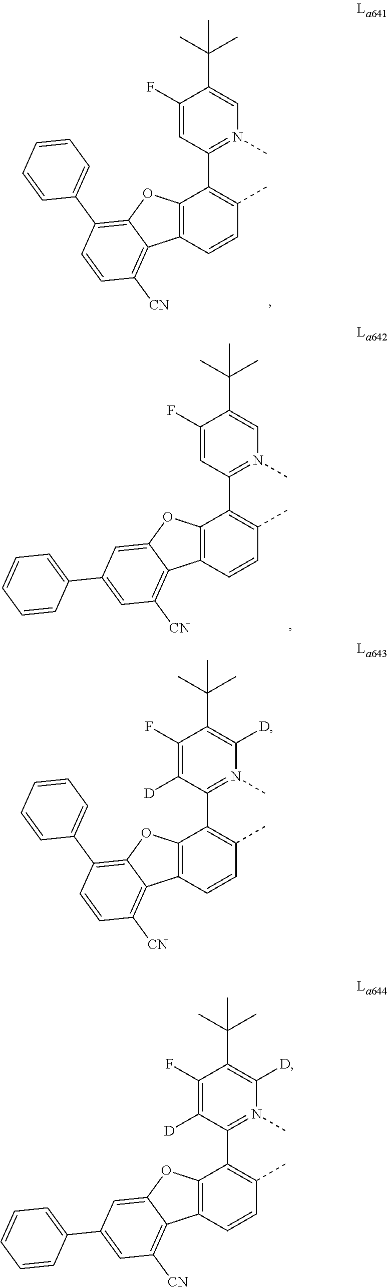

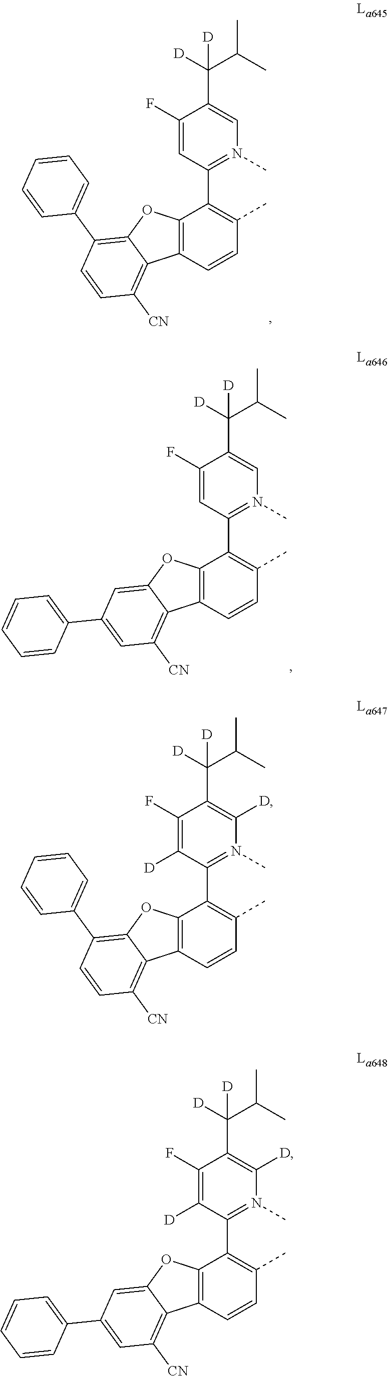

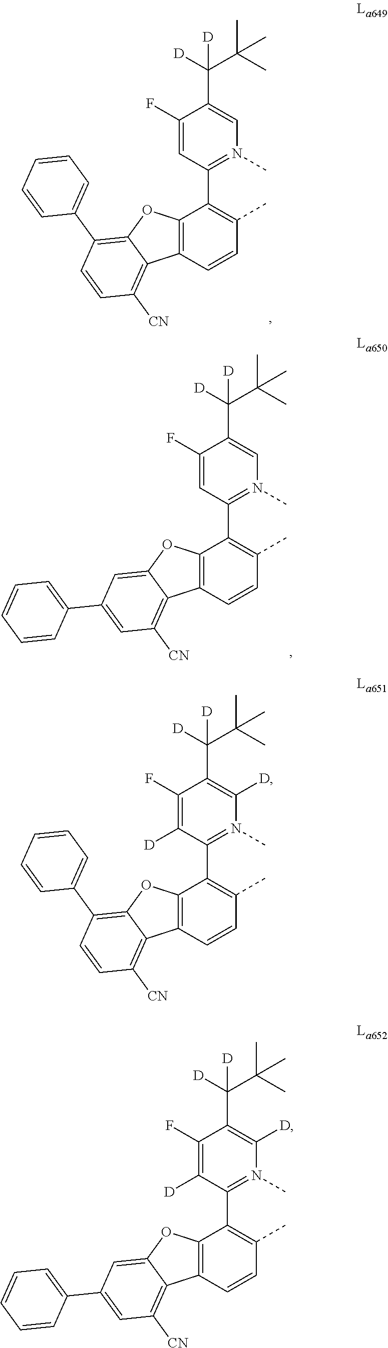

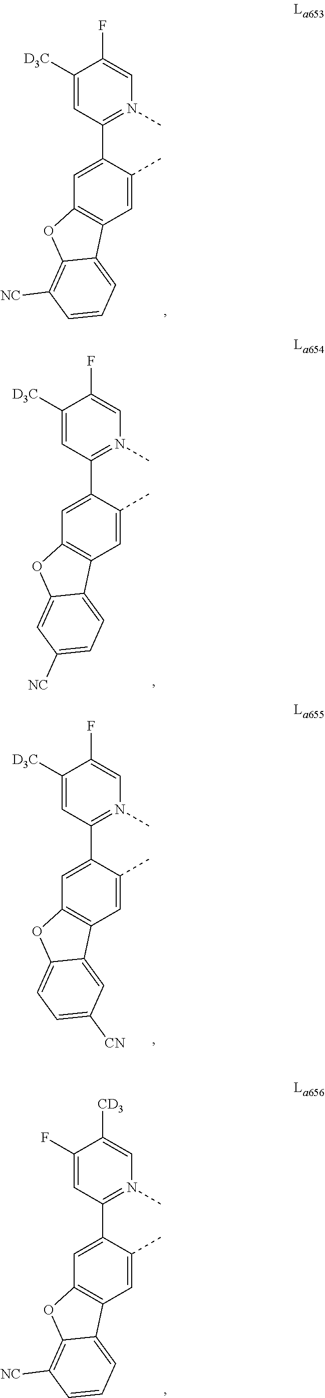

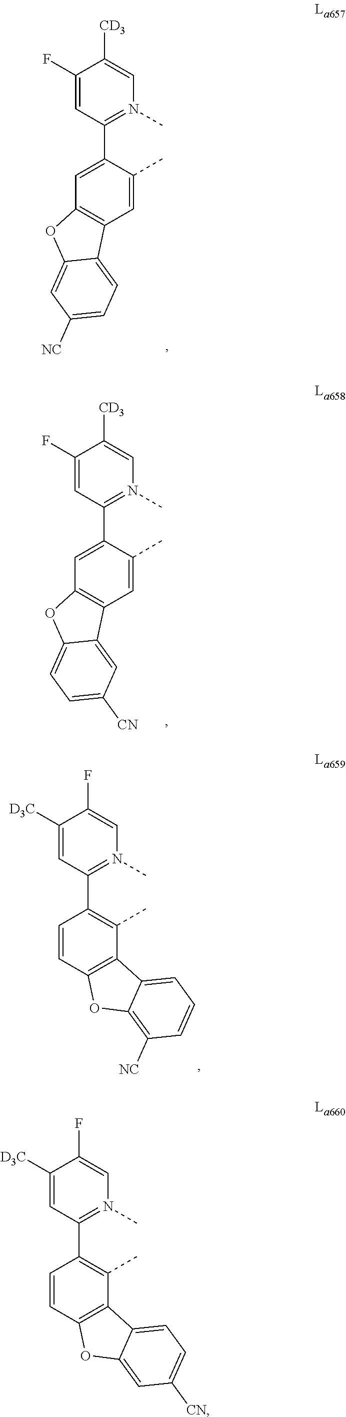

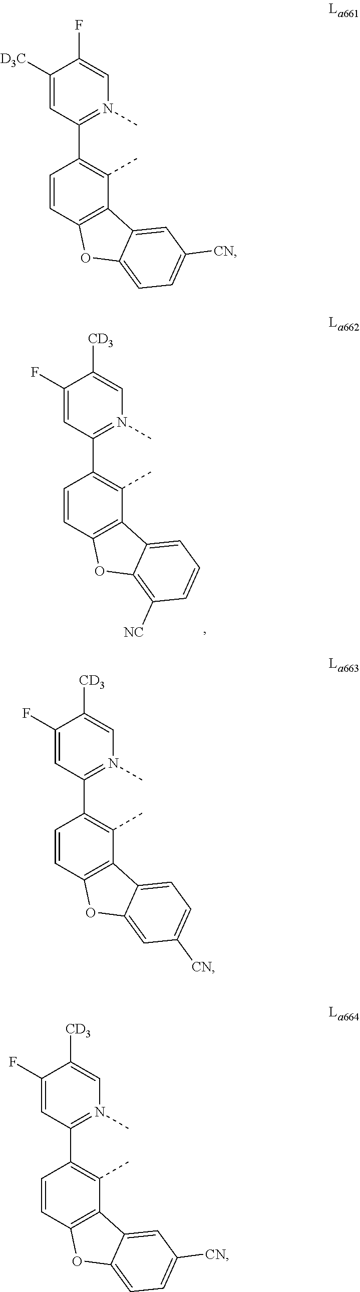

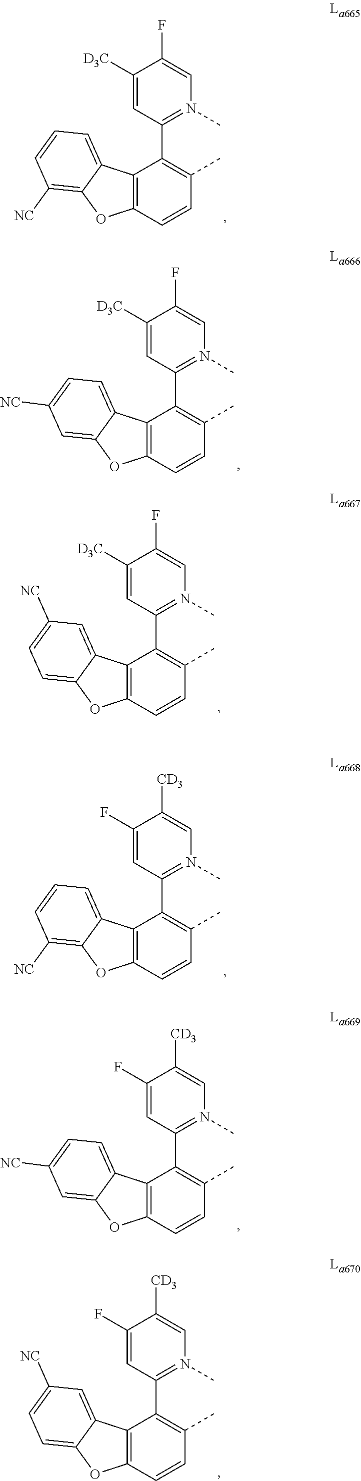

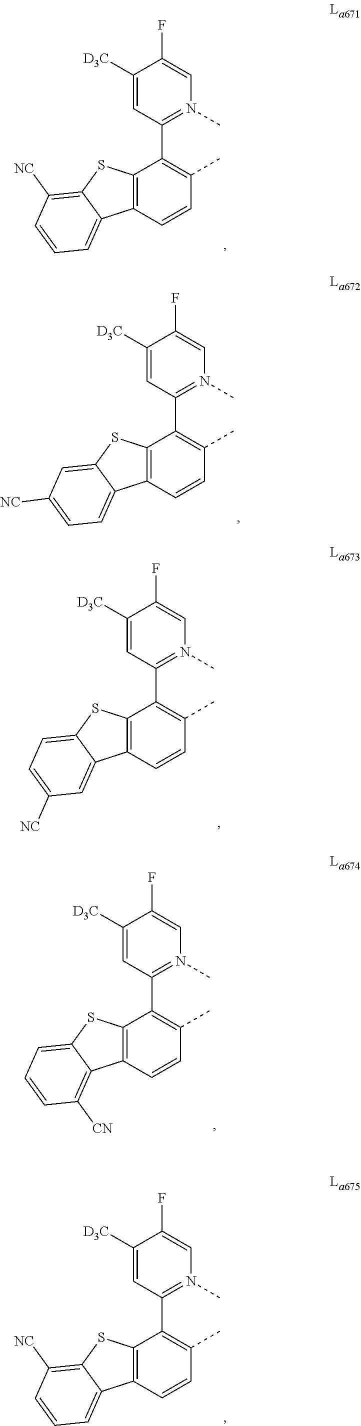

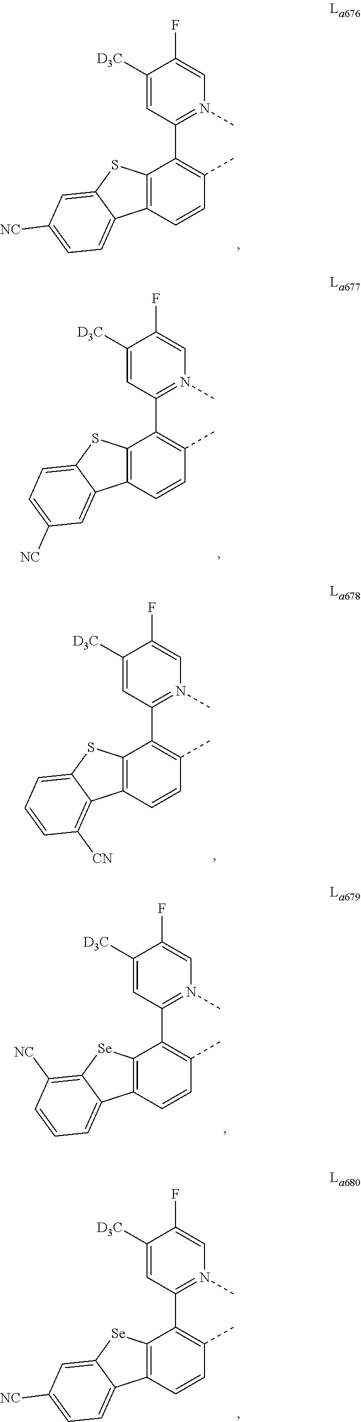

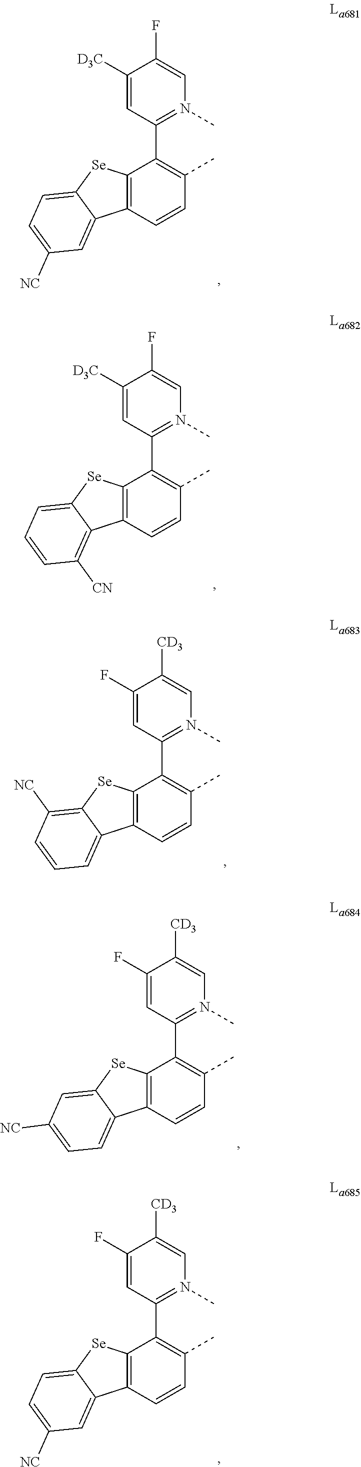

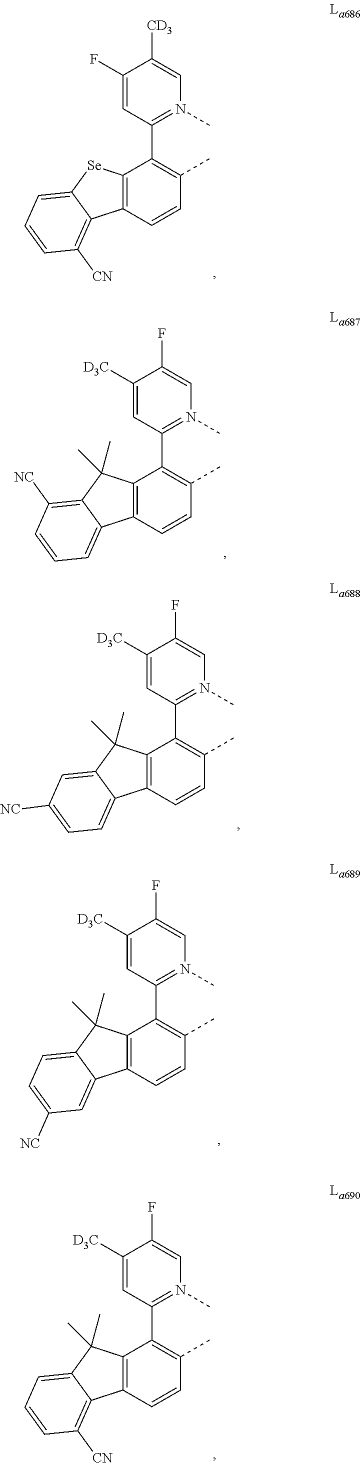

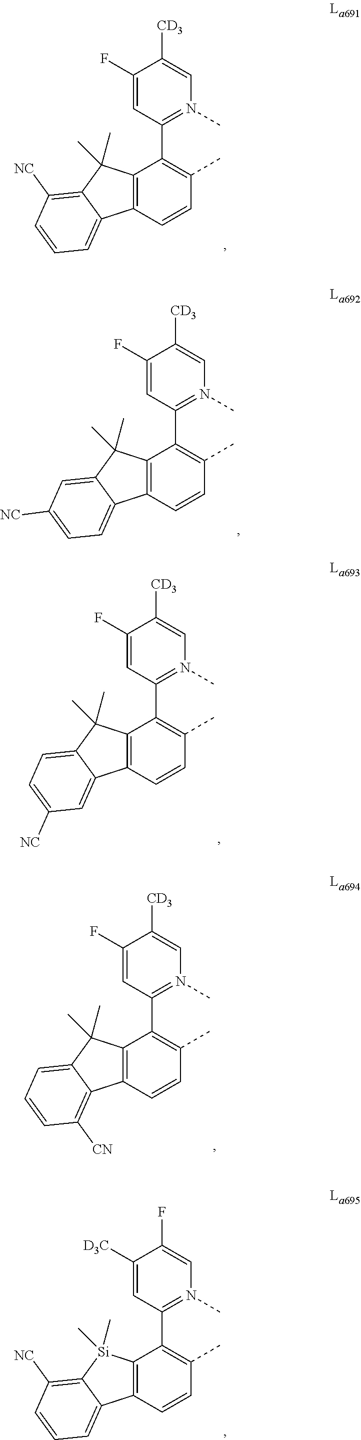

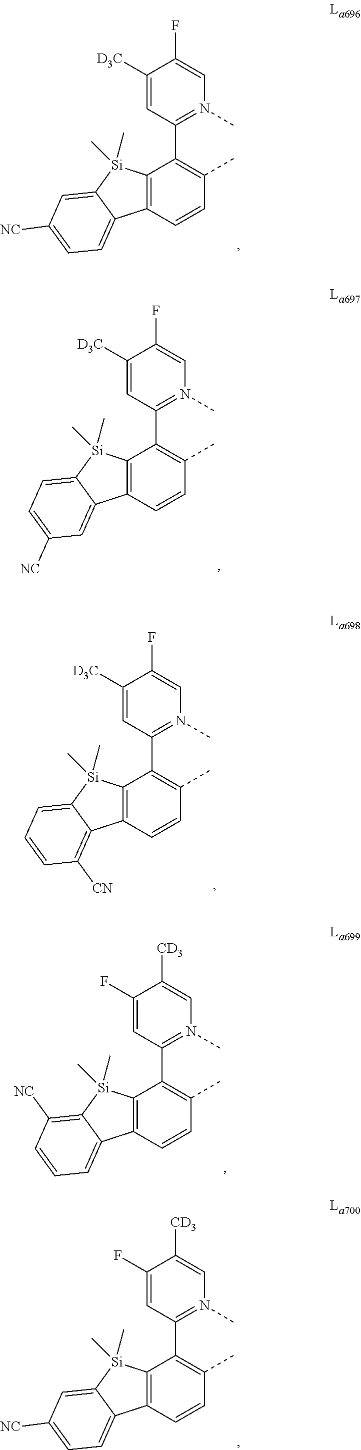

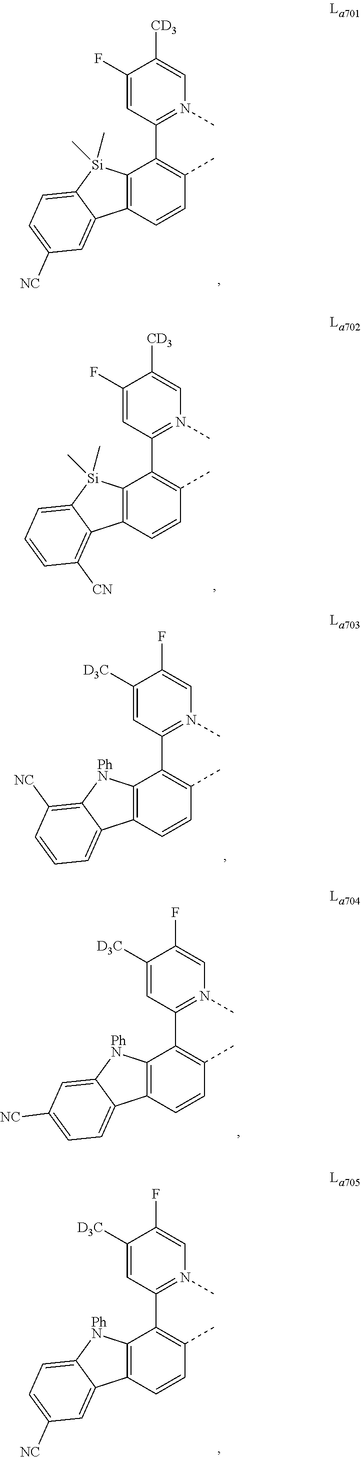

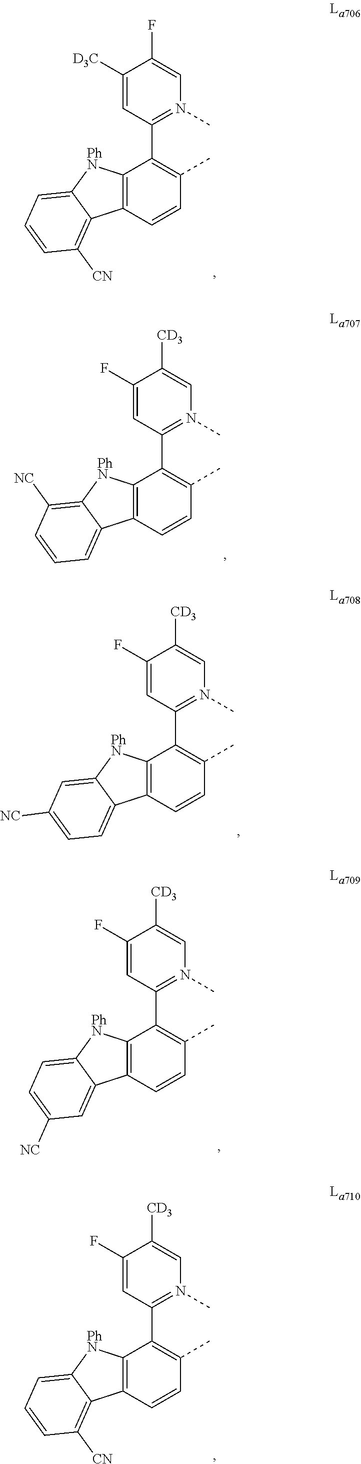

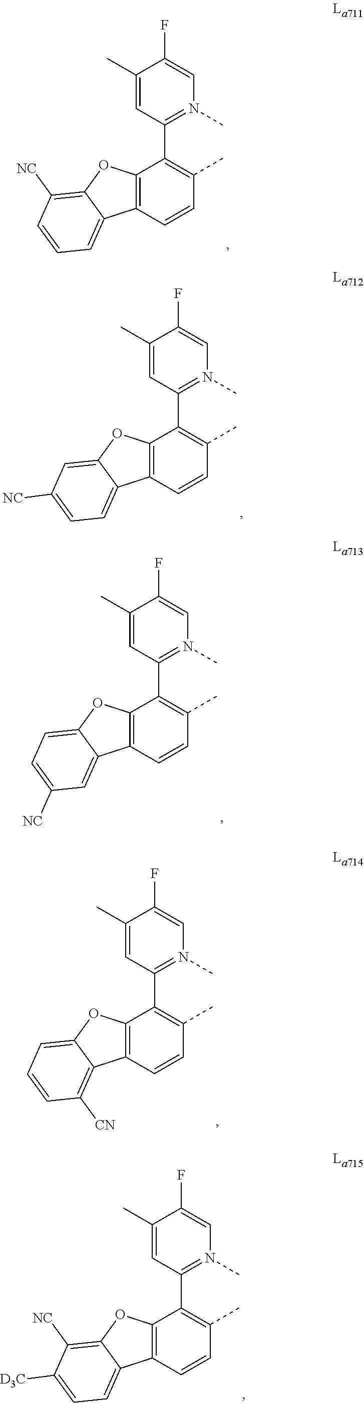

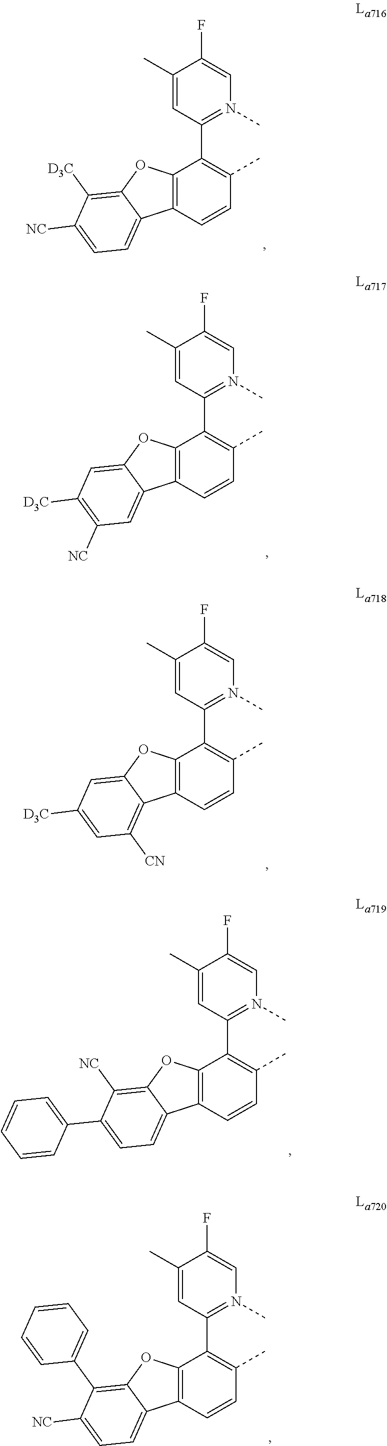

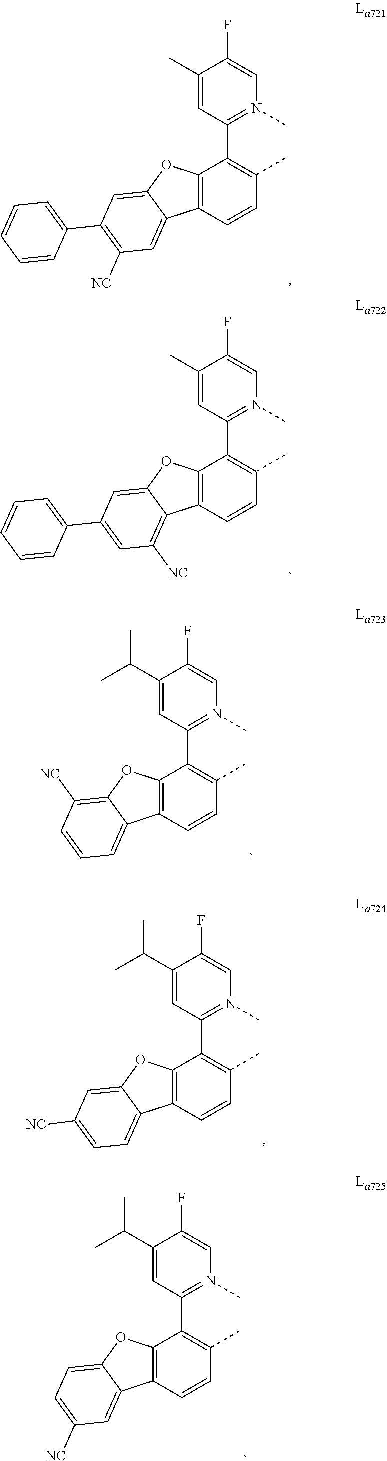

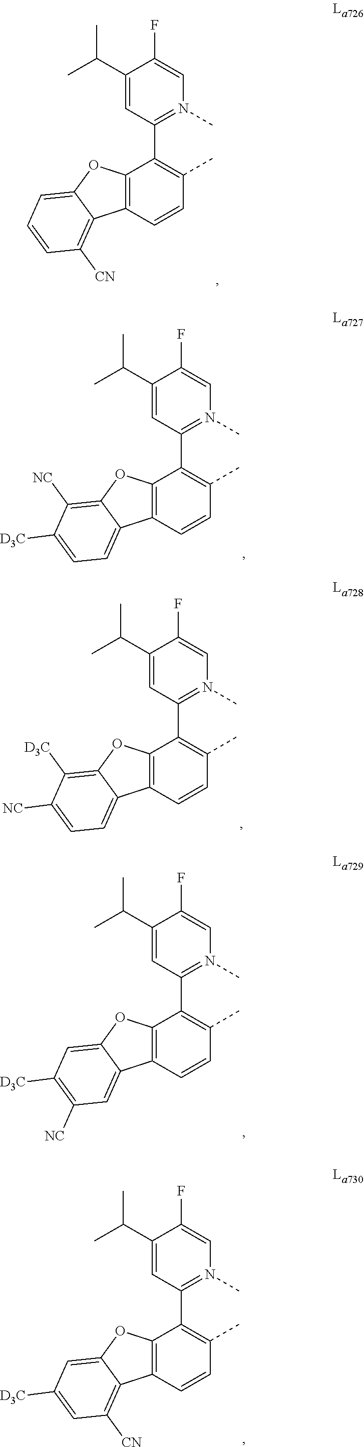

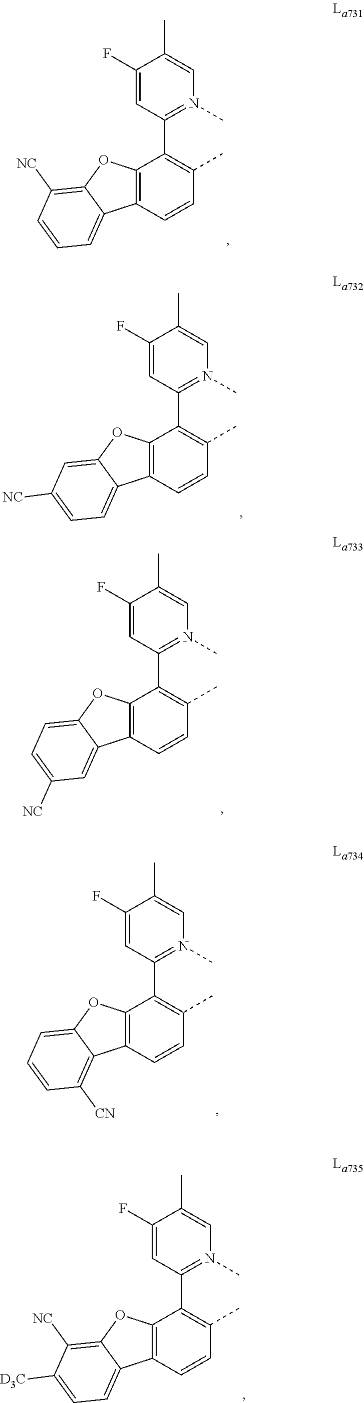

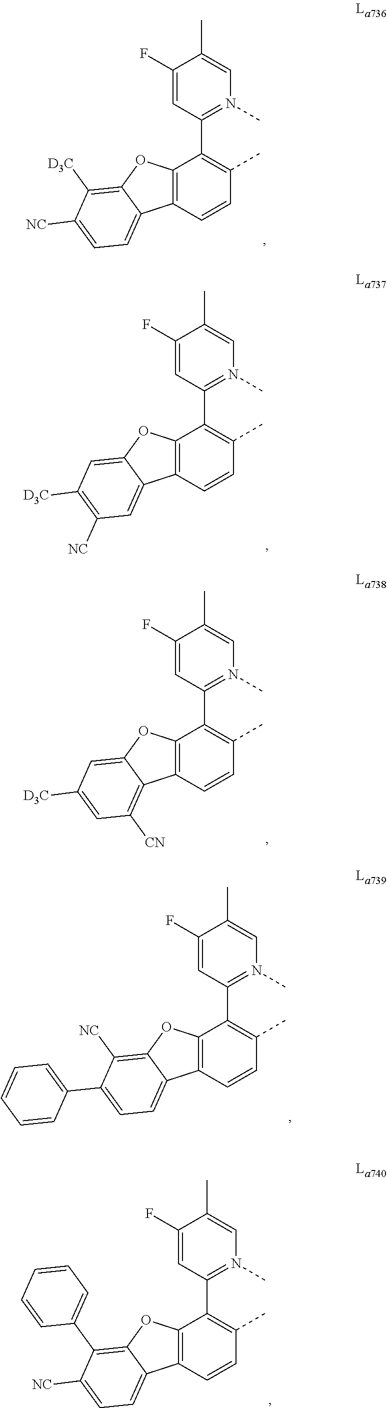

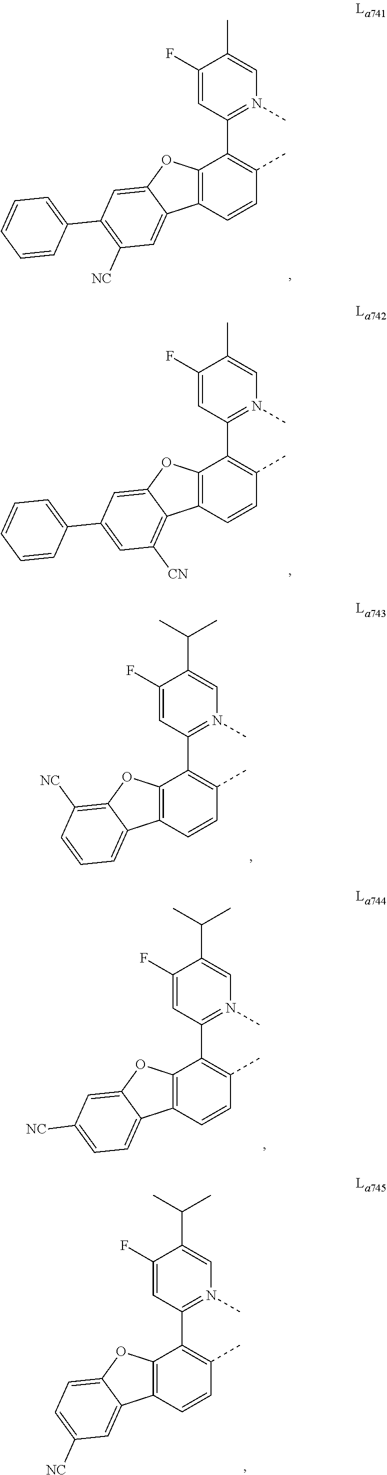

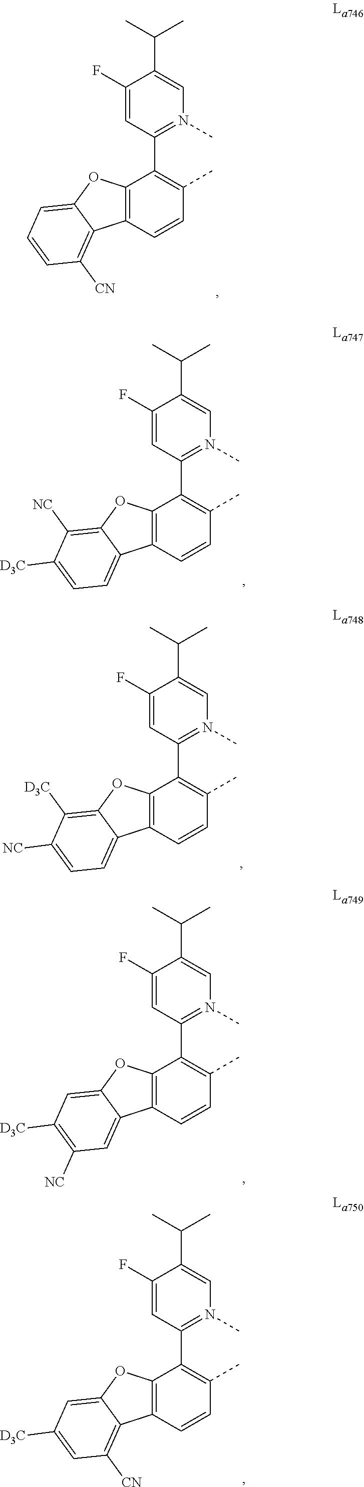

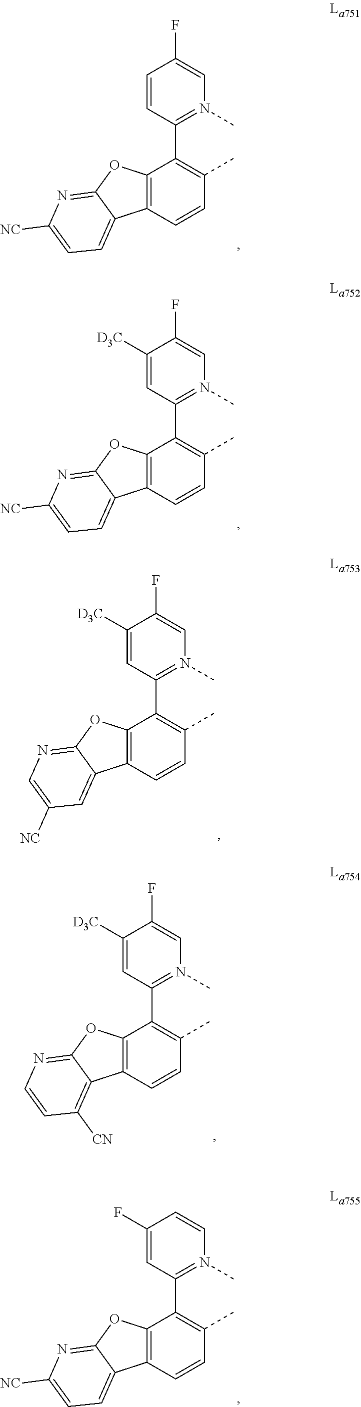

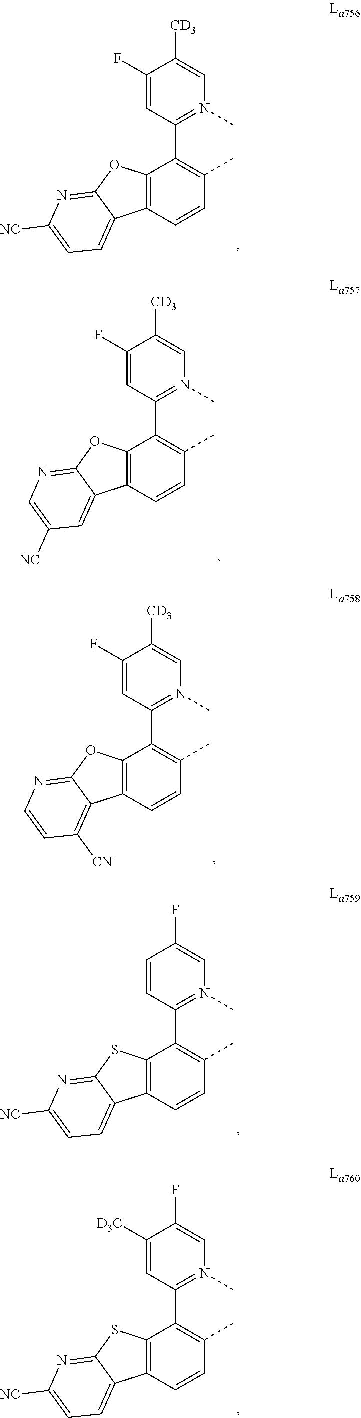

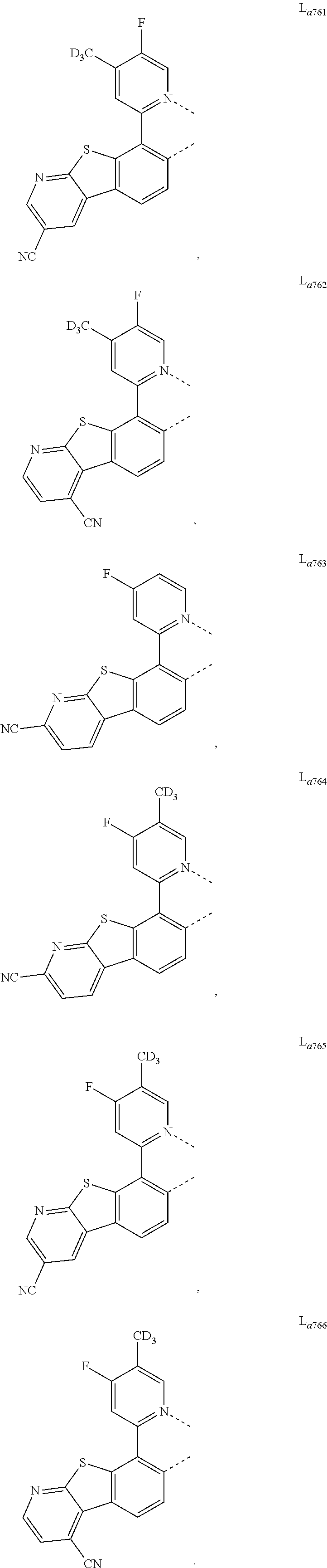

15. The metal complex of claim 14, wherein L_{b} is, at each occurrence identically or differently, selected from the group consisting of

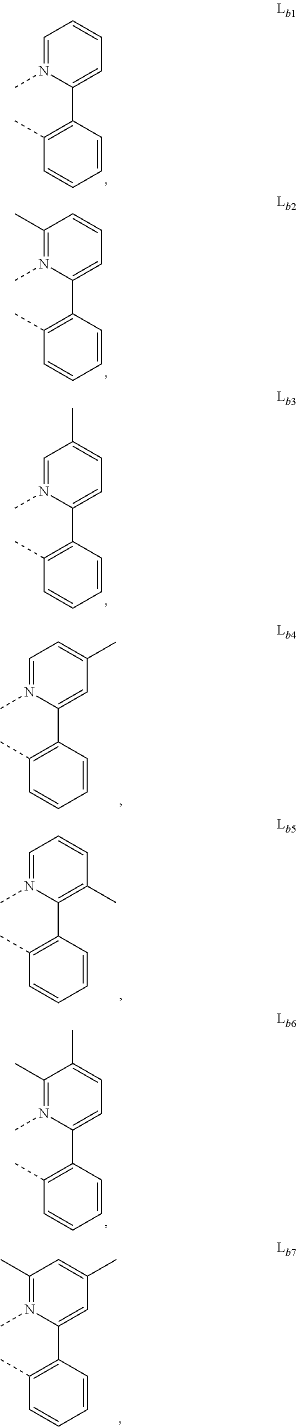

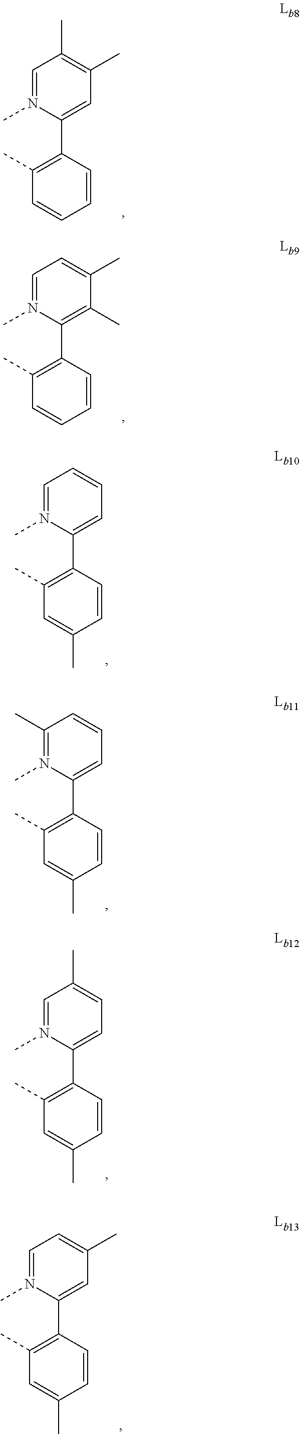

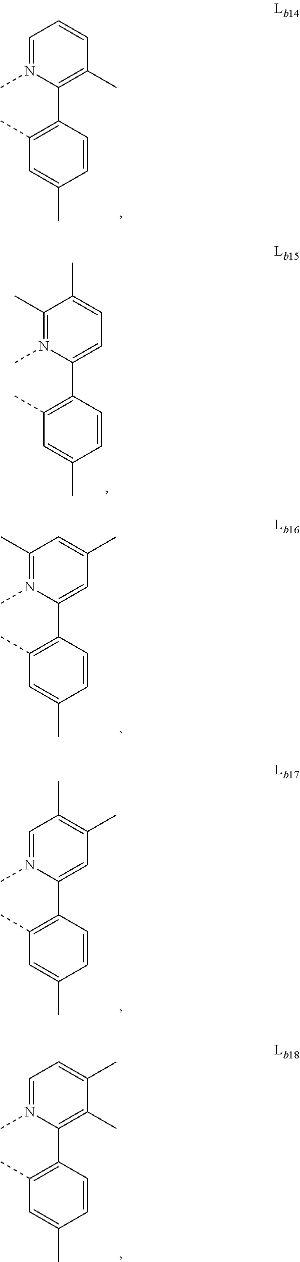

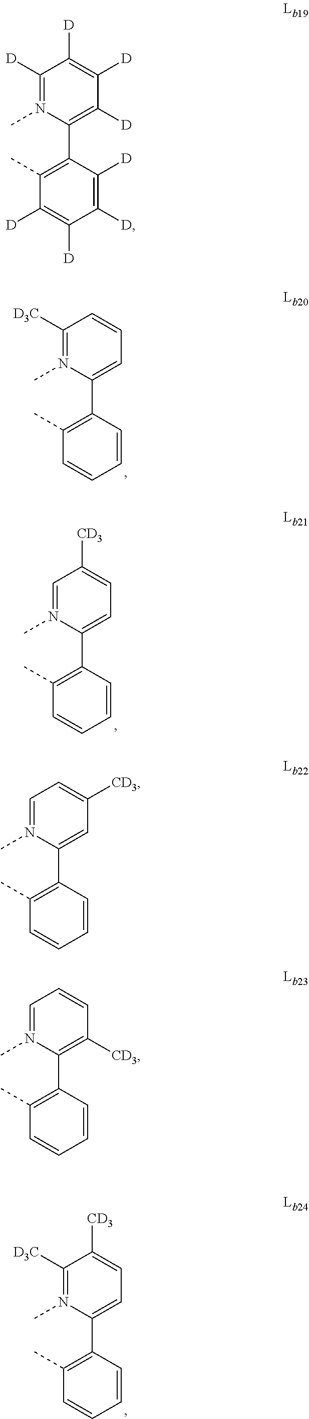

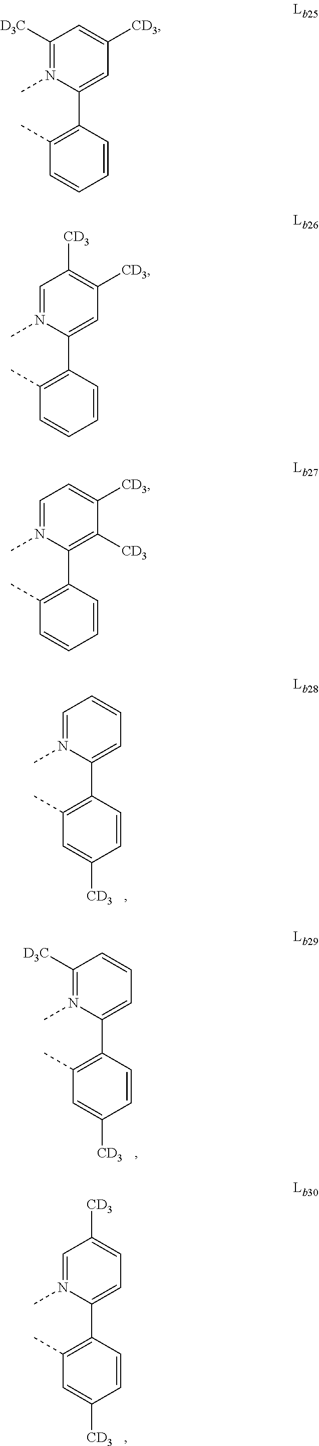

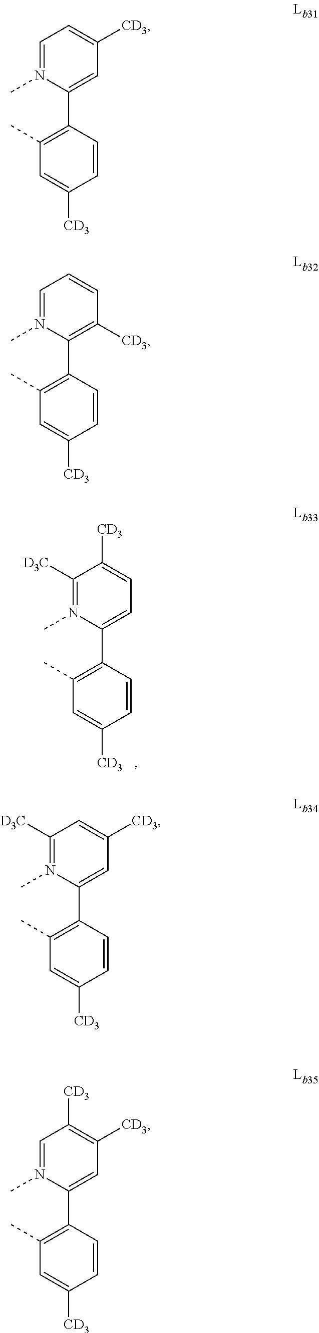

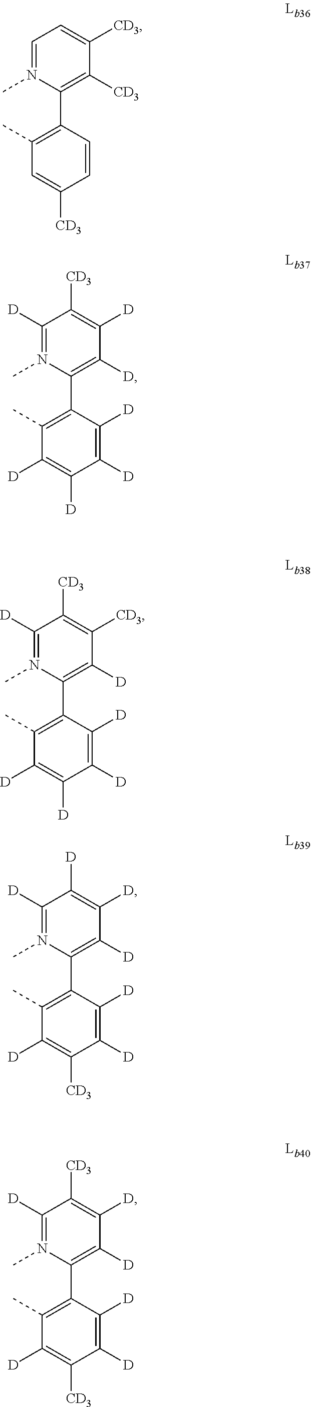

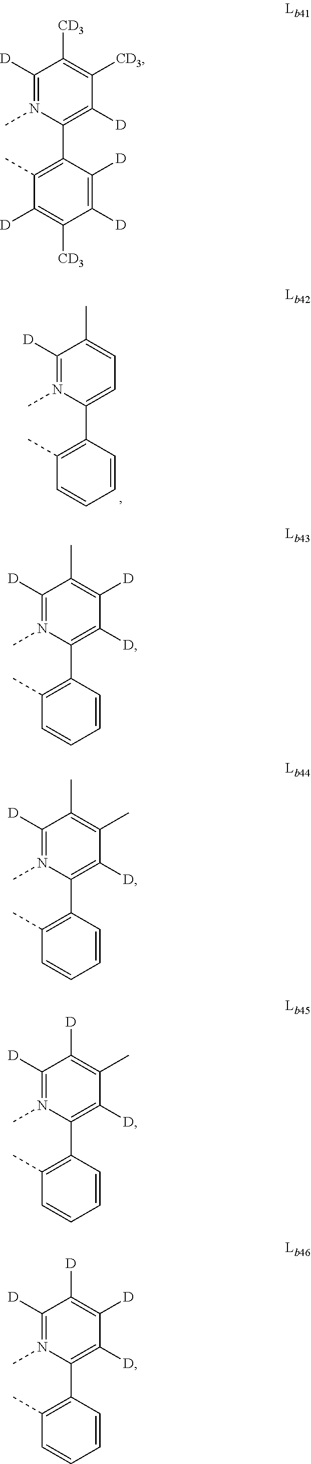

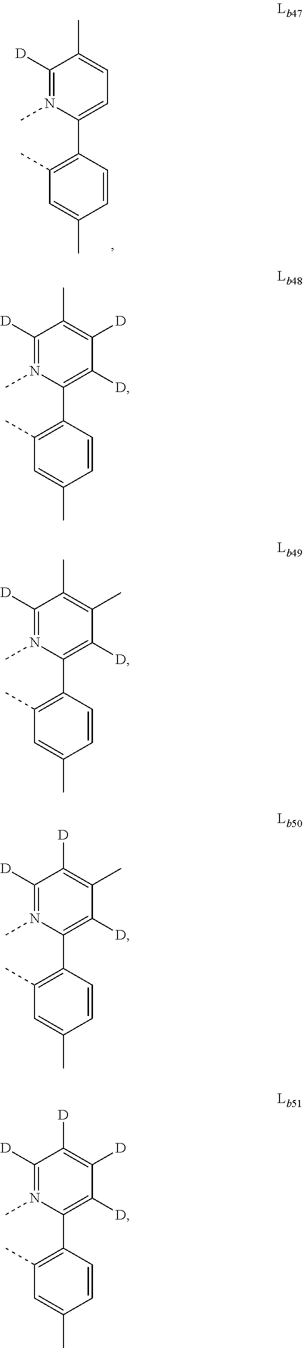

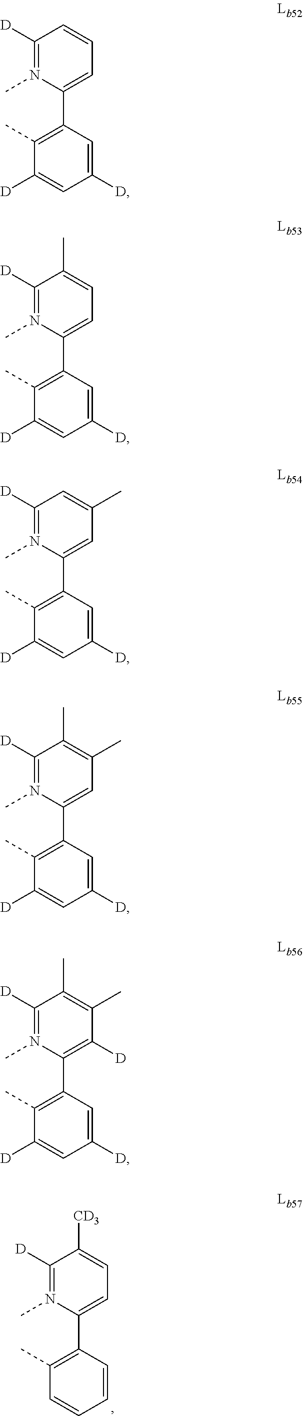

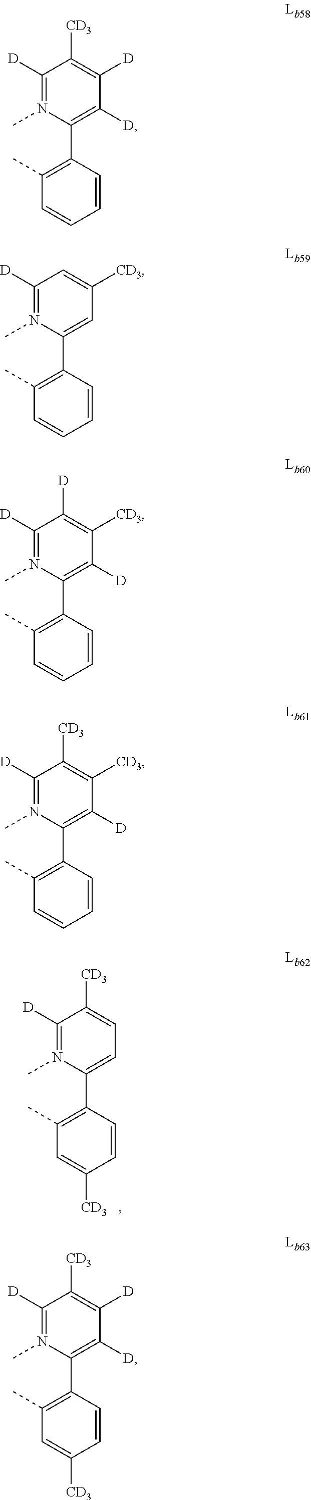

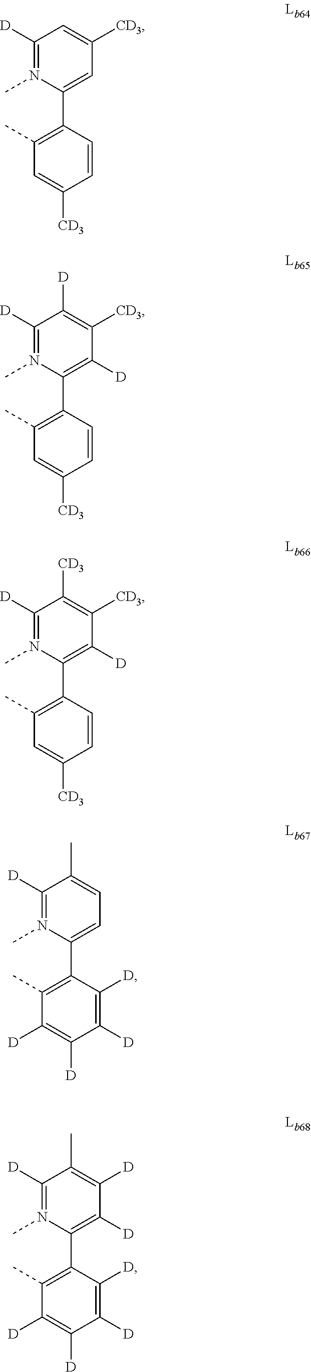

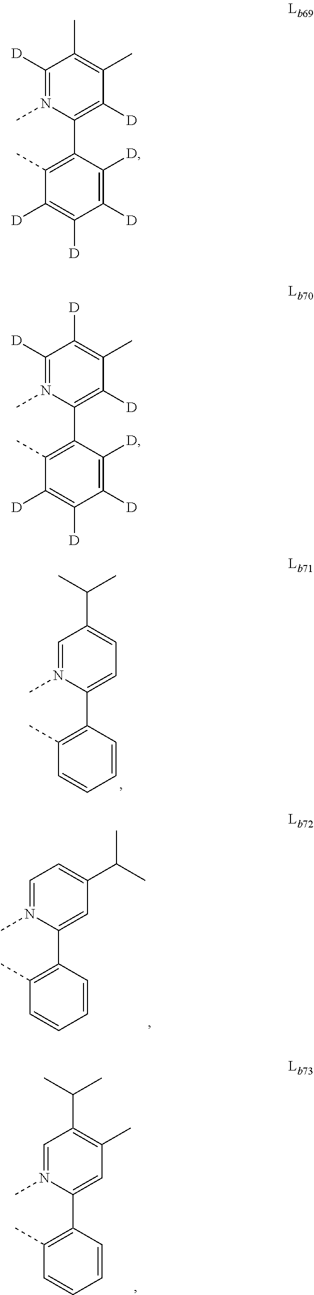

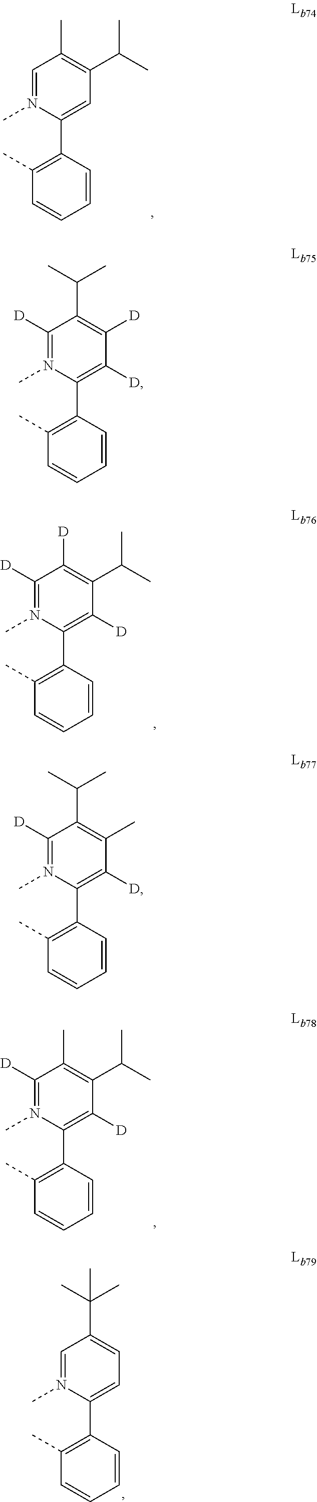

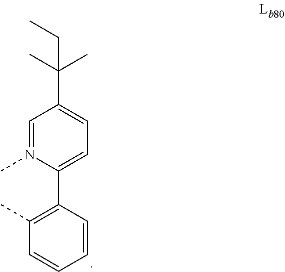

16. The metal complex of claim 15, wherein the metal complex has a structure of Ir(Lₐ)₂(L_{b}), Ir(Lₐ)(L_{b})₂ or Ir(Lₐ)₃, wherein Lₐ is, at each occurrence identically or differently, selected from any one, two or three of the group consisting of Lₐ₁ to Lₐ₇₆₆, and L_{b} is selected from any one or two of the group consisting of L_{b1} to L_{b80};
preferably, the metal complex is selected from the group consisting of Metal Complex 1 to Metal Complex 390, wherein Metal Complex 1 to Metal Complex 390 have the structure of IrLₐ(L_{b})₂, wherein the two L_{b} are identical, and Lₐ and L_{b} correspond to structures shown in the following table, respectively:

| Metal | | | Metal | | | Metal | | |
|---|---|---|---|---|---|---|---|---|
| Com- | | | Com- | | | Com- | | |
| plex | Lₐ | L_{b} | plex | Lₐ | L_{b} | plex | Lₐ | L_{b} |
| 1 | Lₐ₁ | L_{b1} | 2 | Lₐ₂ | L_{b1} | 3 | Lₐ₁₃ | L_{b1} |
| 4 | Lₐ₁₄ | L_{b1} | 5 | Lₐ₁₇ | L_{b1} | 6 | Lₐ₁₈ | L_{b1} |
| 7 | Lₐ₂₅ | L_{b1} | 8 | Lₐ₂₆ | L_{b1} | 9 | Lₐ₅₇ | L_{b1} |
| 10 | Lₐ₅₈ | L_{b1} | 11 | Lₐ₆₅ | L_{b1} | 12 | Lₐ₆₆ | L_{b1} |
| 13 | Lₐ₆₉ | L_{b1} | 14 | Lₐ₇₀ | L_{b1} | 15 | Lₐ₇₃ | L_{b1} |
| 16 | Lₐ₇₄ | L_{b1} | 17 | Lₐ₈₁ | L_{b1} | 18 | Lₐ₈₂ | L_{b1} |
| 19 | Lₐ₁₂₁ | L_{b1} | 20 | Lₐ₁₂₉ | L_{b1} | 21 | Lₐ₁₆₅ | L_{b1} |
| 22 | Lₐ₂₀₉ | L_{b1} | 23 | Lₐ₂₁₀ | L_{b1} | 24 | Lₐ₂₅₃ | L_{b1} |
| 25 | Lₐ₃₅₉ | L_{b1} | 26 | Lₐ₄₃₃ | L_{b1} | 27 | Lₐ₄₇₇ | L_{b1} |
| 28 | Lₐ₄₈₁ | L_{b1} | 29 | Lₐ₅₂₁ | L_{b1} | 30 | Lₐ₅₂₅ | L_{b1} |
| 31 | Lₐ₁ | L_{b3} | 32 | Lₐ₂ | L_{b3} | 33 | Lₐ₁₃ | L_{b3} |
| 34 | Lₐ₁₄ | L_{b3} | 35 | Lₐ₁₇ | L_{b3} | 36 | Lₐ₁₈ | L_{b3} |
| 37 | Lₐ₂₅ | L_{b3} | 38 | Lₐ₂₆ | L_{b3} | 39 | Lₐ₅₇ | L_{b3} |
| 40 | Lₐ₅₈ | L_{b3} | 41 | Lₐ₆₅ | L_{b3} | 42 | Lₐ₆₆ | L_{b3} |
| 43 | Lₐ₆₉ | L_{b3} | 44 | Lₐ₇₀ | L_{b3} | 45 | Lₐ₇₃ | L_{b3} |
| 46 | Lₐ₇₄ | L_{b3} | 47 | Lₐ₈₁ | L_{b3} | 48 | Lₐ₈₂ | L_{b3} |
| 49 | Lₐ₁₂₁ | L_{b3} | 50 | Lₐ₁₂₉ | L_{b3} | 51 | Lₐ₁₆₅ | L_{b3} |
| 52 | Lₐ₂₀₉ | L_{b3} | 53 | Lₐ₂₁₀ | L_{b3} | 54 | Lₐ₂₅₃ | L_{b3} |
| 55 | Lₐ₃₅₉ | L_{b3} | 56 | Lₐ₄₃₃ | L_{b3} | 57 | Lₐ₄₇₇ | L_{b3} |
| 58 | Lₐ₄₈₁ | L_{b3} | 59 | Lₐ₅₂₁ | L_{b3} | 60 | Lₐ₅₂₅ | L_{b3} |
| 61 | Lₐ₁ | L_{b4} | 62 | Lₐ₂ | L_{b4} | 63 | Lₐ₁₃ | L_{b4} |
| 64 | Lₐ₁₄ | L_{b4} | 65 | Lₐ₁₇ | L_{b4} | 66 | Lₐ₁₈ | L_{b4} |
| 67 | Lₐ₂₅ | L_{b4} | 68 | Lₐ₂₆ | L_{b4} | 69 | Lₐ₅₇ | L_{b4} |
| 70 | Lₐ₅₈ | L_{b4} | 71 | Lₐ₆₅ | L_{b4} | 72 | Lₐ₆₆ | L_{b4} |
| 73 | Lₐ₆₉ | L_{b4} | 74 | Lₐ₇₀ | L_{b4} | 75 | Lₐ₇₃ | L_{b4} |
| 76 | Lₐ₇₄ | L_{b4} | 77 | Lₐ₈₁ | L_{b4} | 78 | Lₐ₈₂ | L_{b4} |
| 79 | Lₐ₁₂₁ | L_{b4} | 80 | Lₐ₁₂₉ | L_{b4} | 81 | Lₐ₁₆₅ | L_{b4} |
| 82 | Lₐ₂₀₉ | L_{b4} | 83 | Lₐ₂₁₀ | L_{b4} | 84 | Lₐ₂₅₃ | L_{b4} |
| 85 | Lₐ₃₅₉ | L_{b4} | 86 | Lₐ₄₃₃ | L_{b4} | 87 | Lₐ₄₇₇ | L_{b4} |
| 88 | Lₐ₄₈₁ | L_{b4} | 89 | Lₐ₅₂₁ | L_{b4} | 90 | Lₐ₅₂₅ | L_{b4} |
| 91 | Lₐ₁ | L_{b8} | 92 | Lₐ₂ | L_{b8} | 93 | Lₐ₁₃ | L_{b8} |
| 94 | Lₐ₁₄ | L_{b8} | 95 | Lₐ₁₇ | L_{b8} | 96 | Lₐ₁₈ | L_{b8} |
| 97 | Lₐ₂₅ | L_{b8} | 98 | Lₐ₂₆ | L_{b8} | 99 | Lₐ₅₇ | L_{b8} |
| 100 | Lₐ₅₈ | L_{b8} | 101 | Lₐ₆₅ | L_{b8} | 102 | Lₐ₆₆ | L_{b8} |
| 103 | Lₐ₆₉ | L_{b8} | 104 | Lₐ₇₀ | L_{b8} | 105 | Lₐ₇₃ | L_{b8} |
| 106 | Lₐ₇₄ | L_{b8} | 107 | Lₐ₈₁ | L_{b8} | 108 | Lₐ₈₂ | L_{b8} |
| 109 | Lₐ₁₂₁ | L_{b8} | 110 | Lₐ₁₂₉ | L_{b8} | 111 | Lₐ₁₆₅ | L_{b8} |
| 112 | Lₐ₂₀₉ | L_{b8} | 113 | Lₐ₂₁₀ | L_{b8} | 114 | Lₐ₂₅₃ | L_{b8} |
| 115 | Lₐ₃₅₉ | L_{b8} | 116 | Lₐ₄₃₃ | L_{b8} | 117 | Lₐ₄₇₇ | L_{b8} |
| 118 | Lₐ₄₈₁ | L_{b8} | 119 | Lₐ₅₂₁ | L_{b8} | 120 | Lₐ₅₂₅ | L_{b8} |
| 121 | Lₐ₁ | L_{b19} | 122 | Lₐ₂ | L_{b19} | 123 | Lₐ₁₃ | L_{b19} |
| 124 | Lₐ₁₄ | L_{b19} | 125 | Lₐ₁₇ | L_{b19} | 126 | Lₐ₁₈ | L_{b19} |
| 127 | Lₐ₂₅ | L_{b19} | 128 | Lₐ₂₆ | L_{b19} | 129 | Lₐ₅₇ | L_{b19} |
| 130 | Lₐ₅₈ | L_{b19} | 131 | Lₐ₆₅ | L_{b19} | 132 | Lₐ₆₆ | L_{b19} |
| 133 | Lₐ₆₉ | L_{b19} | 134 | Lₐ₇₀ | L_{b19} | 135 | Lₐ₇₃ | L_{b19} |
| 136 | Lₐ₇₄ | L_{b19} | 137 | Lₐ₈₁ | L_{b19} | 138 | Lₐ₈₂ | L_{b19} |
| 139 | Lₐ₁₂₁ | L_{b19} | 140 | Lₐ₁₂₉ | L_{b19} | 141 | Lₐ₁₆₅ | L_{b19} |
| 142 | Lₐ₂₀₉ | L_{b19} | 143 | Lₐ₂₁₀ | L_{b19} | 144 | Lₐ₂₅₃ | L_{b19} |
| 145 | Lₐ₃₅₉ | L_{b19} | 146 | Lₐ₄₃₃ | L_{b19} | 147 | Lₐ₄₇₇ | L_{b19} |
| 148 | Lₐ₄₈₁ | L_{b19} | 149 | Lₐ₅₂₁ | L_{b19} | 150 | Lₐ₅₂₅ | L_{b19} |
| 151 | Lₐ₁ | L_{b21} | 152 | Lₐ₂ | L_{b21} | 153 | Lₐ₁₃ | L_{b21} |
| 154 | Lₐ₁₄ | L_{b21} | 155 | Lₐ₁₇ | L_{b21} | 156 | Lₐ₁₈ | L_{b21} |
| 157 | Lₐ₂₅ | L_{b21} | 158 | Lₐ₂₆ | L_{b21} | 159 | Lₐ₅₇ | L_{b21} |
| 160 | Lₐ₅₈ | L_{b21} | 161 | Lₐ₆₅ | L_{b21} | 162 | Lₐ₆₆ | L_{b21} |
| 163 | Lₐ₆₉ | L_{b21} | 164 | Lₐ₇₀ | L_{b21} | 165 | Lₐ₇₃ | L_{b21} |
| 166 | Lₐ₇₄ | L_{b21} | 167 | Lₐ₈₁ | L_{b21} | 168 | Lₐ₈₂ | L_{b21} |
| 169 | Lₐ₁₂₁ | L_{b21} | 170 | Lₐ₁₂₉ | L_{b21} | 171 | Lₐ₁₆₅ | L_{b21} |
| 172 | Lₐ₂₀₉ | L_{b21} | 173 | Lₐ₂₁₀ | L_{b21} | 174 | Lₐ₂₅₃ | L_{b21} |
| 175 | Lₐ₃₅₉ | L_{b21} | 176 | Lₐ₄₃₃ | L_{b21} | 177 | Lₐ₄₇₇ | L_{b21} |
| 178 | Lₐ₄₈₁ | L_{b21} | 179 | Lₐ₅₂₁ | L_{b21} | 180 | Lₐ₅₂₅ | L_{b21} |
| 181 | Lₐ₁ | L_{b22} | 182 | Lₐ₂ | L_{b22} | 183 | Lₐ₁₃ | L_{b22} |
| 184 | Lₐ₁₄ | L_{b22} | 185 | Lₐ₁₇ | L_{b22} | 186 | Lₐ₁₈ | L_{b22} |
| 187 | Lₐ₂₅ | L_{b22} | 188 | Lₐ₂₆ | L_{b22} | 189 | Lₐ₅₇ | L_{b22} |
| 190 | Lₐ₅₈ | L_{b22} | 191 | Lₐ₆₅ | L_{b22} | 192 | Lₐ₆₆ | L_{b22} |
| 193 | Lₐ₆₉ | L_{b22} | 194 | Lₐ₇₀ | L_{b22} | 195 | Lₐ₇₃ | L_{b22} |
| 196 | Lₐ₇₄ | L_{b22} | 197 | Lₐ₈₁ | L_{b22} | 198 | Lₐ₈₂ | L_{b22} |
| 199 | Lₐ₁₂₁ | L_{b22} | 200 | Lₐ₁₂₉ | L_{b22} | 201 | Lₐ₁₆₅ | L_{b22} |
| 202 | Lₐ₂₀₉ | L_{b22} | 203 | Lₐ₂₁₀ | L_{b22} | 204 | Lₐ₂₅₃ | L_{b22} |
| 205 | Lₐ₃₅₉ | L_{b22} | 206 | Lₐ₄₃₃ | L_{b22} | 207 | Lₐ₄₇₇ | L_{b22} |
| 208 | Lₐ₄₈₁ | L_{b22} | 209 | Lₐ₅₂₁ | L_{b22} | 210 | Lₐ₅₂₅ | L_{b22} |
| 211 | Lₐ₁ | L_{b57} | 212 | Lₐ₂ | L_{b57} | 213 | Lₐ₁₃ | L_{b57} |
| 214 | Lₐ₁₄ | L_{b57} | 215 | Lₐ₁₇ | L_{b57} | 216 | Lₐ₁₈ | L_{b57} |
| 217 | Lₐ₂₅ | L_{b57} | 218 | Lₐ₂₆ | L_{b57} | 219 | Lₐ₅₇ | L_{b57} |
| 220 | Lₐ₅₈ | L_{b57} | 221 | Lₐ₆₅ | L_{b57} | 222 | Lₐ₆₆ | L_{b57} |
| 223 | Lₐ₆₉ | L_{b57} | 224 | Lₐ₇₀ | L_{b57} | 225 | Lₐ₇₃ | L_{b57} |
| 226 | Lₐ₇₄ | L_{b57} | 227 | Lₐ₈₁ | L_{b57} | 228 | Lₐ₈₂ | L_{b57} |
| 229 | Lₐ₁₂₁ | L_{b57} | 230 | Lₐ₁₂₉ | L_{b57} | 231 | Lₐ₁₆₅ | L_{b57} |
| 232 | Lₐ₂₀₉ | L_{b57} | 233 | Lₐ₂₁₀ | L_{b57} | 234 | Lₐ₂₅₃ | L_{b57} |
| 235 | Lₐ₃₅₉ | L_{b57} | 236 | Lₐ₄₃₃ | L_{b57} | 237 | Lₐ₄₇₇ | L_{b57} |
| 238 | Lₐ₄₈₁ | L_{b57} | 239 | Lₐ₅₂₁ | L_{b57} | 240 | Lₐ₅₂₅ | L_{b57} |
| 241 | Lₐ₁ | L_{b58} | 242 | Lₐ₂ | L_{b58} | 243 | Lₐ₁₃ | L_{b58} |
| 244 | Lₐ₁₄ | L_{b58} | 245 | Lₐ₁₇ | L_{b58} | 246 | Lₐ₁₈ | L_{b58} |
| 247 | Lₐ₂₅ | L_{b58} | 248 | Lₐ₂₆ | L_{b58} | 249 | Lₐ₅₇ | L_{b58} |
| 250 | Lₐ₅₈ | L_{b58} | 251 | Lₐ₆₅ | L_{b58} | 252 | Lₐ₆₆ | L_{b58} |
| 253 | Lₐ₆₉ | L_{b58} | 254 | Lₐ₇₀ | L_{b58} | 255 | Lₐ₇₃ | L_{b58} |
| 256 | Lₐ₇₄ | L_{b58} | 257 | Lₐ₈₁ | L_{b58} | 258 | Lₐ₈₂ | L_{b58} |
| 259 | Lₐ₁₂₁ | L_{b58} | 260 | Lₐ₁₂₉ | L_{b58} | 261 | Lₐ₁₆₅ | L_{b58} |
| 262 | Lₐ₂₀₉ | L_{b58} | 263 | Lₐ₂₁₀ | L_{b58} | 264 | Lₐ₂₅₃ | L_{b58} |
| 265 | Lₐ₃₅₉ | L_{b58} | 266 | Lₐ₄₃₃ | L_{b58} | 267 | Lₐ₄₇₇ | L_{b58} |
| 268 | Lₐ₄₈₁ | L_{b58} | 269 | Lₐ₅₂₁ | L_{b58} | 270 | Lₐ₅₂₅ | L_{b58} |
| 271 | Lₐ₁ | L_{b459} | 272 | Lₐ₂ | L_{b459} | 273 | Lₐ₁₃ | L_{b459} |
| 274 | Lₐ₁₄ | L_{b459} | 275 | Lₐ₁₇ | L_{b459} | 276 | Lₐ₁₈ | L_{b459} |
| 277 | Lₐ₂₅ | L_{b459} | 278 | Lₐ₂₆ | L_{b459} | 279 | Lₐ₅₇ | L_{b459} |
| 280 | Lₐ₅₈ | L_{b459} | 281 | Lₐ₆₅ | L_{b459} | 282 | Lₐ₆₆ | L_{b459} |
| 283 | Lₐ₆₉ | L_{b459} | 284 | Lₐ₇₀ | L_{b459} | 285 | Lₐ₇₃ | L_{b459} |
| 286 | Lₐ₇₄ | L_{b459} | 287 | Lₐ₈₁ | L_{b459} | 288 | Lₐ₈₂ | L_{b459} |
| 289 | Lₐ₁₂₁ | L_{b459} | 290 | Lₐ₁₂₉ | L_{b459} | 291 | Lₐ₁₆₅ | L_{b459} |
| 292 | Lₐ₂₀₉ | L_{b459} | 293 | Lₐ₂₁₀ | L_{b459} | 294 | Lₐ₂₅₃ | L_{b459} |
| 295 | Lₐ₃₅₉ | L_{b459} | 296 | Lₐ₄₃₃ | L_{b459} | 297 | Lₐ₄₇₇ | L_{b459} |
| 298 | Lₐ₄₈₁ | L_{b459} | 299 | Lₐ₅₂₁ | L_{b459} | 300 | Lₐ₅₂₅ | L_{b459} |
| 301 | Lₐ₁ | L_{b60} | 302 | Lₐ₂ | L_{b60} | 303 | Lₐ₁₃ | L_{b60} |
| 304 | Lₐ₁₄ | L_{b60} | 305 | Lₐ₁₇ | L_{b60} | 306 | Lₐ₁₈ | L_{b60} |
| 307 | Lₐ₂₅ | L_{b60} | 308 | Lₐ₂₆ | L_{b60} | 309 | Lₐ₅₇ | L_{b60} |
| 310 | Lₐ₅₈ | L_{b60} | 311 | Lₐ₆₅ | L_{b60} | 312 | Lₐ₆₆ | L_{b60} |
| 313 | Lₐ₆₉ | L_{b60} | 314 | Lₐ₇₀ | L_{b60} | 315 | Lₐ₇₃ | L_{b60} |
| 316 | Lₐ₇₄ | L_{b60} | 317 | Lₐ₈₁ | L_{b60} | 318 | Lₐ₈₂ | L_{b60} |
| 319 | Lₐ₁₂₁ | L_{b60} | 320 | Lₐ₁₂₉ | L_{b60} | 321 | Lₐ₁₆₅ | L_{b60} |
| 322 | Lₐ₂₀₉ | L_{b60} | 323 | Lₐ₂₁₀ | L_{b60} | 324 | Lₐ₂₅₃ | L_{b60} |
| 325 | Lₐ₃₅₉ | L_{b60} | 326 | Lₐ₄₃₃ | L_{b60} | 327 | Lₐ₄₇₇ | L_{b60} |
| 328 | Lₐ₄₈₁ | L_{b60} | 329 | Lₐ₅₂₁ | L_{b60} | 330 | Lₐ₅₂₅ | L_{b60} |
| 331 | Lₐ₁ | L_{b61} | 332 | Lₐ₂ | L_{b61} | 333 | Lₐ₁₃ | L_{b61} |
| 334 | Lₐ₁₄ | L_{b61} | 335 | Lₐ₁₇ | L_{b61} | 336 | Lₐ₁₈ | L_{b61} |
| 337 | Lₐ₂₅ | L_{b61} | 338 | Lₐ₂₆ | L_{b61} | 339 | Lₐ₅₇ | L_{b61} |
| 340 | Lₐ₅₈ | L_{b61} | 341 | Lₐ₆₅ | L_{b61} | 342 | Lₐ₆₆ | L_{b61} |
| 343 | Lₐ₆₉ | L_{b61} | 344 | Lₐ₇₀ | L_{b61} | 345 | Lₐ₇₃ | L_{b61} |
| 346 | Lₐ₇₄ | L_{b61} | 347 | Lₐ₈₁ | L_{b61} | 348 | Lₐ₈₂ | L_{b61} |
| 349 | Lₐ₁₂₁ | L_{b61} | 350 | Lₐ₁₂₉ | L_{b61} | 351 | Lₐ₁₆₅ | L_{b61} |
| 352 | Lₐ₂₀₉ | L_{b61} | 353 | Lₐ₂₁₀ | L_{b61} | 354 | Lₐ₂₅₃ | L_{b61} |
| 355 | Lₐ₃₅₉ | L_{b61} | 356 | Lₐ₄₃₃ | L_{b61} | 357 | Lₐ₄₇₇ | L_{b61} |
| 358 | Lₐ₄₈₁ | L_{b61} | 359 | Lₐ₅₂₁ | L_{b61} | 360 | Lₐ₅₂₅ | L_{b61} |
| 361 | Lₐ₁ | L_{b79} | 362 | Lₐ₂ | L_{b79} | 363 | Lₐ₁₃ | L_{b79} |
| 364 | Lₐ₁₄ | L_{b79} | 365 | Lₐ₁₇ | L_{b79} | 366 | Lₐ₁₈ | L_{b79} |
| 367 | Lₐ₂₅ | L_{b79} | 368 | Lₐ₂₆ | L_{b79} | 369 | Lₐ₅₇ | L_{b79} |
| 370 | Lₐ₅₈ | L_{b79} | 371 | Lₐ₆₅ | L_{b79} | 372 | Lₐ₆₆ | L_{b79} |
| 373 | Lₐ₆₉ | L_{b79} | 374 | Lₐ₇₀ | L_{b79} | 375 | Lₐ₇₃ | L_{b79} |
| 376 | Lₐ₇₄ | L_{b79} | 377 | Lₐ₈₁ | L_{b79} | 378 | Lₐ₈₂ | L_{b79} |
| 379 | Lₐ₁₂₁ | L_{b79} | 380 | Lₐ₁₂₉ | L_{b79} | 381 | Lₐ₁₆₅ | L_{b79} |
| 382 | Lₐ₂₀₉ | L_{b79} | 383 | Lₐ₂₁₀ | L_{b79} | 384 | Lₐ₂₅₃ | L_{b79} |
| 385 | Lₐ₃₅₉ | L_{b79} | 386 | Lₐ₄₃₃ | L_{b79} | 387 | Lₐ₄₇₇ | L_{b79} |
| 388 | Lₐ₄₈₁ | L_{b79} | 389 | Lₐ₅₂₁ | L_{b79} | 390 | Lₐ₅₂₅ | L_{b79} |

17. An electroluminescent device, comprising:
an anode,
a cathode, and
an organic layer disposed between the anode and the cathode, wherein at least one layer of the organic layer contains the metal complex of claim 1.

18. The electroluminescent device of claim 17, wherein the organic layer containing the metal complex is a light-emitting layer.

19. The electroluminescent device of claim 18, wherein the light-emitting layer emits green light.

20. The electroluminescent device of claim 18, wherein the light-emitting layer contains at least one first host compound;
preferably, the light-emitting layer further contains at least two host compounds; and
more preferably, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

21. The electroluminescent device of claim 20, wherein the first host compound has a structure represented by Formula 3: 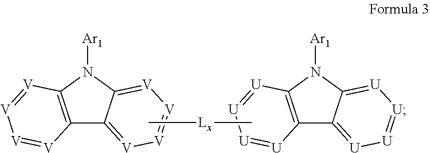
wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof,
V is, at each occurrence identically or differently, selected from C, CRᵥ or N, and at least one V is C and joined to Lₓ;
U is, at each occurrence identically or differently, selected from C, CRᵤ or N, and at least one U is C and joined to Lₓ;
Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof,
adjacent substituents Rᵥ and Rᵤ can be optionally joined to form a ring; and
preferably, wherein the first host compound has a structure represented by one of Formulas 3-a to 3-j:

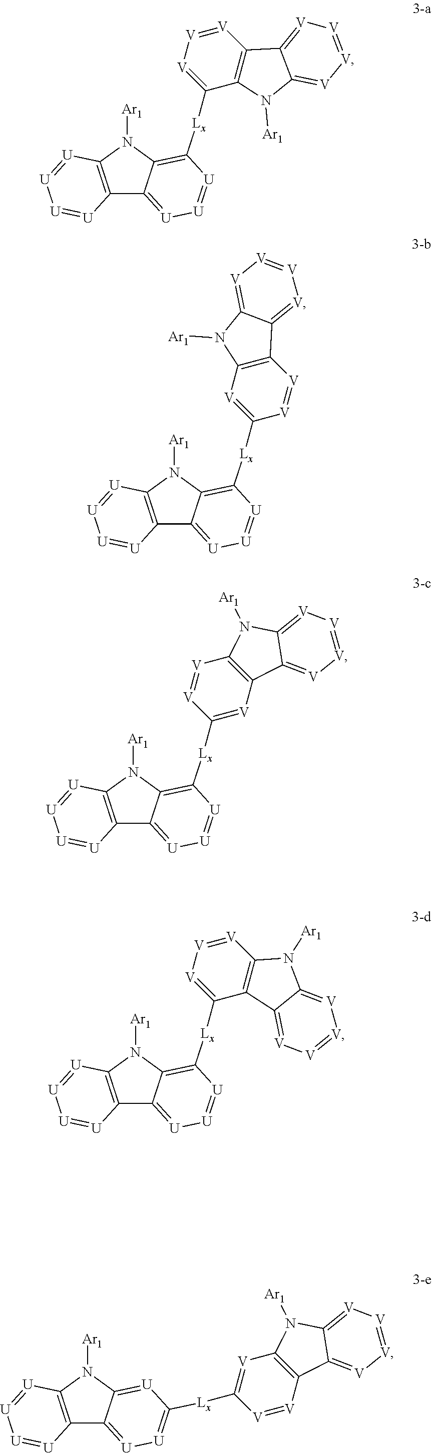

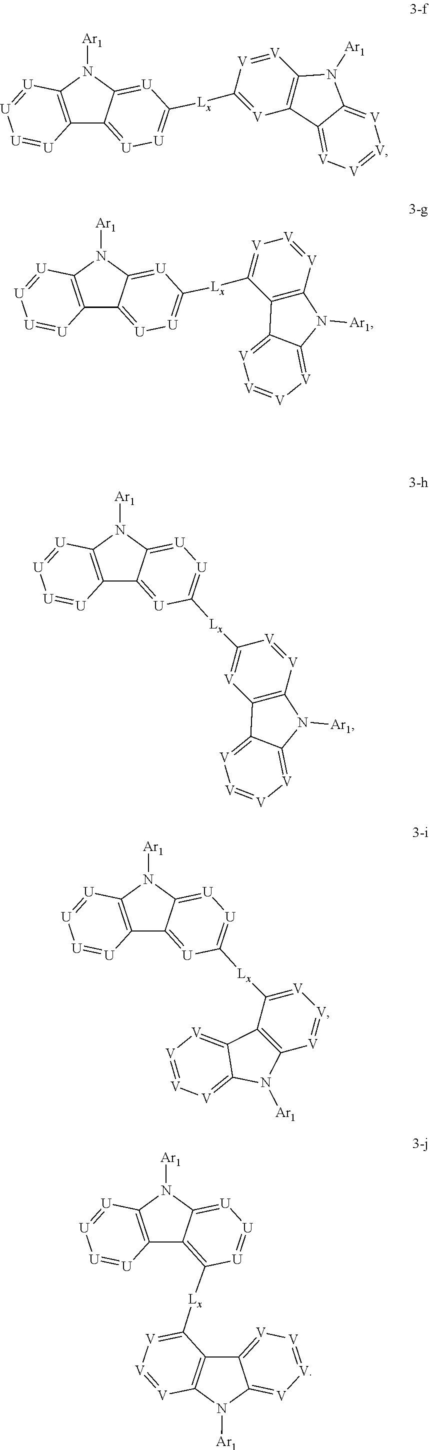

22. The electroluminescent device of claim 20, wherein the metal complex is doped in the first host compound and the second host compound, and the weight of the metal complex accounts for 1% to 30% of the total weight of the light-emitting layer; and
preferably, the weight of the metal complex accounts for 3% to 13% of the total weight of the light-emitting layer.

23. A compound composition containing the metal complex of claim 1.
